(19) United States
(12) Patent Application Publication
(10) Pub. No.: US 2025/0038772 A1
(43) Pub. Date: Jan. 30, 2025

(54) RADIO FREQUENCY CIRCUIT

(71) Applicant: Murata Manufacturing Co., Ltd., Nagaokakyo-shi (JP)

(72) Inventor: Shoji NAGUMO, Nagaokakyo-shi (JP)

(73) Assignee: Murata Manufacturing Co., Ltd., Nagaokakyo-shi (JP)

(21) Appl. No.: 18/916,766

(22) Filed: Oct. 16, 2024

Related U.S. Application Data
(63) Continuation of application No. PCT/JP2023/006829, filed on Feb. 24, 2023.

(30) Foreign Application Priority Data
Apr. 25, 2022 (JP) 2022-071588

(51) Int. Cl. H04B 1/00; H04B 1/04

(52) U.S. Cl. CPC H04B 1/0057; H04B 1/0458; H04B 2001/0408

(57) ABSTRACT

A radio frequency circuit includes a divider including a first, second, and third terminals. A first multiplexer includes a first filter having a first passband and a second filter having a second, higher passband. A first switch includes a first terminal, a second terminal connected to the first terminal of the divider, and a third terminal connected to first ends of the first and second filters. A second switch includes a first terminal, a second terminal connected to the third terminal of the divider, and a third terminal connected to a second end of the first filter. A third filter has a WLAN passband, and a first amplifier is connected to a first end of the third filter. The first terminal of the first switch is connected to the first amplifier or the first terminal of the second switch is connected to a second end of the third filter.

### CROSS-REFERENCE TO RELATED APPLICATIONS

This is a continuation application of PCT International Application No. PCT/JP2023/006829 filed on Feb. 24, 2023, which is based on and claims priority to Japanese Patent Application No. 2022-071588 filed on Apr. 25, 2022. The entire disclosures of the above-identified applications, including the specifications, drawings, and claims are incorporated herein by reference in their entirety.

### BACKGROUND

### 1. Field

The present disclosure relates to a radio frequency circuit.

### 2. Description of the Related Art

In mobile communication systems used in mobile phones and so on, utilization of a frequency band that does not require radio station license (hereinafter referred to as an unlicensed band) has been advanced, in addition to a frequency band that requires the radio station license (hereinafter referred to as a licensed band). For example, in 3rd Generation Partnership Project (3GPP) (registered trademark), standardization of a New Radio Unlicensed (NR-U) band for using the unlicensed band of five gigahertz or more (hereinafter represented as 5 GHz or more), which is used in a wireless local area network (WLAN), in 5th Generation New Radio (5GNR) is performed For example, there is a radio frequency circuit that is capable of using the unlicensed band, in addition to the licensed band.

However, with the technology in related art, the quality of transmission signals and/or receiving sensibility may be degraded.

### SUMMARY

Accordingly, the present disclosure provides a radio frequency circuit capable of improving the quality of transmission signals and/or receiving sensibility.

A radio frequency circuit according to one aspect of the present disclosure includes a first divider including a first terminal, a second terminal, and a third terminal; a first multiplexer including a first filter having a first passband and a second filter having a second passband higher than the first passband; a first switch including a first terminal, a second terminal connected to the first terminal of the first divider, and a third terminal connected to a first end of the first filter and a first end of the second filter; a second switch including a first terminal, a second terminal connected to the third terminal of the first divider, and a third terminal connected to a second end of the first filter; a third filter having a third passband including a WLAN band of 5 GHz or more; and a first amplifier connected to a first end of the third filter. The first terminal of the first switch is connected to the first amplifier or the first terminal of the second switch is connected to a second end of the third filter.

A radio frequency circuit according to one aspect of the present disclosure includes a first divider including a first terminal, a second terminal, and a third terminal; a first multiplexer including a first filter having a first passband and a second filter having a second passband higher than the first passband; a first switch including a first terminal, a second terminal, and a third terminal connected to a first end of the first filter and a first end of the second filter; a second switch including a first terminal connected to the first terminal of the first divider, a second terminal connected to the second terminal of the first switch, and a third terminal connected to a second end of the first filter; a third filter having a third passband including a WLAN band of 5 GHz or more; and a first amplifier connected to a first end of the third filter. The first terminal of the first switch is connected to the first amplifier or the third terminal of the first divider is connected to a second end of the third filter.

Further advantages provided by the disclosed exemplary embodiments will be recognized from the specification and the drawings. These advantages may be individually provided by the various exemplary embodiments and features of the specification and the drawings and all of them are not necessarily provided in order to achieve one or more advantages.

According to the present disclosure, it is possible to improve the quality of transmission signals and/or the receiving sensibility.

### BRIEF DESCRIPTION OF THE DRAWINGS

These and other objects, advantages and features of the disclosure will become apparent from the following description thereof taken in conjunction with the accompanying drawings that illustrate specific exemplary embodiments of the present disclosure.

FIG. 1 is a diagram illustrating an example of how a licensed band and an unlicensed band are allocated in each region;

FIG. 2 is a diagram illustrating the circuit configuration of a communication apparatus according to a comparative example;

FIG. 3 is a diagram illustrating the circuit configuration of a communication apparatus according to a first exemplary embodiment;

FIG. 4 is a diagram illustrating the connection state and the flow of a radio frequency signal for transmission in a first region in a radio frequency circuit according to the first exemplary embodiment;

FIG. 5 is a diagram illustrating the connection state and the flow of the radio frequency signal for reception in the first region in the radio frequency circuit according to the first exemplary embodiment;

FIG. 6 is a diagram illustrating the connection state and the flow of the radio frequency signal for transmission in a second region or a third region in the radio frequency circuit according to the first exemplary embodiment;

FIG. 7 is a diagram illustrating the connection state and the flow of the radio frequency signal for reception in the second region or the third region in the radio frequency circuit according to the first exemplary embodiment;

FIG. 8 is a diagram illustrating the circuit configuration of a communication apparatus according to a second exemplary embodiment;

FIG. 9 is a diagram illustrating the connection state and the flow of the radio frequency signal for transmission in the first region in a radio frequency circuit according to the second exemplary embodiment;

FIG. 10 is a diagram illustrating the connection state and the flow of the radio frequency signal for reception in the first region in the radio frequency circuit according to the second exemplary embodiment;

FIG. 11 is a diagram illustrating the connection state and the flow of the radio frequency signal for transmission in the second region or the third region in the radio frequency circuit according to the second exemplary embodiment;

FIG. 12 is a diagram illustrating the connection state and the flow of the radio frequency signal for reception in the second region or the third region in the radio frequency circuit according to the second exemplary embodiment;

FIG. 13 is a diagram illustrating the circuit configuration of a communication apparatus according to a third exemplary embodiment;

FIG. 14 is a diagram illustrating the connection state and the flow of the radio frequency signal for transmission in the first region in a radio frequency circuit according to the third exemplary embodiment;

FIG. 15 is a diagram illustrating the connection state and the flow of the radio frequency signal for reception in the first region in the radio frequency circuit according to the third exemplary embodiment;

FIG. 16 is a diagram illustrating the connection state and the flow of the radio frequency signal for transmission in the second region or the third region in the radio frequency circuit according to the third exemplary embodiment;

FIG. 17 is a diagram illustrating the connection state and the flow of the radio frequency signal for reception in the second region or the third region in the radio frequency circuit according to the third exemplary embodiment;

FIG. 18 is a diagram illustrating the circuit configuration of a communication apparatus according to a fourth exemplary embodiment;

FIG. 19 is a diagram illustrating the connection state and the flow of the radio frequency signal for transmission in the first region in a radio frequency circuit according to the fourth exemplary embodiment;

FIG. 20 is a diagram illustrating the connection state and the flow of the radio frequency signal for reception in the first region in the radio frequency circuit according to the fourth exemplary embodiment;

FIG. 21 is a diagram illustrating the connection state and the flow of the radio frequency signal for transmission in the second region or the third region in the radio frequency circuit according to the fourth exemplary embodiment;

FIG. 22 is a diagram illustrating the connection state and the flow of the radio frequency signal for reception in the second region or the third region in the radio frequency circuit according to the fourth exemplary embodiment;

FIG. 23 is a diagram illustrating the circuit configuration of a communication apparatus according to a fifth exemplary embodiment;

FIG. 24 is a diagram illustrating the connection state and the flow of the radio frequency signal for transmission in the first region in a radio frequency circuit according to the fifth exemplary embodiment;

FIG. 25 is a diagram illustrating the connection state and the flow of the radio frequency signal for reception in the first region in the radio frequency circuit according to the fifth exemplary embodiment;

FIG. 26 is a diagram illustrating the connection state and the flow of the radio frequency signal for transmission in the second region or the third region in the radio frequency circuit according to the fifth exemplary embodiment; and

FIG. 27 is a diagram illustrating the connection state and the flow of the radio frequency signal for reception in the second region or the third region in the radio frequency circuit according to the fifth exemplary embodiment.

### DESCRIPTION OF THE PREFERRED EMBODIMENTS

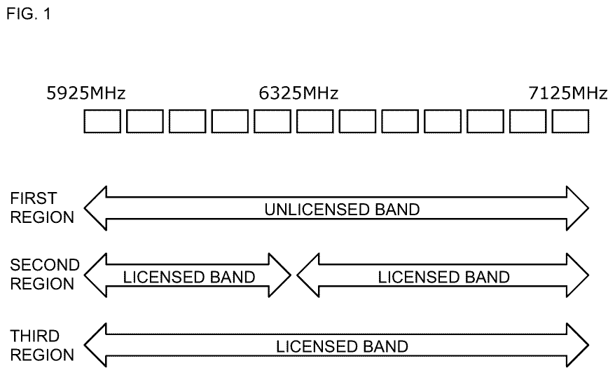

Which band, the licensed band or the unlicensed band, is allocated to a range from 5,925 MHz to 7,125 MHz in each region has been discussed in recent years. For example, in the US, allocation of the unlicensed band to the entire range from 5,925 MHz to 7,125 MHz is determined (refer to a first region in FIG. 1). For example, in China, allocation of the licensed band to the entire range is being discussed (refer to a third region in FIG. 1). For example, in Europe, allocation of the unlicensed band to a lower-frequency portion of the range and allocation of the licensed band to a higher-frequency portion of the range are being discussed (refer to a second region in FIG. 1).

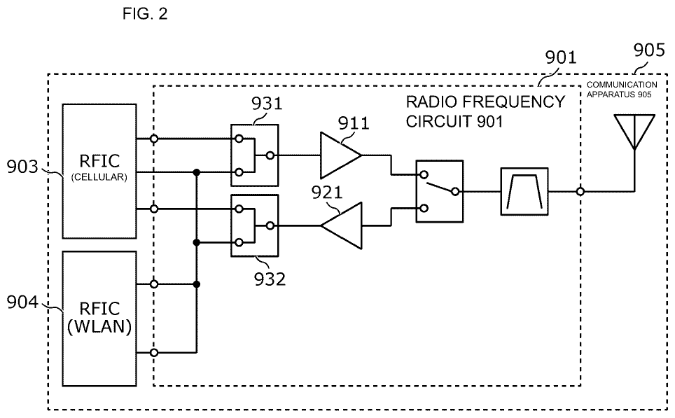

Since how the licensed band the unlicensed band are allocated is varied depending on the region, as described above, for example, a communication apparatus 905 illustrated in FIG. 2 is considered as a communication apparatus capable of being used in multiple regions. The communication apparatus 905 according to a comparative example, illustrated in FIG. 2, includes a radio frequency circuit 901, a radio frequency integrated circuit (RFIC) 903 for a cellular system, and an RFIC 904 for a WLAN system. In the radio frequency circuit 901, transmission signals received from the RFICs 903 and 904 are combined in a divider 931 and the combined signal is supplied to a power amplifier 911. A reception signal amplified in a low-noise amplifier 921 is divided in a divider 932 and the divided signals are supplied to the RFICs 903 and 904.

In such a communication apparatus 905, the use of the dividers 931 and 932 enables filters and amplifiers to be shared between the licensed band and the unlicensed band. However, the use of the dividers 931 and 932 causes power loss of 3 dB. In particular, since output power higher than that of the unlicensed band is frequently required in the licensed band, the influence of the power loss in the licensed band is greater than that in the unlicensed band.

In order to resolve the above problem, radio frequency circuits capable of suppressing the power loss due to the divider to improve the quality of transmission signals and/or receiving sensibility will herein be described in detail based on exemplary embodiments. All the exemplary embodiments described below indicate comprehensive or specific examples. Numerical values, shapes, materials, components, the arrangement of the components, the connection mode of the components, and so on, which are indicated in the exemplary embodiments described below, are only examples and are not intended to limit the present disclosure.

The respective drawings are schematic diagrams appropriately subjected to emphasis, omission, or adjustment of ratios in order to describe the present disclosure. The respective drawings are not necessarily strictly illustrated and may be different from the actual shapes, positional relationship, and ratios. The same reference numerals and letters are used in the respective drawings to identify substantially the same components and a duplicated description of such components may be omitted or simplified.

In circuit configurations of the present disclosure, “connected” includes not only direct connection with a connection terminal and/or a wiring conductor but also electrical connection via another circuit element. “Connected between A and B” means connection to both A and B between A and B and includes parallel connection (shunt connection) between a path between A and B and ground, in addition to series connection on the path between A and B.

In the present disclosure, a “terminal” includes not only a point at which conductor in an element comes to an end but also an arbitrary point on a path between elements. The terminal may be interpreted as not only a single point but also the entire path between elements.

In the present disclosure, a “6-GHz licensed band” means a frequency band that requires the radio station license in a range from 5,925 MHz to 7,125 MHz. The range from 5,925 MHz to 7,125 MHz may be appropriately varied. An “NR-U band” means a frequency band for using the unlicensed band of 5 GHz or more in the 5GNR. A “WLAN band” means a frequency band for using the unlicensed band of 5 GHz or more in the WLAN. Part of the WLAN band or the entire WLAN band may be overlapped with part of the NR-U band or the entire NR-U band.

In the present disclosure, the passband of a filter means a portion of the frequency spectrum transmitted by the filter and is defined as a frequency band in which the output power is not attenuated from the maximum output power by 3 dB or more. Accordingly, the cutoff frequencies of a high pass filter and a low pass filter are defined as the frequencies at points at which the output power is attenuated from the maximum output power by 3 dB.

### First Embodiment

A first exemplary embodiment will now be described.

### 1.1 Circuit Configuration of Communication Apparatus 5

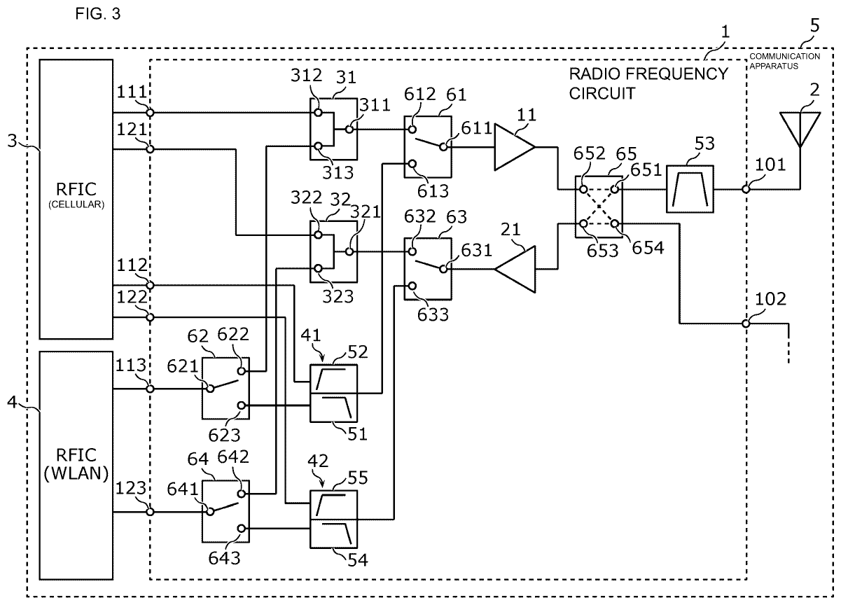

First, the circuit configuration of a communication apparatus 5 according to the first exemplary embodiment will be described with reference to FIG. 3. FIG. 3 is a diagram illustrating the circuit configuration of the communication apparatus 5 according to the first exemplary embodiment.

The communication apparatus 5 corresponds to user equipment (UE) in a cellular communication system and is typically a mobile phone, a smartphone, a tablet computer, a wearable device, or the like. The communication apparatus 5 may be an Internet of Things (IoT) sensor device, a medical-health care device, an automobile, an unmanned aerial vehicle (UAV) (so-called drone), or an automated guided vehicle (AGV). The communication apparatus 5 may be used as a base station (BS) in the cellular communication system.

As illustrated in FIG. 3, the communication apparatus 5 includes a radio frequency circuit 1, an antenna 2, RFICs 3 and 4.

The radio frequency circuit 1 transmits a radio frequency signal between the antenna 2 and the RFICs 3 and 4. The internal configuration of the radio frequency circuit 1 will be described below.

The antenna 2 is connected to an antenna connection terminal 101 of the radio frequency circuit 1. The radio frequency signal output from the radio frequency circuit 1 is transmitted through the antenna 2, and the radio frequency signal is received from the outside of the radio frequency circuit 1 through the antenna 2 to be supplied to the radio frequency circuit 1.

The RFICs 3 and 4 are examples of a signal processing circuit that processes the radio frequency signal. The RFIC 3 is capable of processing the radio frequency signal for the cellular system and the RFIC 4 is capable of processing the radio frequency signal for the WLAN system. Specifically, the RFICs 3 and 4 are capable of performing signal processing, such as up-conversion, of transmission signals for the cellular system and the WLAN system and supplying radio frequency transmission signals generated through the signal processing to a transmission path of the radio frequency circuit 1. In addition, the RFICs 3 and 4 are capable of performing signal processing, such as down-conversion, of a radio frequency reception signal input through a reception path of the radio frequency circuit 1 and outputting reception signals for the cellular system and the WLAN system generated through the signal processing.

The RFICs 3 and 4 may each include a control unit that controls switches, amplifiers, and so on in the radio frequency circuit 1. Part or all of the functions as the control units of the RFICs 3 and 4 may be implemented outside the RFICs 3 and 4 and, for example, may be implemented in the radio frequency circuit 1.

The antenna 2 is not an essential element in the communication apparatus 5 according to the first exemplary embodiment.

### 1.2 Circuit Configuration of Radio Frequency Circuit 1

Next, the circuit configuration of the radio frequency circuit 1 will be described with reference to FIG. 3. The radio frequency circuit 1 includes a power amplifier 11, a low-noise amplifier 21, dividers 31 and 32, multiplexers 41 and 42, a filter 53, switches 61 to 65, the antenna connection terminal 101 and an antenna connection terminal 102, radio-frequency input terminals 111 to 113, and radio-frequency output terminals 121 to 123. The components in the radio frequency circuit 1 will be sequentially described below.

The antenna connection terminal 101 is an example of a first antenna connection terminal. The antenna connection terminal 101 is connected to the antenna 2 outside the radio frequency circuit 1 and is connected to the filter 53 in the radio frequency circuit 1.

The antenna connection terminal 102 is an example of a second antenna connection terminal. The antenna connection terminal 102 is connected to an antenna (not illustrated) different from the antenna 2 outside the radio frequency circuit 1 and is connected to the switch 65 in the radio frequency circuit 1. Specifically, the antenna connection terminal 102 is connected to a diversity antenna via a filter or the like outside the radio frequency circuit 1 to be used for transmission of a sounding reference signal (SRS) and so on.

The radio-frequency input terminal 111 is an example of a first input-output terminal and a first input terminal and is a terminal for receiving the transmission signal in the NR-U band from the outside of the radio frequency circuit 1. Referring to FIG. 3, the radio-frequency input terminal 111 is connected to the RFIC 3 outside the radio frequency circuit 1 and is connected to the divider 31 in the radio frequency circuit 1.

The radio-frequency input terminal 112 is an example of a second input-output terminal and a second input terminal and is a terminal for receiving the transmission signal in the 6-GHz licensed band from the outside of the radio frequency circuit 1. Referring to FIG. 3, the radio-frequency input terminal 112 is connected to the RFIC 3 outside the radio frequency circuit 1 and is connected to the multiplexer 41 in the radio frequency circuit 1.

The radio-frequency input terminal 113 is an example of a third input-output terminal and a third input terminal and is a terminal for receiving the transmission signal in the WLAN band from the outside of the radio frequency circuit 1. Referring to FIG. 3, the radio-frequency input terminal 113 is connected to the RFIC 4 outside the radio frequency circuit 1 and is connected to the switch 62 in the radio frequency circuit 1.

The radio-frequency output terminal 121 is an example of a first output terminal and is a terminal for supplying the reception signal in the NR-U band to the outside of the radio frequency circuit 1. Referring to FIG. 3, the radio-frequency output terminal 121 is connected to the RFIC 3 outside the radio frequency circuit 1 and is connected to the divider 32 in the radio frequency circuit 1.

The radio-frequency output terminal 122 is an example of a second output terminal and is a terminal for supplying the reception signal in the 6-GHz licensed band to the outside of the radio frequency circuit 1. Referring to FIG. 3, the radio-frequency output terminal 122 is connected to the RFIC 3 outside the radio frequency circuit 1 and is connected to the multiplexer 42 in the radio frequency circuit 1.

The radio-frequency output terminal 123 is an example of a third output terminal and is a terminal for supplying the reception signal in the WLAN band to the outside of the radio frequency circuit 1. Referring to FIG. 3, the radio-frequency output terminal 123 is connected to the RFIC 4 outside the radio frequency circuit 1 and is connected to the switch 64 in the radio frequency circuit 1.

The power amplifier 11 is an example of a first amplifier and is connected between the switch 61 and the filter 53. Specifically, an input end of the power amplifier 11 is connected to the switch 61 and an output end of the power amplifier 11 is connected to the filter 53 or the antenna connection terminal 102 via the switch 65. The power amplifier 11 is capable of amplifying the transmission signals in the WLAN band, the NR-U band, and the 6-GHz licensed band.

The power amplifier means an active circuit that generates an output signal of energy higher than that of an input signal (the transmission signal) based on power supplied from a power source. The power amplifier includes an amplifier transistor and may further include an inductor and/or a capacitor. The internal configuration of the power amplifier is not particularly limited. For example, the power amplifier may be a multistage amplifier, an amplifier of a differential amplification type, or a Doherty amplifier.

The low-noise amplifier 21 is connected between the switch 63 and the filter 53. Specifically, an input end of the low-noise amplifier 21 is connected to the filter 53 or the antenna connection terminal 102 via the switch 65 and an output end of the low-noise amplifier 21 is connected to the switch 63. The low-noise amplifier 21 is capable of amplifying the reception signals in the WLAN band, the NR-U band, and the 6-GHz licensed band.

The low-noise amplifier means an active circuit that generates an output signal of energy higher than that of an input signal (the reception signal) with low noise based on power supplied from a power source. The low-noise amplifier includes an amplifier transistor and may further include an inductor and/or a capacitor. The internal configuration of the low-noise amplifier is not particularly limited.

The divider 31 is an example of a first divider and is a power divider including three terminals 311 to 313. The terminal 311 is an example of a first terminal and is connected to the switch 61. The terminal 312 is an example of a second terminal and is connected to the radio-frequency input terminal 111. The terminal 313 is an example of a third terminal and is connected to the switch 62.

The divider 32 is an example of a second divider and is a power divider including three terminals 321 to 323. The terminal 321 is an example of the first terminal and is connected to the switch 63. The terminal 322 is an example of the second terminal and is connected to the radio-frequency output terminal 121. The terminal 323 is an example of the third terminal and is connected to the switch 64.

The multiplexers 41 and 42 are examples of a first multiplexer and a second multiplexer, respectively. The multiplexer 41 includes filters 51 and 52 and the multiplexer 42 includes filters 54 and 55.

The filter 51 is an example of a first filter and has a passband (an example of a first passband) lower than a passband of the filter 52. One end of the filter 51 is connected to the switch 61 and the other end of the filter 51 is connected to the switch 62.

In the first exemplary embodiment, the low pass filter is used as the filter 51. At this time, a frequency higher than or equal to an upper limit frequency of the WLAN band in a certain region in which the 6-GHz licensed band is capable of being used is usable as a cutoff frequency of the low pass filter. The certain region is a region supported by the radio frequency circuit 1. For example, when the certain region is the second region in FIG. 1, a frequency higher than or equal to the upper limit frequency (6,325 MHZ) of the WLAN band in the second region is used as the cutoff frequency of the filter 51. In this case, the passband of the filter 51 at least includes the unlicensed band of 5 GHZ or more in the second region. For example, when the certain region is the third region in FIG. 1, a frequency higher than or equal to the upper limit frequency (5,925 MHZ) of the WLAN band in the third region is used as the cutoff frequency of the filter 51. In this case, the passband of the filter 51 at least includes the unlicensed band of 5 GHZ or more in the third region. The filter 51 is not necessarily the low pass filter and may be a band pass filter.

The filter 52 is an example of a second filter and has a passband (an example of a second passband) higher than the passband of the filter 51. One end of the filter 52 is connected to the switch 61 and the other end of the filter 52 is connected to the radio-frequency input terminal 112.

In the first exemplary embodiment, the high pass filter is used as the filter 52. At this time, a frequency lower than or equal to a lower limit frequency of the 6-GHz licensed band in a certain region in which the 6-GHz licensed band is capable of being used is usable as the cutoff frequency of the high pass filter. For example, when the certain region is the second region in FIG. 1, a frequency lower than or equal to the lower limit frequency (6,325 MHz) of the 6-GHz licensed band in the second region is used as the cutoff frequency of the filter 52. In this case, the passband of the filter 52 at least includes the 6-GHz licensed band in the second region. For example, when the certain region is the third region in FIG. 1, a frequency lower than or equal to the lower limit frequency (5,925 MHz) of the 6-GHz licensed band in the third region is used as the cutoff frequency of the filter 52. In this case, the passband of the filter 52 at least includes the 6-GHz licensed band in the third region. The filter 52 is not necessarily the high pass filter and may be a band pass filter.

The filter 53 is an example of a third filter and is a band pass filter having a passband (an example of a third passband) including the WLAN band, the NR-U band, and the 6-GHz licensed band. Specifically, the passband of the filter 53 includes a range that is higher than the lower limit frequency (for example, 5,170 MHz) of the unlicensed band of 5 GHz or more and that is lower than the upper limit frequency of the unlicensed band of 5 GHz or more or the upper limit frequency (for example, 7,125 MHz) of the 6-GHz licensed band. Accordingly, when the radio frequency circuit 1 supports a region (for example, the second region or the third region in FIG. 1) to which the 6-GHz licensed band is allocated, the passband of the filter 53 includes both the unlicensed band of 5 GHz or more and the 6-GHz licensed band. When the radio frequency circuit 1 supports a region (for example, the first region in FIG. 1) to which the 6-GHz licensed band is not allocated, the passband of the filter 53 includes the entire unlicensed band of 5 GHz or more. One end of the filter 53 is connected to the switch 65 and the other end of the filter 53 is connected to the antenna connection terminal 101.

The filter 54 is an example of a fourth filter and has a passband (an example of a fourth passband) lower than a passband of the filter 55. One end of the filter 54 is connected to the switch 63 and the other end of the filter 54 is connected to the switch 64.

In the first exemplary embodiment, the low pass filter is used as the filter 54, like the filter 51. At this time, a frequency higher than or equal to the upper limit frequency of the WLAN band in a certain region in which the 6-GHz licensed band is capable of being used is usable as the cutoff frequency of the low pass filter. Specifically, the passband of the filter 54 at least includes the unlicensed band of 5 GHz or more in the second region when the radio frequency circuit 1 supports the second region and at least includes the unlicensed band of 5 GHz or more in the third region when the radio frequency circuit 1 supports the third region, like the passband of the filter 51. The filter 54 is not necessarily the low pass filter and may be a band pass filter.

The filter 55 is an example of a fifth filter and has a passband (an example of a fifth passband) higher than the passband of the filter 54. One end of the filter 55 is connected to the switch 63 and the other end of the filter 55 is connected to the radio-frequency output terminal 122.

In the first exemplary embodiment, the high pass filter is used as the filter 55, like the filter 52. At this time, a frequency lower than or equal to the lower limit frequency of the 6-GHz licensed band in a certain region in which the 6-GHz licensed band is capable of being used is usable as the cutoff frequency of the high pass filter. Specifically, the passband of the filter 55 at least includes the 6-GHz licensed band in the second region when the radio frequency circuit 1 supports the second region and at least includes the 6-GHz licensed band in the third region when the radio frequency circuit 1 supports the third region, like the passband of the filter 52. The filter 55 is not necessarily the high pass filter and may be a band pass filter.

Each of the filters 51 to 55 may be composed of any of a surface acoustic wave (SAW) filter, a bulk acoustic wave (BAW) filter, an LC filter, and a dielectric filter and is not limited to these filters.

The switch 61 is an example of a first switch and includes three terminals 611 to 613. The terminal 611 is an example of the first terminal and is connected to the input end of the power amplifier 11. The terminal 612 is an example of the second terminal and is connected to the terminal 311 of the divider 31. The terminal 613 is an example of the third terminal and is connected to one end of the filter 51 and one end of the filter 52.

In this connection configuration, the switch 61 is capable of exclusively connecting the terminal 611 to the terminals 612 and 613 based on, for example, a control signal from the RFIC 3. The switch 61 is composed of, for example, a single-pole double-throw (SPDT) switch circuit.

The switch 62 is an example of a second switch and includes three terminals 621 to 623. The terminal 621 is an example of the first terminal and is connected to the radio-frequency input terminal 113. The terminal 622 is an example of the second terminal and is connected to the terminal 313 of the divider 31. The terminal 623 is an example of the third terminal and is connected to the other end of the filter 51.

In this connection configuration, the switch 62 is capable of exclusively connecting the terminal 621 to the terminals 622 and 623 based on, for example, the control signal from the RFIC 3. The switch 62 is composed of, for example, an SPDT switch circuit.

The switch 63 is an example of a third switch and includes three terminals 631 to 633. The terminal 631 is an example of the first terminal and is connected to the output end of the low-noise amplifier 21. The terminal 632 is an example of the second terminal and is connected to the terminal 321 of the divider 32. The terminal 633 is an example of the third terminal and is connected to one end of the filter 54 and one end of the filter 55.

In this connection configuration, the switch 63 is capable of exclusively connecting the terminal 631 to the terminals 632 and 633 based on, for example, the control signal from the RFIC 3. The switch 63 is composed of, for example, an SPDT switch circuit.

The switch 64 is an example of a fourth switch and includes three terminals 641 to 643. The terminal 641 is an example of the first terminal and is connected to the radio-frequency output terminal 123. The terminal 642 is an example of the second terminal and is connected to the terminal 323 of the divider 32. The terminal 643 is an example of the third terminal and is connected to the other end of the filter 54.

In this connection configuration, the switch 64 is capable of exclusively connecting the terminal 641 to the terminals 642 and 643 based on, for example, the control signal from the RFIC 3. The switch 64 is composed of, for example, an SPDT switch circuit.

The switch 65 is an example of a fifth switch and includes four terminals 651 to 654. The terminal 651 is an example of the first terminal and is connected to one end of the filter 53. The terminal 652 is an example of the second terminal and is connected to the output end of the power amplifier 11. The terminal 653 is an example of the third terminal and is connected to the input end of the low-noise amplifier 21. The terminal 654 is an example of a fourth terminal and is connected to the antenna connection terminal 102.

In this connection configuration, the switch 65 is capable of exclusively connecting the terminal 651 to the terminals 652 and 653 and is capable of exclusively connecting the terminal 654 to the terminals 652 and 653 based on, for example, the control signal from the RFIC 3. The switch 65 is composed of, for example, a double-pole double-throw (DPDT) switch circuit.

The radio frequency circuit 1 illustrated in FIG. 3 is only an example and is not limited to this. For example, the radio frequency circuit 1 does not necessarily include the reception path. Specifically, the radio frequency circuit 1 does not necessarily include the low-noise amplifier 21, the divider 32, the multiplexer 42, the switches 63 to 65, and the radio-frequency output terminals 121 to 123. For example, the radio frequency circuit 1 does not necessarily include the transmission path. Specifically, the radio frequency circuit 1 does not necessarily include the power amplifier 11, the divider 31, the multiplexer 41, the switches 61, 62, and 65, and the radio-frequency input terminals 111 to 113. In this case, the low-noise amplifier 21 is an example of the first amplifier, the divider 32 is an example of the first divider, the multiplexer 42 is an example of the first multiplexer, the filters 54 and 55 are examples of the first filter and the second filter, respectively, the passbands of the filters 54 and 55 are examples of the first passband and the second passband, respectively, the switches 63 and 64 are examples of the first switch and the second switch, respectively, and the radio-frequency output terminals 121 to 123 are examples of the first to third input-output terminals, respectively. For example, the radio frequency circuit 1 does not necessarily include the antenna connection terminal 102. In this case, the switch 65 does not necessarily have the terminal 654.

### 1.3 Connection States and Flows of Radio Frequency Signal in the Radio Frequency Circuit 1

Next, specific examples of connection states and the flows of the radio frequency signal in the respective connection states in the radio frequency circuit 1 according to the first exemplary embodiment will be described.

### 1.3.1 Connection State and Flow of Radio Frequency Signal for Transmission in First Region

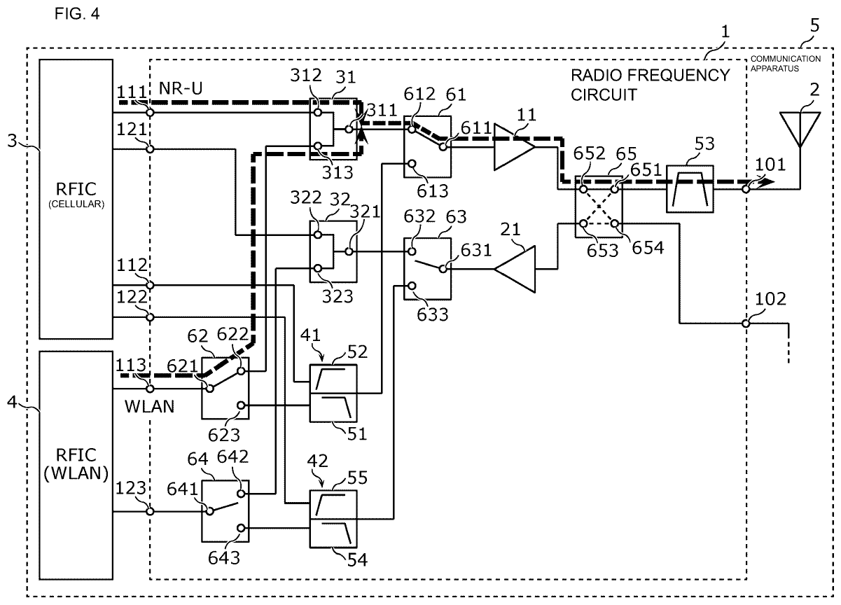

First, the connection state and the flow of the radio frequency signal for transmission in the first region will be described with reference to FIG. 4. FIG. 4 is a diagram illustrating the connection state and the flow of the radio frequency signal for transmission in the first region in the radio frequency circuit 1 according to the first exemplary embodiment.

The 6-GHz licensed band is not used and the NR-U band and the WLAN band are used in the first region, as illustrated in FIG. 1. Accordingly, the RFIC 3 controls each switch in the radio frequency circuit 1 to transmit the signals in the NR-U band and the WLAN band using the divider 31 in FIG. 4. Specifically, the switch 61 connects the terminal 611 to the terminal 612, the switch 62 connects the terminal 621 to the terminal 622, and the switch 65 connects the terminal 651 to the terminal 652.

As a result, the transmission signal in the NR-U band is transmitted from the radio-frequency input terminal 111 to the divider 31. The transmission signal in the WLAN band is transmitted from the radio-frequency input terminal 113 to the divider 31 via the switch 62. The transmission signal in the NR-U band is combined with the transmission signal in the WLAN band in the divider 31. The transmission signal combined in the divider 31 is transmitted to the antenna connection terminal 101 via the switch 61, the power amplifier 11, the switch 65, and the filter 53.

The signals in the NR-U band and the WLAN band received from the RFICs 3 and 4, respectively, are transmitted from the antenna 2.

### 1.3.2 Connection State and Flow of Radio Frequency Signal for Reception in First Region

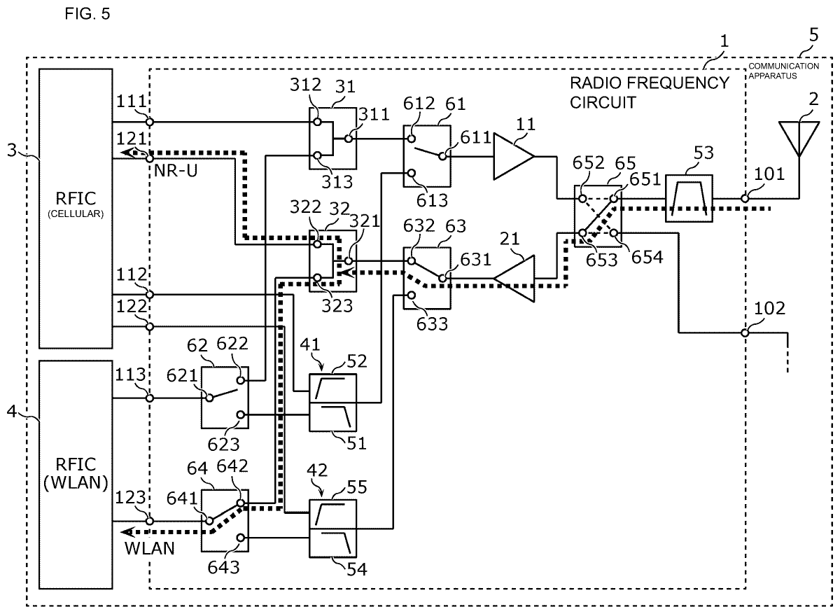

Next, the connection state and the flow of the radio frequency signal for reception in the first region will be described with reference to FIG. 5. FIG. 5 is a diagram illustrating the connection state and the flow of the radio frequency signal for reception in the first region in the radio frequency circuit 1 according to the first exemplary embodiment.

The 6-GHz licensed band is not used and the NR-U band and the WLAN band are used in the first region, as illustrated in FIG. 1. Accordingly, the RFIC 3 controls each switch in the radio frequency circuit 1 to receive the signals in the NR-U band and the WLAN band using the divider 32 in FIG. 5. Specifically, the switch 63 connects the terminal 631 to the terminal 632, the switch 64 connects the terminal 641 to the terminal 642, and the switch 65 connects the terminal 651 to the terminal 653.

As a result, the reception signals in the NR-U band and the WLAN band are transmitted from the antenna connection terminal 101 to the divider 32 via the filter 53, the switch 65, the low-noise amplifier 21, and the switch 63. The reception signals in the NR-U band and the WLAN band are divided in the divider 32. One of the divided reception signals is transmitted to the radio-frequency output terminal 121. The other of the divided reception signals is transmitted to the radio-frequency output terminal 123 via the switch 64.

The signals in the NR-U band and the WLAN band received through the antenna 2 are supplied to the RFICs 3 and 4, respectively.

### 1.3.3 Connection State and Flow of Radio Frequency Signal for Transmission in Second Region or Third Region

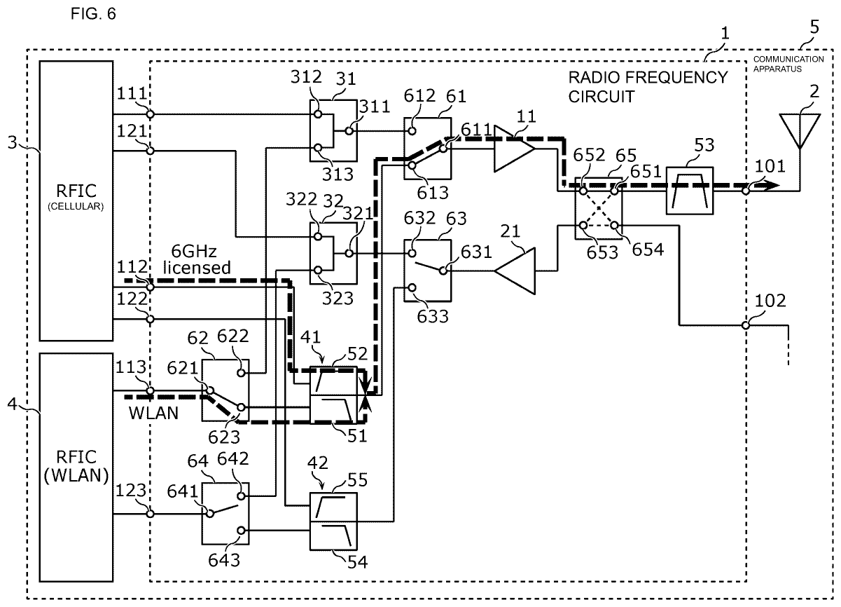

Next, the connection state and the flow of the radio frequency signal for transmission in the second region or the third region will be described with reference to FIG. 6. FIG. 6 is a diagram illustrating the connection state and the flow of the radio frequency signal for transmission in the second region or the third region in the radio frequency circuit 1 according to the first exemplary embodiment.

The 6-GHz licensed band is used in the second region and the third region, as illustrated in FIG. 1. Accordingly, the RFIC 3 controls each switch in the radio frequency circuit 1 to transmit the signals in the 6-GHz licensed band and the WLAN band using the multiplexer 41 in FIG. 6. Specifically, the switch 61 connects the terminal 611 to the terminal 613, the switch 62 connects the terminal 621 to the terminal 623, and the switch 65 connects the terminal 651 to the terminal 652.

As a result, the transmission signal in the 6-GHz licensed band is transmitted from the radio-frequency input terminal 112 to the multiplexer 41. The transmission signal in the WLAN band is transmitted from the radio-frequency input terminal 113 to the multiplexer 41 via the switch 62. The transmission signal in the 6-GHz licensed band is multiplexed with the transmission signal in the WLAN band in the multiplexer 41. The transmission signal multiplexed in the multiplexer 41 is transmitted to the antenna connection terminal 101 via the switch 61, the power amplifier 11, the switch 65, and the filter 53.

The signals in the 6-GHz licensed band and the WLAN band received from the RFICs 3 and 4, respectively, are transmitted from the antenna 2.

### 1.3.4 Connection State and Flow of Radio Frequency Signal for Reception in Second Region or Third Region

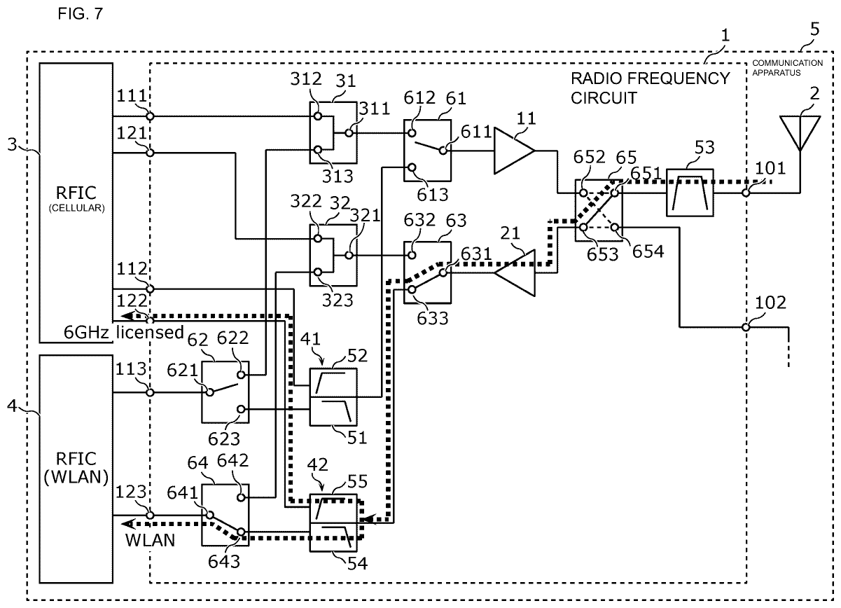

Next, the connection state and the flow of the radio frequency signal for reception in the second region or the third region will be described with reference to FIG. 7. FIG. 7 is a diagram illustrating the connection state and the flow of the radio frequency signal for reception in the second region or the third region in the radio frequency circuit 1 according to the first exemplary embodiment.

The 6-GHz licensed band is used in the second region and the third region, as illustrated in FIG. 1. Accordingly, the RFIC 3 controls each switch in the radio frequency circuit 1 to receive the signals in the 6-GHz licensed band and the WLAN band using the multiplexer 42 in FIG. 7. Specifically, the switch 63 connects the terminal 631 to the terminal 633, the switch 64 connects the terminal 641 to the terminal 643, and the switch 65 connects the terminal 651 to the terminal 653.

As a result, the reception signals in the 6-GHz licensed band and the WLAN band are transmitted from the antenna connection terminal 101 to the multiplexer 42 via the filter 53, the switch 65, the low-noise amplifier 21, and the switch 63. The reception signals in the 6-GHz licensed band and the WLAN band are demultiplexed into the reception signal in the 6-GHz licensed band and the reception signal in the WLAN band in the multiplexer 42. The reception signal in the 6-GHz licensed band demultiplexed in the multiplexer 42 is transmitted to the radio-frequency output terminal 122. The reception signal in the WLAN band demultiplexed in the multiplexer 42 is transmitted to the radio-frequency output terminal 123 via the switch 64.

The signals in the 6-GHz licensed band and the WLAN band received through the antenna 2 are supplied to the RFICs 3 and 4, respectively.

### 1.4 Exemplary Advantages

As described above, the radio frequency circuit 1 according to the first exemplary embodiment includes the divider 31 or 32 including the first terminal, the second terminal, and the third terminal; the multiplexer 41 or 42 including the filter 51 or 54 having the first passband and the filter 52 or 55 having the second passband higher than the first passband; the switch 61 or 63 including the first terminal, the second terminal connected to the first terminal of the divider 31 or 32, and the third terminal connected to one end of the filter 51 or 54 and one end of the filter 52 or 55; the switch 62 or 64 including the first terminal, the second terminal connected to the third terminal of the divider 31 or 32, and the third terminal connected to the other end of the filter 51 or 54; the filter 53 having the third passband including the WLAN band amplifier 11 or the low-noise amplifier 21) connected to one end of the filter 53. The first terminal of the switch 61 or 63 is connected to the first amplifier (the power amplifier 11 or the low-noise amplifier 21).

With the above configuration, the connection of the first amplifier (the power amplifier 11 or the low-noise amplifier 21) and the filter 53 is capable of being switched between the divider 31 or 32 and the multiplexer 41 or 42 using the switch 61 or 63. Accordingly, it is possible to use the multiplexer 41 or 42, instead of the divider 31 or 32 causing loss of 3 dB, for transmission or reception to improve the quality of transmission signals or the receiving sensibility, compared with that of the radio frequency circuit 901 according to the comparative example.

For example, in the radio frequency circuit 1 according to the first exemplary embodiment, the first terminal of the switch 61 or 63 may be connected to the first amplifier (the power amplifier 11 or the low-noise amplifier 21). The third passband of the filter 53 may further include the NR-U band and the 6-GHz licensed band. The radio frequency circuit 1 may further include the antenna connection terminal 101 connected to the other end of the filter 53; the first input-output terminal (the radio-frequency input terminal 111 or the radio-frequency output terminal 121) that is for the NR-U band and that is connected to the second terminal of the divider 31 or 32; the second input-output terminal (the radio-frequency input terminal 112 or the radio-frequency output terminal 122) that is for the 6-GHz licensed band and that is connected to the other end of the filter 52 or 55; and the third input-output terminal (the radio-frequency input terminal 113 or the radio-frequency output terminal 123) that is for the WLAN band and that is connected to the first terminal of the switch 62 or 64.

With the above configuration, the multiplexer 41 or 42 is connected between the first amplifier (the power amplifier 11 or the low-noise amplifier 21) and the second input-output terminal (the radio-frequency input terminal 112 or the radio-frequency output terminal 122) and the third input-output terminal (the radio-frequency input terminal 113 or the radio-frequency output terminal 123) via the switch 61 or 63 and the switch 62 or 64. Accordingly, the use of the multiplexer 41 or 42 enables the power loss to be reduced in transmission or reception of the signals in the 6-GHz licensed band and the WLAN band to improve the quality of transmission signals or the receiving sensibility. In addition, it is possible to share the filter 53 and the first amplifier (the power amplifier 11 or the low-noise amplifier 21) among the NR-U band, the 6-GHz licensed band, and the WLAN band to contribute to a reduction in the number of components.

For example, in the radio frequency circuit 1 according to the first exemplary embodiment, the first amplifier may be the power amplifier 11, the first input-output terminal may be the radio-frequency input terminal 111 for receiving the transmission signal in the NR-U band from the outside of the radio frequency circuit 1, the second input-output terminal may be the radio-frequency input terminal 112 for receiving the transmission signal in the 6-GHz licensed band from the outside of the radio frequency circuit 1, and the third input-output terminal may be the radio-frequency input terminal 113 for receiving the transmission signal in the WLAN band from the outside of the radio frequency circuit 1.

With the above configuration, the use of the multiplexer 41 enables the power loss to be reduced in transmission of the signals in the 6-GHz licensed band and the WLAN band to improve the quality of transmission signals. In particular, since the output power higher than that of the NR-U band is required in transmission of the signal in the 6-GHz licensed band, the effect of improving the quality of the transmission signals due to the reduction in the power loss is high.

For example, the radio frequency circuit 1 according to the first exemplary embodiment may further include the divider 32 including the first terminal, the second terminal, and the third terminal; the multiplexer 42 including the filter 54 having the fourth passband and the filter 55 having the fifth passband higher than the fourth passband; the switch 63 including the first terminal, the second terminal connected to the first terminal of the divider 32, and the third terminal connected to one end of the filter 54 and one end of the filter 55; the switch 64 including the first terminal, the second terminal connected to the third terminal of the divider 32, and the third terminal connected to the other end of the filter 54; the low-noise amplifier 21 connected between one end of the filter 53 and the first terminal of the switch 63; the switch 65 including the first terminal connected to one end of the filter 53, the second terminal connected to the output end of the power amplifier 11, and the third terminal connected to the input end of the low-noise amplifier 21; the radio-frequency output terminal 121 that is for supplying the reception signal in the NR-U band to the outside of the radio frequency circuit 1 and that is connected to the second terminal of the divider 32; the radio-frequency output terminal 122 that is for supplying the reception signal in the 6-GHz licensed band to the outside of the radio frequency circuit 1 and that is connected to the other end of the filter 55; and the radio-frequency output terminal 123 that is for supplying the reception signal in the WLAN band to the outside of the radio frequency circuit 1 and that is connected to the first terminal of the switch 64.

With the above configuration, the use of the multiplexer 41 enables the power loss to be reduced in transmission of the signals in the 6-GHz licensed band and the WLAN band and the use of the multiplexer 42 enables the power loss to be reduced in reception of the signals in the 6-GHz licensed band and the WLAN band. Accordingly, it is possible to improve the quality of transmission signals and the receiving sensibility.

For example, the radio frequency circuit 1 according to the first exemplary embodiment may further include the antenna connection terminal 102. The switch 65 may further include the fourth terminal connected to the antenna connection terminal 102.

With the above configuration, the antenna connection terminals 101 and 102 are capable of being selected using the switch 65. Accordingly, the antenna to be used in transmission or reception is capable of being swapped to improve the quality of transmission signals and the receiving sensibility. For example, when a diversity antenna is connected to the antenna connection terminal 102 via a diversity circuit, the signal (for example, the SRS or the like) transmitted through the diversity antenna is capable of being amplified by the power amplifier 11 in the radio frequency circuit 1. Accordingly, in such a case, the power amplifier in the diversity circuit may be omitted.

For example, in the radio frequency circuit 1 according to the first exemplary embodiment, the first amplifier may be the low-noise amplifier 21, the first input-output terminal may be the radio-frequency output terminal 121 for supplying the reception signal in the NR-U band to the outside of the radio frequency circuit 1, the second input-output terminal may be the radio-frequency output terminal 122 for supplying the reception signal in the 6-GHz licensed band to the outside of the radio frequency circuit 1, and the third input-output terminal may be the radio-frequency output terminal 123 for supplying the reception signal in the WLAN band to the outside of the radio frequency circuit 1.

With the above configuration, the use of the multiplexer 41 enables the power loss to be reduced in reception of the signals in the 6-GHz licensed band and the WLAN band to improve the receiving sensibility.

For example, in the radio frequency circuit 1 according to the first exemplary embodiment, the filter 51 and/or 54 may be a low pass filter having the cutoff frequency higher than or equal to the upper limit frequency of the WLAN band in a certain region in which the 6-GHz licensed band is capable of being used. The filter 52 and/or 55 may be a high pass filter having the cutoff frequency lower than or equal to the lower limit frequency of the 6-GHz licensed band in the certain region.

With the above configuration, the signal in the 6-GHz licensed band and the signal in the WLAN band are capable of being efficiently multiplexed and/or demultiplexed with the multiplexer 41 and/or 42 to improve the quality of transmission signals and/or the receiving sensibility.

### Second Embodiment

Next, a second exemplary embodiment will be described. The second exemplary embodiment mainly differs from the first exemplary embodiment described above in that the divider, the multiplexer, and the switches for switching between the divider and the multiplexer are connected between the band pass filters and the antenna connection terminal. The second exemplary embodiment will be described below, focusing on points different from the first exemplary embodiment described above.

### 2.1 Circuit Configuration of Communication Apparatus 5A

The circuit configuration of a communication apparatus 5A according to the second exemplary embodiment is the same as that of the communication apparatus 5 according to the first exemplary embodiment described above excluding inclusion of a radio frequency circuit 1A, instead of the radio frequency circuit 1. Accordingly, description of the circuit configuration of the communication apparatus 5A is omitted herein, excluding the description of the radio frequency circuit 1A.

### 2.2 Circuit Configuration of Radio Frequency Circuit 1A

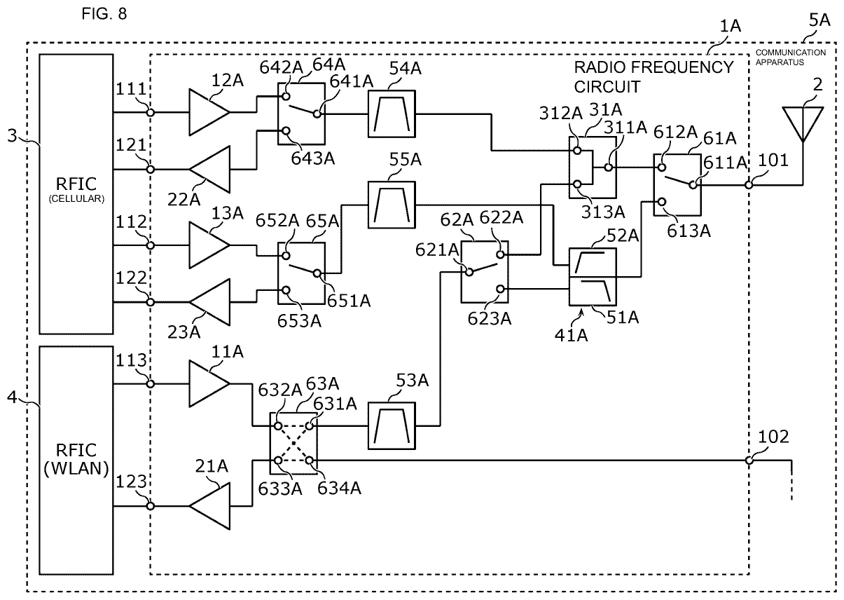

The circuit configuration of the radio frequency circuit 1A according to the second exemplary embodiment will be described with reference to FIG. 8. FIG. 8 is a diagram illustrating the circuit configuration of the communication apparatus 5A according to the second exemplary embodiment.

The radio frequency circuit 1A includes power amplifiers 11A to 13A, low-noise amplifiers 21A to 23A, a divider 31A, a multiplexer 41A, filters 53A to 55A, switches 61A to 65A, the antenna connection terminals 101 and 102, the radio-frequency input terminals 111 to 113, and the radio-frequency output terminals 121 to 123. The components in the radio frequency circuit 1A will be described, focusing on points different from the radio frequency circuit 1.

The power amplifier 11A is an example of the first amplifier and a first power amplifier and is connected between the radio-frequency input terminal 113 and the filter 53A. Specifically, an input end of the power amplifier 11A is connected to the radio-frequency input terminal 113 and an output end of the power amplifier 11A is connected to the filter 53A or the antenna connection terminal 102 via the switch 63A. The power amplifier 11A is capable of amplifying the transmission signal in the WLAN band.

The power amplifier 12A is an example of a second amplifier and a second power amplifier and is connected between the radio-frequency input terminal 111 and the filter 54A. Specifically, an input end of the power amplifier 12A is connected to the radio-frequency input terminal 111 and an output end of the power amplifier 12A is connected to the filter 54A via the switch 64A. The power amplifier 12A is capable of amplifying the transmission signal in the NR-U band.

The power amplifier 13A is an example of a third amplifier and a third power amplifier and is connected between the radio-frequency input terminal 112 and the filter 55A. Specifically, an input end of the power amplifier 13A is connected to the radio-frequency input terminal 112 and an output end of the power amplifier 13A is connected to the filter 55A via the switch 65A. The power amplifier 13A is capable of amplifying the transmission signal in the 6-GHz licensed band.

The low-noise amplifier 21A is an example of a first low-noise amplifier and is connected between the filter 53A and the radio-frequency output terminal 123. Specifically, an input end of the low-noise amplifier 21A is connected to the filter 53A or the antenna connection terminal 102 via the switch 63A and an output end of the low-noise amplifier 21A is connected to the radio-frequency output terminal 123. The low-noise amplifier 21A is capable of amplifying the reception signal in the WLAN band.

The low-noise amplifier 22A is an example of a second low-noise amplifier and is connected between the filter 54A and the radio-frequency output terminal 121. Specifically, an input end of the low-noise amplifier 22A is connected to the filter 54A via the switch 64A and an output end of the low-noise amplifier 22A is connected to the radio-frequency output terminal 121. The low-noise amplifier 22A is capable of amplifying the reception signal in the NR-U band.

The low-noise amplifier 23A is an example of a third low-noise amplifier and is connected between the filter 55A and the radio-frequency output terminal 122. Specifically, an input end of the low-noise amplifier 23A is connected to the filter 55A via the switch 65A and an output end of the low-noise amplifier 23A is connected to the radio-frequency output terminal 122. The low-noise amplifier 23A is capable of amplifying the reception signal in the 6-GHz licensed band.

The divider 31A is an example of the first divider and is a power divider including three terminals 311A to 313A. The terminal 311A is an example of the first terminal and is connected to the switch 61A. The terminal 312A is an example of the second terminal and is connected to the filter 54A. The terminal 313A is an example of the third terminal and is connected to the switch 62A.

The multiplexer 41A is an example of the first multiplexer and includes filters 51A and 52A.

The filter 51A is an example of the first filter and has a passband (an example of the first passband) lower than a passband of the filter 52A. One end of the filter 51A is connected to the switch 61A and the other end of the filter 51A is connected to the switch 62A.

In the second exemplary embodiment, the low pass filter is used as the filter 51A, like the filter 51. At this time, a frequency higher than or equal to the upper limit frequency of the WLAN band in a certain region in which the 6-GHz licensed band is capable of being used is usable as the cutoff frequency of the low pass filter. Specifically, the passband of the filter 51A at least includes the unlicensed band of 5 GHz or more in the second region when the radio frequency circuit 1A supports the second region and at least includes the unlicensed band of 5 GHz or more in the third region when the radio frequency circuit 1A supports the third region, like the passband of the filter 51. The filter 51A is not necessarily the low pass filter and may be a band pass filter.

The filter 52A is an example of the second filter and has a passband (an example of the second passband) higher than the passband of the filter 51A. One end of the filter 52A is connected to the switch 61A and the other end of the filter 52A is connected to the filter 55A.

In the second exemplary embodiment, the high pass filter is used as the filter 52A, like the filter 52. At this time, a frequency lower than or equal to the lower limit frequency of the 6-GHz licensed band in a certain region in which the 6-GHz licensed band is capable of being used is usable as the cutoff frequency of the high pass filter. Specifically, the passband of the filter 52A at least includes the 6-GHz licensed band in the second region when the radio frequency circuit 1A supports the second region and at least includes the 6-GHz licensed band in the third region when the radio frequency circuit 1A supports the third region, like the passband of the filter 52. The filter 52A is not necessarily the high pass filter and may be a band pass filter.

The filter 53A is an example of the third filter and is a band pass filter having a passband (an example of the third passband) including the WLAN band. Specifically, the passband of the filter 53A includes a range that is higher than the lower limit frequency (for example, 5,170 MHZ) of the unlicensed band of 5 GHz or more and that is lower than the upper limit frequency (for example, 7,125 MHz) of the unlicensed band of 5 GHz or more. In other words, the passband of the filter 53A includes the unlicensed band of 5 GHz or more in any region supported by the radio frequency circuit 1A. One end of the filter 53A is connected to the switch 63A and the other end of the filter 53A is connected to the switch 62A.

The filter 54A is an example of the fourth filter and is a band pass filter having a passband (an example of the fourth passband) including the NR-U band. Specifically, the passband of the filter 54A includes a range that is higher than the lower limit frequency (for example, 5,170 MHZ) of the unlicensed band of 5 GHz or more and that is lower than the upper limit frequency (for example, 7,125 MHZ) of the unlicensed band of 5 GHz or more. In other words, the passband of the filter 54A includes the unlicensed band of 5 GHz or more in any region supported by the radio frequency circuit 1A. One end of the filter 54A is connected to the switch 64A and the other end of the filter 54A is connected to terminal 312A of the divider 31A.

The filter 55A is an example of the fifth filter and is a band pass filter having a passband (an example of the fifth passband) including the 6-GHz licensed band. Specifically, the passband of the filter 55A includes a range that is higher than the lower limit frequency (for example, 5,925 MHz) of the 6-GHz licensed band and that is lower than the upper limit frequency (for example, 7,125 MHz) of the 6-GHz licensed band. In other words, the passband of the filter 55A includes the 6-GHz licensed band in any region supported by the radio frequency circuit 1A. One end of the filter 55A is connected to the switch 65A and the other end of the filter 55A is connected to the other end of the filter 52A.

Each of the filters 51A to 55A may be composed of any of a SAW filter, a BAW filter, an LC filter, and a dielectric filter and is not limited to these filters.

The switch 61A is an example of the first switch and includes three terminals 611A to 613A. The terminal 611A is an example of the first terminal and is connected to the antenna connection terminal 101. The terminal 612A is an example of the second terminal and is connected to the terminal 311A of the divider 31A. The terminal 613A is an example of the third terminal and is connected to one end of the filter 51A and one end of the filter 52A.

In this connection configuration, the switch 61A is capable of exclusively connecting the terminal 611A to the terminals 612A and 613A based on, for example, a control signal from the RFIC 3. The switch 61A is composed of, for example, an SPDT switch circuit.

The switch 62A is an example of the second switch and includes three terminals 621A to 623A. The terminal 621A is an example of the first terminal and is connected to the filter 53A. The terminal 622A is an example of the second terminal and is connected to the terminal 313A of the divider 31A. The terminal 623A is an example of the third terminal and is connected to the other end of the filter 51A.

In this connection configuration, the switch 62A is capable of exclusively connecting the terminal 621A to the terminals 622A and 623A based on, for example, the control signal from the RFIC 3. The switch 62A is composed of, for example, an SPDT switch circuit.

The switch 63A is an example of the third switch and includes four terminals 631A to 634A. The terminal 631A is an example of the first terminal and is connected to one end of the filter 53A. The terminal 632A is an example of the second terminal and is connected to the output end of the power amplifier 11A. The terminal 633A is an example of the third terminal and is connected to the input end of the low-noise amplifier 21A. The terminal 634A is an example of the fourth terminal and is connected to the antenna connection terminal 102.

In this connection configuration, the switch 63A is capable of exclusively connecting the terminal 631A to the terminals 632A and 633A and is capable of exclusively connecting the terminal 634A to the terminals 632A and 633A based on, for example, the control signal from the RFIC 3. The switch 63A is composed of, for example, a DPDT switch circuit.

The switch 64A is an example of the fourth switch and includes three terminals 641A to 643A. The terminal 641A is an example of the first terminal and is connected to one end of the filter 54A. The terminal 642A is an example of the second terminal and is connected to the output end of the power amplifier 12A. The terminal 643A is an example of the third terminal and is connected to the input end of the low-noise amplifier 22A.

In this connection configuration, the switch 64A is capable of exclusively connecting the terminal 641A to the terminals 642A and 643A based on, for example, the control signal from the RFIC 3. The switch 64A is composed of, for example, an SPDT switch circuit.

The switch 65A is an example of the fifth switch and includes three terminals 651A to 653A. The terminal 651A is an example of the first terminal and is connected to one end of the filter 55A. The terminal 652A is an example of the second terminal and is connected to the output end of the power amplifier 13A. The terminal 653A is an example of the third terminal and is connected to the input end of the low-noise amplifier 23A.

In this connection configuration, the switch 65A is capable of exclusively connecting the terminal 651A to the terminals 652A and 653A based on, for example, the control signal from the RFIC 3. The switch 65A is composed of, for example, an SPDT switch circuit.

The radio frequency circuit 1A illustrated in FIG. 8 is only an example and is not limited to this. For example, the radio frequency circuit 1A does not necessarily include the reception path. Specifically, the radio frequency circuit 1A does not necessarily include the low-noise amplifiers 21A to 23A, the switches 63A to 65A, and the radio-frequency output terminals 121 to 123. For example, the radio frequency circuit 1A does not necessarily include the transmission path. Specifically, the radio frequency circuit 1A does not necessarily include the power amplifiers 11A to 13A, the switches 63A to 65A, and the radio-frequency input terminals 111 to 113. In this case, the low-noise amplifier 21A is an example of the first amplifier, the low-noise amplifier 22A is an example of the second amplifier, the low-noise amplifier 23A is an example of the third amplifier, and the radio-frequency output terminals 121 to 123 are examples of the first to third input-output terminals, respectively.

In addition, for example, the radio frequency circuit 1A does not necessarily include the antenna connection terminal 102. In this case, the switch 63A does not necessarily have the terminal 634A. The switch connected to the antenna connection terminal 102 is not limited to the switch 63A. For example, the switch 61A may have a terminal connected to the antenna connection terminal 102. In this case, the terminal connected to the antenna connection terminal 102 may be exclusively connected to the terminals 612A and 613A.

### 2.3 Connection States and Flows of Radio Frequency Signal in the Radio Frequency Circuit 1A

Next, specific examples of connection states and the flows of the radio frequency signal in the respective connection states in the radio frequency circuit 1A according to the second exemplary embodiment will be described.

### 2.3.1 Connection State and Flow of Radio Frequency Signal for Transmission in First Region

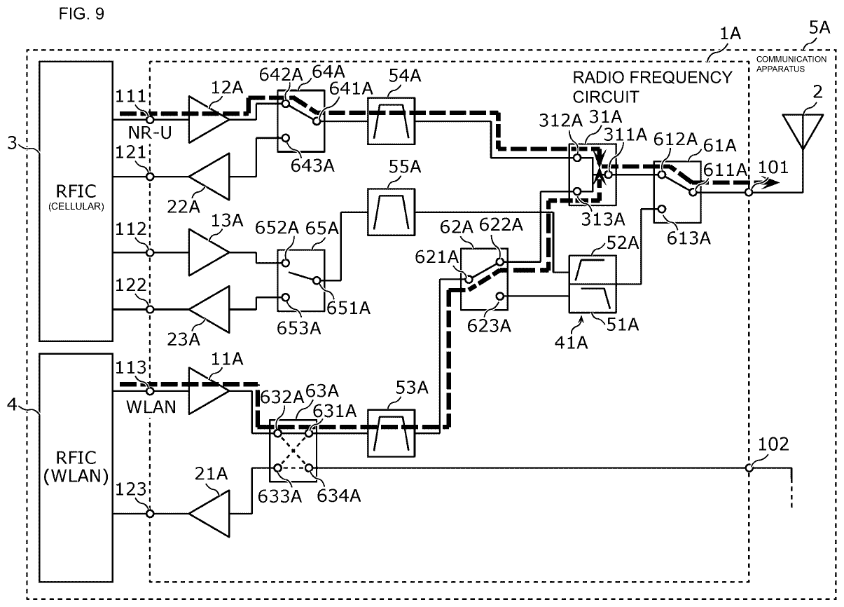

First, the connection state and the flow of the radio frequency signal for transmission in the first region will be described with reference to FIG. 9. FIG. 9 is a diagram illustrating the connection state and the flow of the radio frequency signal for transmission in the first region in the radio frequency circuit 1A according to the second embodiment.

The 6-GHz licensed band is not used and the NR-U band and the WLAN band are used in the first region, as illustrated in FIG. 1. Accordingly, the RFIC 3 controls each switch in the radio frequency circuit 1A to transmit the signals in the NR-U band and the WLAN band using the divider 31A in FIG. 9. Specifically, the switch 61A connects the terminal 611A to the terminal 612A, the switch 62A connects the terminal 621A to the terminal 622A, the switch 63A connects the terminal 631A to the terminal 632A, and the switch 64A connects the terminal 641A to the terminal 642A.

As a result, the transmission signal in the NR-U band is transmitted from the radio-frequency input terminal 111 to the divider 31A via the power amplifier 12A, the switch 64A, and the filter 54A. The transmission signal in the WLAN band is transmitted from the radio-frequency input terminal 113 to the divider 31A via the power amplifier 11A, the switch 63A, the filter 53A, and the switch 62A. The transmission signal in the NR-U band is combined with the transmission signal in the WLAN band in the divider 31A. The transmission signal combined in the divider 31A is transmitted to the antenna connection terminal 101 via the switch 61A.

The signals in the NR-U band and the WLAN band received from the RFICs 3 and 4, respectively, are transmitted from the antenna 2.

### 2.3.2 Connection State and Flow of Radio Frequency Signal for Reception in First Region

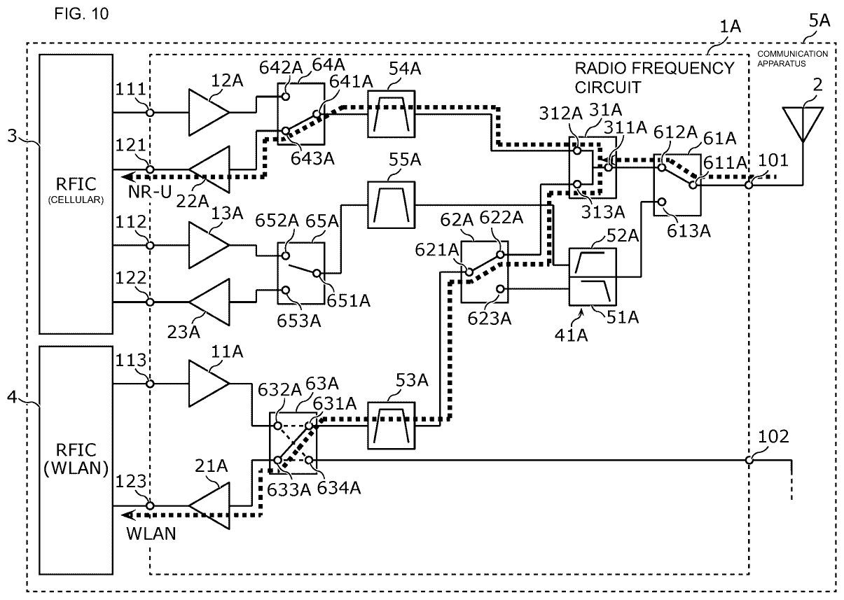

Next, the connection state and the flow of the radio frequency signal for reception in the first region will be described with reference to FIG. 10. FIG. 10 is a diagram illustrating the connection state and the flow of the radio frequency signal for reception in the first region in the radio frequency circuit 1A according to the second exemplary embodiment.

The 6-GHz licensed band is not used and the NR-U band and the WLAN band are used in the first region, as illustrated in FIG. 1. Accordingly, the RFIC 3 controls each switch in the radio frequency circuit 1A to receive the signals in the NR-U band and the WLAN band using the divider 31A in FIG. 10. Specifically, the switch 61A connects the terminal 611A to the terminal 612A, the switch 62A connects the terminal 621A to the terminal 622A, the switch 63A connects the terminal 631A to the terminal 633A, and the switch 64A connects the terminal 641A to the terminal 643A.

As a result, the reception signals in the NR-U band and the WLAN band are transmitted from the antenna connection terminal 101 to the divider 31A via the switch 61A. The reception signals in the NR-U band and the WLAN band are divided in the divider 31A. One of the divided reception signals is transmitted to the radio-frequency output terminal 121 via the filter 54A, the switch 64A, and the low-noise amplifier 22A. The other of the divided reception signals is transmitted to the radio-frequency output terminal 123 via the switch 62A, the filter 53A, the switch 63A, and the low-noise amplifier 21A.

The signals in the NR-U band and the WLAN band received through the antenna 2 are supplied to the RFICs 3 and 4, respectively.

### 2.3.3 Connection State and Flow of Radio Frequency Signal for Transmission in Second Region or Third Region

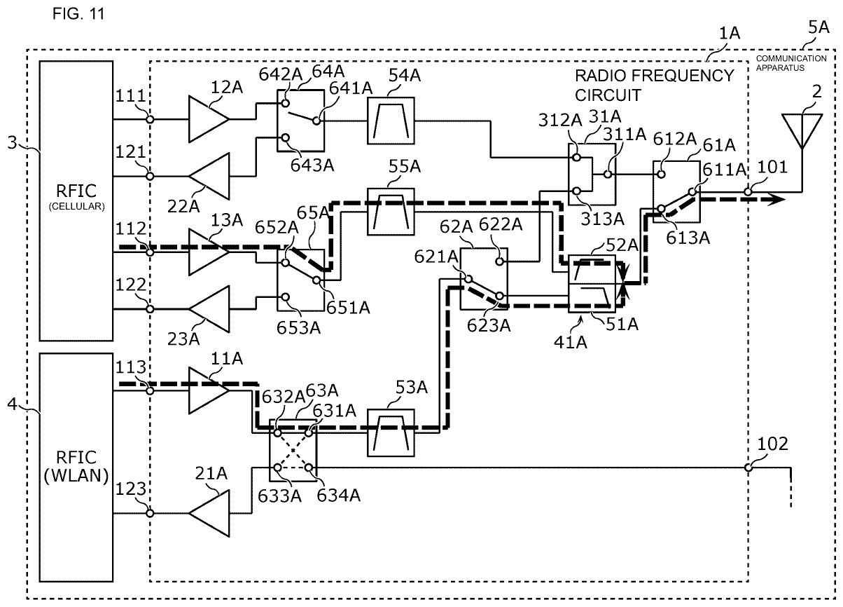

Next, the connection state and the flow of the radio frequency signal for transmission in the second region or the third region will be described with reference to FIG. 11. FIG. 11 is a diagram illustrating the connection state and the flow of the radio frequency signal for transmission in the second region or the third region in the radio frequency circuit 1A according to the second exemplary embodiment.

The 6-GHz licensed band is used in the second region and the third region, as illustrated in FIG. 1. Accordingly, the RFIC 3 controls each switch in the radio frequency circuit 1A to transmit the signals in the 6-GHz licensed band and the WLAN band using the multiplexer 41A in FIG. 11. Specifically, the switch 61A connects the terminal 611A to the terminal 613A, the switch 62A connects the terminal 621A to the terminal 623A, the switch 63A connects the terminal 631A to the terminal 632A, and the switch 65A connects the terminal 651A to the terminal 652A.

As a result, the transmission signal in the 6-GHz licensed band is transmitted from the radio-frequency input terminal 112 to the multiplexer 41A via the power amplifier 13A, the switch 65A, and the filter 55A. The transmission signal in the WLAN band is transmitted from the radio-frequency input terminal 113 to the multiplexer 41A via the power amplifier 11A, the switch 63A, the filter 53A, and the switch 62A. The transmission signal in the 6-GHz licensed band is multiplexed with the transmission signal in the WLAN band in the multiplexer 41A. The transmission signal multiplexed in the multiplexer 41A is transmitted to the antenna connection terminal 101 via switch 61A.

The signals in the 6-GHz licensed band and the WLAN band received from the RFICs 3 and 4, respectively, are transmitted from the antenna 2.

### 2.3.4 Connection State and Flow of Radio Frequency Signal for Reception in Second Region or Third Region

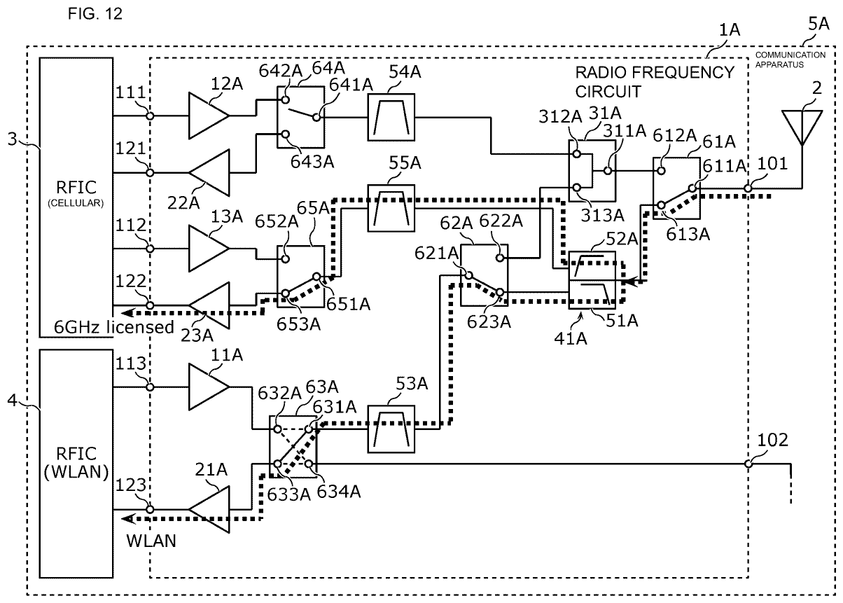

Next, the connection state and the flow of the radio frequency signal for reception in the second region or the third region will be described with reference to FIG. 12. FIG. 12 is a diagram illustrating the connection state and the flow of the radio frequency signal for reception in the second region or the third region in the radio frequency circuit 1A according to the second exemplary embodiment.

The 6-GHz licensed band is used in the second region and the third region, as illustrated in FIG. 1. Accordingly, the RFIC 3 controls each switch in the radio frequency circuit 1A to receive the signals in the 6-GHz licensed band and the WLAN band using the multiplexer 41A in FIG. 12. Specifically, the switch 61A connects the terminal 611A to the terminal 613A, the switch 62A connects the terminal 621A to the terminal 623A, the switch 63A connects the terminal 631A to the terminal 633A, and the switch 65A connects the terminal 651A to the terminal 653A.

As a result, the reception signals in the 6-GHz licensed band and the WLAN band are transmitted from the antenna connection terminal 101 to the multiplexer 41A via the switch 61A. The reception signals in the 6-GHz licensed band and the WLAN band are demultiplexed into the reception signal in the 6-GHz licensed band and the reception signal in the WLAN band in the multiplexer 41A. The reception signal in the 6-GHz licensed band demultiplexed in the multiplexer 41A is transmitted to the radio-frequency output terminal 122 via the filter 55A, the switch 65A, and the low-noise amplifier 23A. The reception signal in the WLAN band demultiplexed in the multiplexer 41A is transmitted to the radio-frequency output terminal 123 via the switch 62A, the filter 53A, the switch 63A, and the low-noise amplifier 21A.

The signals in the 6-GHz licensed band and the WLAN band received through the antenna 2 are supplied to the RFICs 3 and 4, respectively.

### 2.4 Advantages

As described above, the radio frequency circuit 1A according to the second exemplary embodiment includes the divider 31A including the first terminal, the second terminal, and the third terminal; the multiplexer 41A including the filter 51A having the first passband and the filter 52A having the second passband higher than the first passband; the switch 61A including the first terminal, the second terminal connected to the first terminal of the divider 31A, and the third terminal connected to one end of the filter 51A and one end of the filter 52A; the switch 62A including the first terminal, the second terminal connected to the third terminal of the divider 31A, and the third terminal connected to the other end of the filter 51A; the filter 53A having the third passband including the WLAN band of 5 GHz or more; and the first amplifier (the power amplifier 11A or the low-noise amplifier 21A) connected to one end of the filter 53A. The first terminal of the switch 62A is connected to the other end of the filter 53A.

With the above configuration, the connection of the filter 53A is capable of being switched between the divider 31A and the multiplexer 41A using the switch 62A. Accordingly, it is possible to use the multiplexer 41A, instead of the divider 31A causing loss of 3 dB, for transmission or reception to improve the quality of transmission signals or the receiving sensibility, compared with that of the radio frequency circuit 901 according to the comparative example.

For example, in the radio frequency circuit 1A according to the second exemplary embodiment, the first terminal of the switch 62A may be connected to the other end of the filter 53A. The radio frequency circuit 1A may further include the antenna connection terminal 101 connected to the first terminal of the switch 61A; the first input-output terminal (the radio-frequency input terminal 111 or the radio-frequency output terminal 121) for the NR-U band; the second input-output terminal (the radio-frequency input terminal 112 or the radio-frequency output terminal 122) for the 6-GHz licensed band; the third input-output terminal (the radio-frequency input terminal 113 or the radio-frequency output terminal 123) that is for the WLAN band and that is connected to the first amplifier (the power amplifier 11A or the low-noise amplifier 21A); the filter 54A having the fourth passband including the NR-U band; the second amplifier (the power amplifier 12A or the low-noise amplifier 22A) connected between the first input-output terminal and one end of the filter 54A; the filter 55A having the fifth passband including the 6-GHz licensed band; and the third amplifier (the power amplifier 13A or the low-noise amplifier 23A) connected between the second input-output terminal and one end of the filter 55A. The second terminal of the divider 31A may be connected to the other end of the filter 54A. The other end of the filter 52A may be connected to the other end of the filter 55A.

With the above configuration, the multiplexer 41A is connected between the antenna connection terminal 101 and the filters 53A to 55A via the switches 61A and 62A. Accordingly, the use of the multiplexer 41A enables the power loss to be reduced in transmission or reception of the signals in the 6-GHz licensed band and the WLAN band to improve the quality of transmission signals or the receiving sensibility. In addition, it is possible to use the divider 31A, the multiplexer 41A, and the switches 61A and 62A in both transmission and reception to contribute to a reduction in the number of components.

For example, in the radio frequency circuit 1A according to the second exemplary embodiment, the first amplifier may be the power amplifier 11A, the second amplifier may be the power amplifier 12A, the third amplifier may be the power amplifier 13A, the first input-output terminal may be the radio-frequency input terminal 111 for receiving the transmission signal in the NR-U band from the outside of the radio frequency circuit 1A, the second input-output terminal may be the radio-frequency input terminal 112 for receiving the transmission signal in the 6-GHz licensed band from the outside of the radio frequency circuit 1A, and the third input-output terminal may be the radio-frequency input terminal 113 for receiving the transmission signal in the WLAN band from the outside of the radio frequency circuit 1A.

With the above configuration, the use of the multiplexer 41A enables the power loss to be reduced in transmission of the signals in the 6-GHz licensed band and the WLAN band to improve the quality of transmission signals. In particular, since the output power higher than that of the NR-U band is required in transmission of the signal in the 6-GHz licensed band, the effect of improving the quality of the transmission signals due to the reduction in the power loss is high.

For example, the radio frequency circuit 1A according to the second exemplary embodiment may further include the radio-frequency output terminal 121 for supplying the reception signal in the NR-U band to the outside of the radio frequency circuit 1A; the radio-frequency output terminal 122 for supplying the reception signal in the 6-GHz licensed band to the outside of the radio frequency circuit 1A; the radio-frequency output terminal 123 for supplying the reception signal in the WLAN band to the outside of the radio frequency circuit 1A; the low-noise amplifier 21A connected between the radio-frequency output terminal 123 and one end of the filter 53A; the switch 63A including the first terminal connected to one end of the filter 53A, the second terminal connected to the output end of the power amplifier 11A, and the third terminal connected to the input end of the low-noise amplifier 21A; the low-noise amplifier 22A connected between the radio-frequency output terminal 121 and one end of the filter 54A; the switch 64A including the first terminal connected to one end of the filter 54A, the second terminal connected to the output end of the power amplifier 12A, and the third terminal connected to the input end of the low-noise amplifier 22A; the low-noise amplifier 23A connected between the radio-frequency output terminal 122 and one end of the filter 55A; and the switch 65A including the first terminal connected to one end of the filter 55A, the second terminal connected to the output end of the power amplifier 13A, and the third terminal connected to the input end of the low-noise amplifier 23A.

With the above configuration, the use of the multiplexer 41A enables the power loss to be reduced in reception of the signals in the 6-GHz licensed band and the WLAN band, in addition to transmission of the signals in the 6-GHz licensed band and the WLAN band, to improve the receiving sensibility, in addition to the quality of transmission signals.

For example, the radio frequency circuit 1A according to the second exemplary embodiment may further include the antenna connection terminal 102. The switch 63A may further include the fourth terminal connected to the antenna connection terminal 102.

With the above configuration, the antenna connection terminals 101 and 102 are capable of being selected using the switch 63A. Accordingly, the antenna to be used in transmission or reception is capable of being swapped to improve the quality of transmission signals and the receiving sensibility. For example, when a diversity antenna is connected to the antenna connection terminal 102 via a diversity circuit, the signal (for example, the SRS or the like) transmitted through the diversity antenna is capable of being amplified by the power amplifier 11A in the radio frequency circuit 1A. Accordingly, in such a case, the power amplifier in the diversity circuit may be omitted.

For example, in the radio frequency circuit 1A according to the second exemplary embodiment, the first amplifier may be the low-noise amplifier 21A, the second amplifier may be the low-noise amplifier 22A, the third amplifier may be the low-noise amplifier 23A, the first input-output terminal may be the radio-frequency output terminal 121 for supplying the reception signal in the NR-U band to the outside of the radio frequency circuit 1A, the second input-output terminal may be the radio-frequency output terminal 122 for supplying the reception signal in the 6-GHz licensed band to the outside of the radio frequency circuit 1A, and the third input-output terminal may be the radio-frequency output terminal 123 for supplying the reception signal in the WLAN band to the outside of the radio frequency circuit 1A.

With the above configuration, the use of the multiplexer 41A enables the power loss to be reduced in reception of the signals in the 6-GHz licensed band and the WLAN band to improve the receiving sensibility.

For example, in the radio frequency circuit 1A according to the second exemplary embodiment, the filter 51A may be a low pass filter having the cutoff frequency higher than or equal to the upper limit frequency of the WLAN band in a certain region in which the 6-GHz licensed band is capable of being used. The filter 52A may be a high pass filter having the cutoff frequency lower than or equal to the lower limit frequency of the 6-GHz licensed band in the certain region.

With the above configuration, the signal in the 6-GHz licensed band and the signal in the WLAN band are capable of being efficiently multiplexed and/or demultiplexed with the multiplexer 41A to improve the quality of transmission signals and/or the receiving sensibility.

### Third Embodiment

Next, a third exemplary embodiment will be described. The third exemplary embodiment mainly differs from the second exemplary embodiment described above in that the NR-U band and the 6-GHz licensed band uses a common path. The third exemplary embodiment will be described below, focusing on points different from the second exemplary embodiment described above.

### 3.1 Circuit Configuration of Communication Apparatus 5B

The circuit configuration of a communication apparatus 5B according to the third exemplary embodiment is the same as that of the communication apparatus 5A according to the second exemplary embodiment described above excluding inclusion of a radio frequency circuit 1B, instead of the radio frequency circuit 1A. Accordingly, description of the circuit configuration of the communication apparatus 5B is omitted herein, excluding the description of the radio frequency circuit 1B.

### 3.2 Circuit Configuration of Radio Frequency Circuit 1B

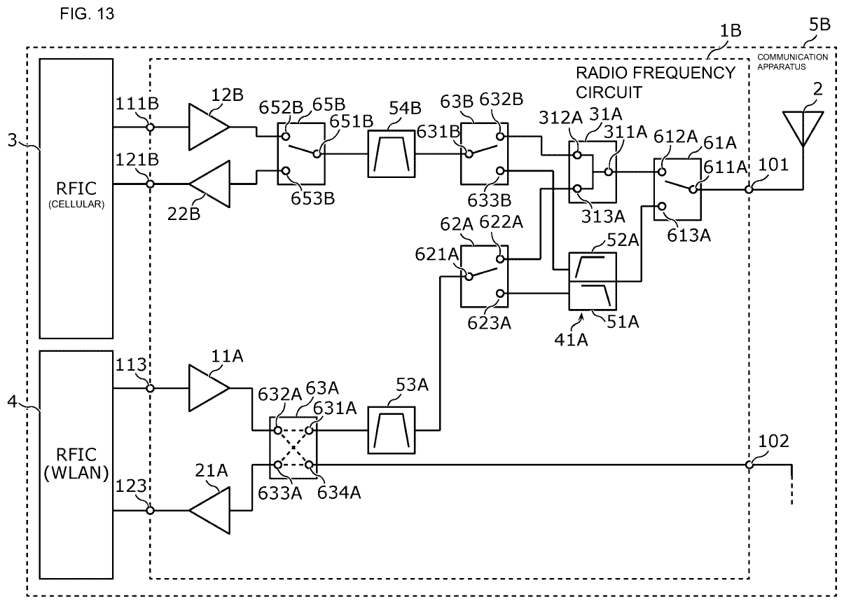

The circuit configuration of the radio frequency circuit 1B according to the third exemplary embodiment will be described with reference to FIG. 13. FIG. 13 is a diagram illustrating the circuit configuration of the communication apparatus 5B according to the third exemplary embodiment.

The radio frequency circuit 1B includes the power amplifier 11A and a power amplifier 12B, the low-noise amplifier 21A and a low-noise amplifier 22B, the divider 31A, the multiplexer 41A, the filter 53A and a filter 54B, the switches 61A to 63A and switches 63B and 65B, the antenna connection terminals 101 and 102, a radio-frequency input terminal 111B and the radio-frequency input terminal 113, and a radio-frequency output terminal 121B and the radio-frequency output terminal 123. The components in the radio frequency circuit 1B will be described, focusing on points different from the radio frequency circuit 1A.

The radio-frequency input terminal 111B is an example of the first input-output terminal and the first input terminal and is a terminal for receiving the transmission signals in the NR-U band and the 6-GHz licensed band from the outside of the radio frequency circuit 1B. Referring to FIG. 13, the radio-frequency input terminal 111B is connected to the RFIC 3 outside the radio frequency circuit 1B and is connected to an input end of the power amplifier 12B in the radio frequency circuit 1B.

The radio-frequency output terminal 121B is an example of the first output terminal and is a terminal for supplying the reception signals in the NR-U band and the 6-GHz licensed band to the outside of the radio frequency circuit 1B. Referring to FIG. 13, the radio-frequency output terminal 121B is connected to the RFIC 3 outside the radio frequency circuit 1B and is connected to an output end of the low-noise amplifier 22B in the radio frequency circuit 1B.

In the third exemplary embodiment, the radio-frequency input terminal 113 is an example of the second input-output terminal and the second input terminal and the radio-frequency output terminal 123 is an example of the second output terminal.

The power amplifier 12B is an example of the second amplifier and the second power amplifier and is connected between the radio-frequency input terminal 111B and the filter 54B. Specifically, the input end of the power amplifier 12B is connected to the radio-frequency input terminal 111B and an output end of the power amplifier 12B is connected to the filter 54B via the switch 65B. The power amplifier 12B is capable of amplifying the transmission signals in the NR-U band and the 6-GHz licensed band.

The low-noise amplifier 22B is an example of the second low-noise amplifier and is connected between the filter 54B and the radio-frequency output terminal 121B. Specifically, an input end of the low-noise amplifier 22B is connected to the filter 54B via the switch 65B and an output end of the low-noise amplifier 22B is connected to the radio-frequency output terminal 121B. The low-noise amplifier 22B is capable of amplifying the reception signals in the NR-U band and the 6-GHz licensed band.

The filter 54B is an example of the fourth filter and is a band pass filter having a passband (an example of the fourth passband) including the NR-U band and the 6-GHz licensed band. One end of the filter 54B is connected to the switch 65B and the other end of the filter 54B is connected to the switch 63B. The filter 54B may be any of a SAW filter, a BAW filter, an LC filter, and a dielectric filter and is not limited to these filters.

The switch 63B is an example of the third switch and includes three terminals 631B to 633B. The terminal 631B is an example of the first terminal and is connected to the other end of the filter 54B. The terminal 632B is an example of the second terminal and is connected to the terminal 312A of the divider 31A. The terminal 633B is an example of the third terminal and is connected to the other end of the filter 52A.

In this connection configuration, the switch 63B is capable of exclusively connecting the terminal 631B to the terminals 632B and 633B based on, for example, a control signal from the RFIC 3. The switch 63B is composed of, for example, an SPDT switch circuit.

The switch 65B is an example of the fifth switch and include three terminals 651B to 653B. The terminal 651B is an example of the first terminal and is connected to one end of the filter 54B. The terminal 652B is an example of the second terminal and is connected to the output end of the power amplifier 12B. The terminal 653B is an example of the third terminal and is connected to the input end of the low-noise amplifier 22B.

In this connection configuration, the switch 65B is capable of exclusively connecting the terminal 651B to the terminals 652B and 653B based on, for example, the control signal from the RFIC 3. The switch 65B is composed of, for example, an SPDT switch circuit.

In the third exemplary embodiment, the switch 63A is an example of the fourth switch.

The radio frequency circuit 1B illustrated in FIG. 13 is only an example and is not limited to this. For example, the radio frequency circuit 1B does not necessarily include the reception path. Specifically, the radio frequency circuit 1B does not necessarily include the low-noise amplifiers 21A and 22B, the switches 63A and 65B, and the radio-frequency output terminals 121B and 123. For example, the radio frequency circuit 1B does not necessarily include the transmission path. Specifically, the radio frequency circuit 1B does not necessarily include the power amplifiers 11A and 12B, the switches 63A and 65B, and the radio-frequency input terminals 111B and 113. In this case, the low-noise amplifier 21A is an example of the first amplifier, the low-noise amplifier 22B is an example of the second amplifier, and the radio-frequency output terminals 121B and 123 are examples of the first and second input-output terminals, respectively. In addition, for example, the radio frequency circuit 1B does not necessarily include the antenna connection terminal 102. In this case, the switch 63A does not necessarily have the terminal 634A.

### 3.3 Connection States and Flows of Radio Frequency Signal in the Radio Frequency Circuit 1B

Next, specific examples of connection states and the flows of the radio frequency signal in the respective connection states in the radio frequency circuit 1B according to the third exemplary embodiment will be described.

### 3.3.1 Connection State and Flow of Radio Frequency Signal for Transmission in First Region

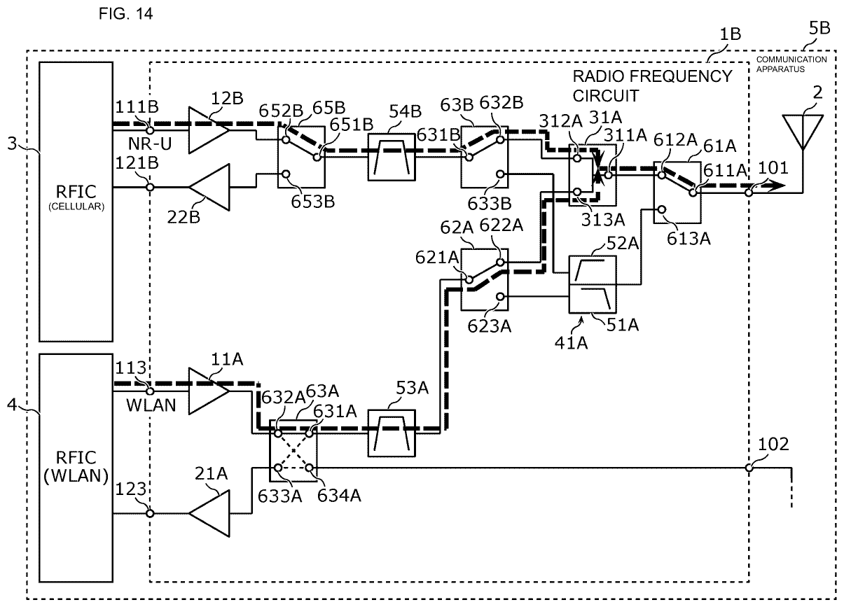

First, the connection state and the flow of the radio frequency signal for transmission in the first region will be described with reference to FIG. 14. FIG. 14 is a diagram illustrating the connection state and the flow of the radio frequency signal for transmission in the first region in the radio frequency circuit 1B according to the third exemplary embodiment.

The 6-GHz licensed band is not used and the NR-U band and the WLAN band are used in the first region, as illustrated in FIG. 1. Accordingly, the RFIC 3 controls each switch in the radio frequency circuit 1B to transmit the signals in the NR-U band and the WLAN band using the divider 31A in FIG. 14. Specifically, the switch 61A connects the terminal 611A to the terminal 612A, the switch 62A connects the terminal 621A to the terminal 622A, the switch 63B connects the terminal 631B to the terminal 632B, the switch 63A connects the terminal 631A to the terminal 632A, and the switch 65B connects the terminal 651B to the terminal 652B.

As a result, the transmission signal in the NR-U band is transmitted from the radio-frequency input terminal 111B to the divider 31A via the power amplifier 12B, the switch 65B, the filter 54B, and the switch 63B. The transmission signal in the WLAN band is transmitted from the radio-frequency input terminal 113 to the divider 31A via the power amplifier 11A, the switch 63A, the filter 53A, and the switch 62A. The transmission signal in the NR-U band is combined with the transmission signal in the WLAN band in the divider 31A. The transmission signal combined in the divider 31A is transmitted to the antenna connection terminal 101 via the switch 61A.

The signals in the NR-U band and the WLAN band received from the RFICs 3 and 4, respectively, are transmitted from the antenna 2.

### 3.3.2 Connection State and Flow of Radio Frequency Signal for Reception in First Region

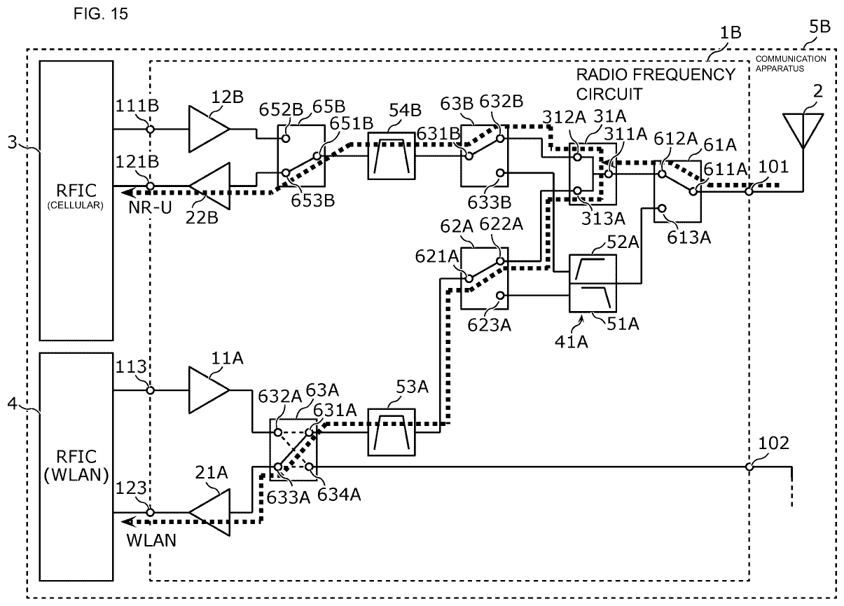

Next, the connection state and the flow of the radio frequency signal for reception in the first region will be described with reference to FIG. 15. FIG. 15 is a diagram illustrating the connection state and the flow of the radio frequency signal for reception in the first region in the radio frequency circuit 1B according to the third exemplary embodiment.

The 6-GHz licensed band is not used and the NR-U band and the WLAN band are used in the first region, as illustrated in FIG. 1. Accordingly, the RFIC 3 controls each switch in the radio frequency circuit 1B to receive the signals in the NR-U band and the WLAN band using the divider 31A in FIG. 15. Specifically, the switch 61A connects the terminal 611A to the terminal 612A, the switch 62A connects the terminal 621A to the terminal 622A, the switch 63B connects the terminal 631B to the terminal 632B, the switch 63A connects the terminal 631A to the terminal 633A, and the switch 65B connects the terminal 651B to the terminal 653B.

As a result, the reception signals in the NR-U band and the WLAN band are transmitted from the antenna connection terminal 101 to the divider 31A via the switch 61A. The reception signals in the NR-U band and the WLAN band are divided in the divider 31A. One of the divided reception signals is transmitted to the radio-frequency output terminal 121B via the switch 63B, the filter 54B, the switch 65B, and the low-noise amplifier 22B. The other of the divided reception signals is transmitted to the radio-frequency output terminal 123 via the switch 62A, the filter 53A, the switch 63A, and the low-noise amplifier 21A.

The signals in the NR-U band and the WLAN band received through the antenna 2 are supplied to the RFICs 3 and 4, respectively.

### 3.3.3 Connection State and Flow of Radio Frequency Signal for Transmission in Second Region or Third Region

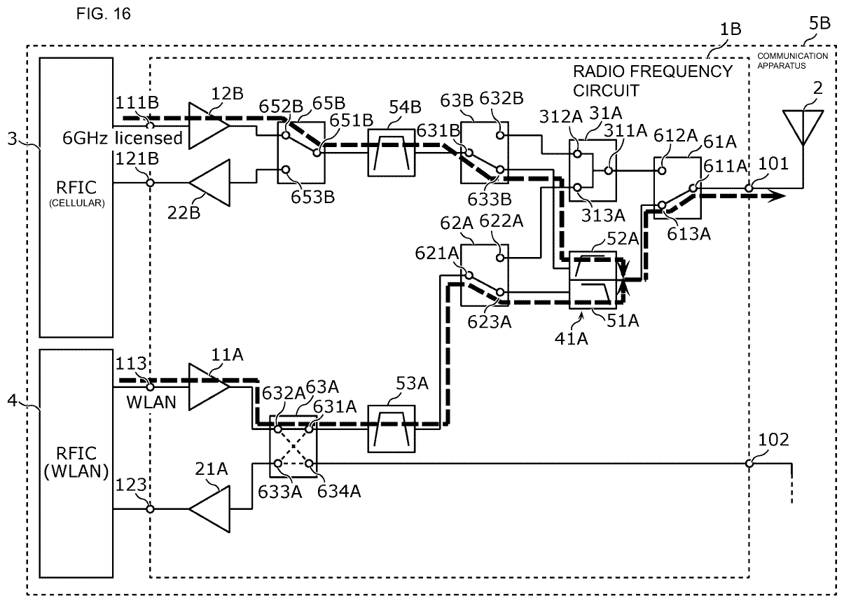

Next, the connection state and the flow of the radio frequency signal for transmission in the second region or the third region will be described with reference to FIG. 16. FIG. 16 is a diagram illustrating the connection state and the flow of the radio frequency signal for transmission in the second region or the third region in the radio frequency circuit 1B according to the third exemplary embodiment.

The 6-GHz licensed band is used in the second region and the third region, as illustrated in FIG. 1. Accordingly, the RFIC 3 controls each switch in the radio frequency circuit 1B to transmit the signals in the 6-GHz licensed band and the WLAN band using the multiplexer 41A in FIG. 16. Specifically, the switch 61A connects the terminal 611A to the terminal 613A, the switch 62A connects the terminal 621A to the terminal 623A, the switch 63B connects the terminal 631B to the terminal 633B, the switch 63A connects the terminal 631A to the terminal 632A, and the switch 65B connects the terminal 651B to the terminal 652B.

As a result, the transmission signal in the 6-GHz licensed band is transmitted from the radio-frequency input terminal 111B to the multiplexer 41A via the power amplifier 12B, the switch 65B, the filter 54B, and the switch 63B. The transmission signal in the WLAN band is transmitted from the radio-frequency input terminal 113 to the multiplexer 41A via the power amplifier 11A, the switch 63A, the filter 53A, and the switch 62A. The transmission signal in the 6-GHz licensed band is multiplexed with the transmission signal in the WLAN band in the multiplexer 41A. The transmission signal multiplexed in the multiplexer 41A is transmitted to the antenna connection terminal 101 via switch 61A.

The signals in the 6-GHz licensed band and the WLAN band received from the RFICs 3 and 4, respectively, are transmitted from the antenna 2.

### 3.3.4 Connection State and Flow of Radio Frequency Signal for Reception in Second Region or Third Region

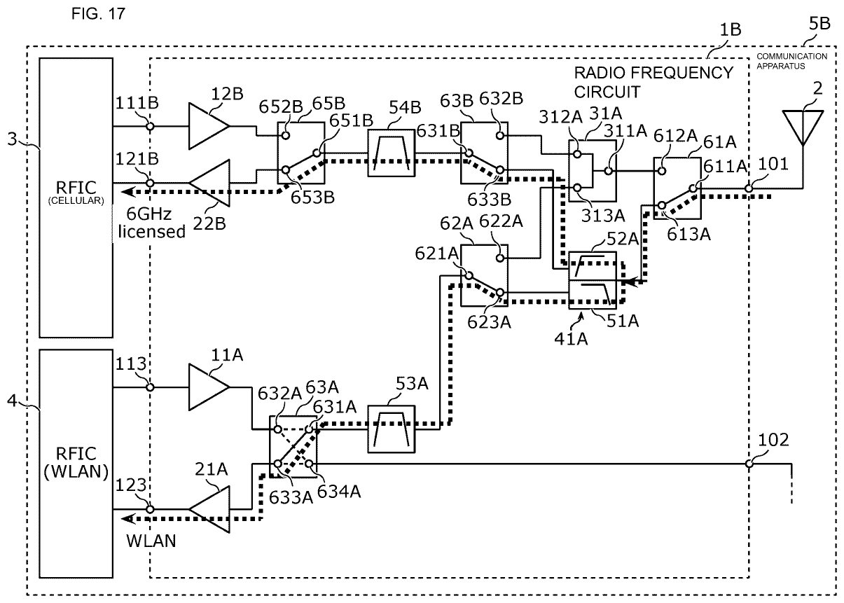

Next, the connection state and the flow of the radio frequency signal for reception in the second region or the third region will be described with reference to FIG. 17. FIG. 17 is a diagram illustrating the connection state and the flow of the radio frequency signal for reception in the second region or the third region in the radio frequency circuit 1B according to the third exemplary embodiment.

The 6-GHz licensed band is used in the second region and the third region, as illustrated in FIG. 1. Accordingly, the RFIC 3 controls each switch in the radio frequency circuit 1B to receive the signals in the 6-GHz licensed band and the WLAN band using the multiplexer 41A in FIG. 17. Specifically, the switch 61A connects the terminal 611A to the terminal 613A, the switch 62A connects the terminal 621A to the terminal 623A, the switch 63B connects the terminal 631B to the terminal 633B, the switch 63A connects the terminal 631A to the terminal 633A, and the switch 65B connects the terminal 651B to the terminal 653B.

As a result, the reception signals in the 6-GHz licensed band and the WLAN band are transmitted from the antenna connection terminal 101 to the multiplexer 41A via the switch 61A. The reception signals in the 6-GHz licensed band and the WLAN band are demultiplexed into the reception signal in the 6-GHz licensed band and the reception signal in the WLAN band in the multiplexer 41A. The reception signal in the 6-GHz licensed band demultiplexed in the multiplexer 41A is transmitted to the radio-frequency output terminal 121B via switch 63B, the filter 54B, the switch 65B, and the low-noise amplifier 22B. The reception signal in the WLAN band demultiplexed in the multiplexer 41A is transmitted to the radio-frequency output terminal 123 via the switch 62A, the filter 53A, the switch 63A, and the low-noise amplifier 21A.

The signals in the 6-GHz licensed band and the WLAN band received through the antenna 2 are supplied to the RFICs 3 and 4, respectively.

### 3.4 Exemplary Advantages

As described above, the radio frequency circuit 1B according to the third exemplary embodiment includes the divider 31A including the first terminal, the second terminal, and the third terminal; the multiplexer 41A including the filter 51A having the first passband and the filter 52A having the second passband higher than the first passband; the switch 61A including the first terminal, the second terminal connected to the first terminal of the divider 31A, and the third terminal connected to one end of the filter 51A and one end of the filter 52A; the switch 62A including the first terminal, the second terminal connected to the third terminal of the divider 31A, and the third terminal connected to the other end of the filter 51A; the filter 53A having the third passband including the WLAN band amplifier 11A or the low-noise amplifier 21A) connected to one end of the filter 53A. The first terminal of the switch 62A is connected to the other end of the filter 53A.

With the above configuration, the connection of the filter 53A is capable of being switched between the divider 31A and the multiplexer 41A using the switch 62A. Accordingly, it is possible to use the multiplexer 41A, instead of the divider 31A causing loss of 3 dB, for transmission or reception to improve the quality of transmission signals or the receiving sensibility, compared with that of the radio frequency circuit 901 according to the comparative example.

For example, in the radio frequency circuit 1B according to the third exemplary embodiment, the first terminal of the switch 62A may be connected to the other end of the filter 53A. The radio frequency circuit 1B may further include the antenna connection terminal 101 connected to the first terminal of the switch 61A; the first input-output terminal (the radio-frequency input terminal 111B or the radio-frequency output terminal 121B) for the NR-U band and the 6-GHz licensed band; the second input-output terminal (the radio-frequency input terminal 113 or the radio-frequency output terminal 123) that is for the WLAN band and that is connected to the first amplifier (the power amplifier 11A or the low-noise amplifier 21A); the filter 54B having the fourth passband including the NR-U band and the 6-GHz licensed band; the second amplifier (the power amplifier 12B or the low-noise amplifier 22B) connected between the first input-output terminal (the radio-frequency input terminal 111B or the radio-frequency output terminal 121B) and one end of the filter 54B; and the switch 63B including the first terminal connected to the other end of the filter 54B, the second terminal connected to the second terminal of the divider 31A, and the third terminal connected to the other end of the filter 52A.

With the above configuration, the multiplexer 41A is connected between the antenna connection terminal 101 and the filters 53A and 54B via the switches 61A and 62A. Accordingly, the use of the multiplexer 41A enables the power loss to be reduced in transmission or reception of the signals in the 6-GHz licensed band and the WLAN band to improve the quality of transmission signals or the receiving sensibility. In addition, it is possible to use the divider 31A, the multiplexer 41A, and the switches 61A and 62A in both transmission and reception to contribute to a reduction in the number of components.

For example, in the radio frequency circuit 1B according to the third exemplary embodiment, the first amplifier may be the power amplifier 11A, the second amplifier may be the power amplifier 12B, the first input-output terminal may be the radio-frequency input terminal 111B for receiving the transmission signals in the NR-U band and the 6-GHz licensed band from the outside of the radio frequency circuit 1B, and the second input-output terminal may be the radio-frequency input terminal 113 for receiving the transmission signal in the WLAN band from the outside of the radio frequency circuit 1B.

With the above configuration, the use of the multiplexer 41A enables the power loss to be reduced in transmission of the signals in the 6-GHz licensed band and the WLAN band to improve the quality of transmission signals. In particular, since the output power higher than that of the NR-U band is required in transmission of the signal in the 6-GHz licensed band, the effect of improving the quality of the transmission signals due to the reduction in the power loss is high.

For example, the radio frequency circuit 1B according to the third exemplary embodiment may further include the radio-frequency output terminal 121B for supplying the reception signals in the NR-U band and the 6-GHz licensed band to the outside of the radio frequency circuit 1B; the radio-frequency output terminal 123 for supplying the reception signal in the WLAN band to the outside of the radio frequency circuit 1B; the low-noise amplifier 21A connected between the radio-frequency output terminal 123 and one end of the filter 53A; the switch 63A including the first terminal connected to one end of the filter 53A, the second terminal connected to the output end of the power amplifier 11A, and the third terminal connected to the input end of the low-noise amplifier 21A; the low-noise amplifier 22B connected between the radio-frequency output terminal 121B and one end of the filter 54B; and the switch 65B including the first terminal connected to one end of the filter 54B, the second terminal connected to the output end of the power amplifier 12B, and the third terminal connected to the input end of the low-noise amplifier 22B.

With the above configuration, the use of the multiplexer 41A enables the power loss to be reduced in reception of the signals in the 6-GHz licensed band and the WLAN band, in addition to transmission of the signals in the 6-GHz licensed band and the WLAN band, to improve the receiving sensibility, in addition to the quality of transmission signals.

For example, the radio frequency circuit 1B according to the third exemplary embodiment may further include the antenna connection terminal 102. The switch 63A may further include the fourth terminal connected to the antenna connection terminal 102.

With the above configuration, the antenna connection terminals 101 and 102 are capable of being selected using the switch 63A. Accordingly, the antenna to be used in transmission or reception is capable of being swapped to improve the quality of transmission signals and the receiving sensibility. For example, when a diversity antenna is connected to the antenna connection terminal 102 via a diversity circuit, the signal (for example, the SRS or the like) transmitted through the diversity antenna is capable of being amplified by the power amplifier 11A in the radio frequency circuit 1B. Accordingly, in such a case, the power amplifier in the diversity circuit may be omitted.

For example, in the radio frequency circuit 1B according to the third exemplary embodiment, the first amplifier may be the low-noise amplifier 21A, the second amplifier may be the low-noise amplifier 22B, the first input-output terminal may be the radio-frequency output terminal 121B for supplying the reception signals in the NR-U band and the 6-GHz licensed band to the outside of the radio frequency circuit 1B, and the second input-output terminal may be the radio-frequency output terminal 123 for supplying the reception signal in the WLAN band to the outside of the radio frequency circuit 1B.

With the above configuration, the use of the multiplexer 41A enables the power loss to be reduced in reception of the signals in the 6-GHz licensed band and the WLAN band to improve the receiving sensibility.

For example, in the radio frequency circuit 1B according to the third exemplary embodiment, the filter 51A may be a low pass filter having the cutoff frequency higher than or equal to the upper limit frequency of the WLAN band in a certain region in which the 6-GHz licensed band is capable of being used. The filter 52A may be a high pass filter having the cutoff frequency lower than or equal to the lower limit frequency of the 6-GHz licensed band in the certain region.

With the above configuration, the signal in the 6-GHz licensed band and the signal in the WLAN band are capable of being efficiently multiplexed and/or demultiplexed with the multiplexer 41A to improve the quality of transmission signals and/or the receiving sensibility.

### Fourth Embodiment

Next, a fourth exemplary embodiment will be described. The fourth exemplary embodiment mainly differs from the first exemplary embodiment described above in that simultaneous communication of the NR-U band and the 6-GHz licensed band is available. The fourth exemplary embodiment will be described below, focusing on points different from the first exemplary embodiment described above.

### [4.1 Circuit Configuration of Communication Apparatus 5C]

The circuit configuration of a communication apparatus 5C according to the fourth exemplary embodiment is the same as that of the communication apparatus 5 according to the first exemplary embodiment described above excluding inclusion of a radio frequency circuit 1C, instead of the radio frequency circuit 1. Accordingly, description of the circuit configuration of the communication apparatus 5C is omitted herein, excluding the description of the radio frequency circuit 1C.

### 4.2 Circuit Configuration of Radio Frequency Circuit 1C

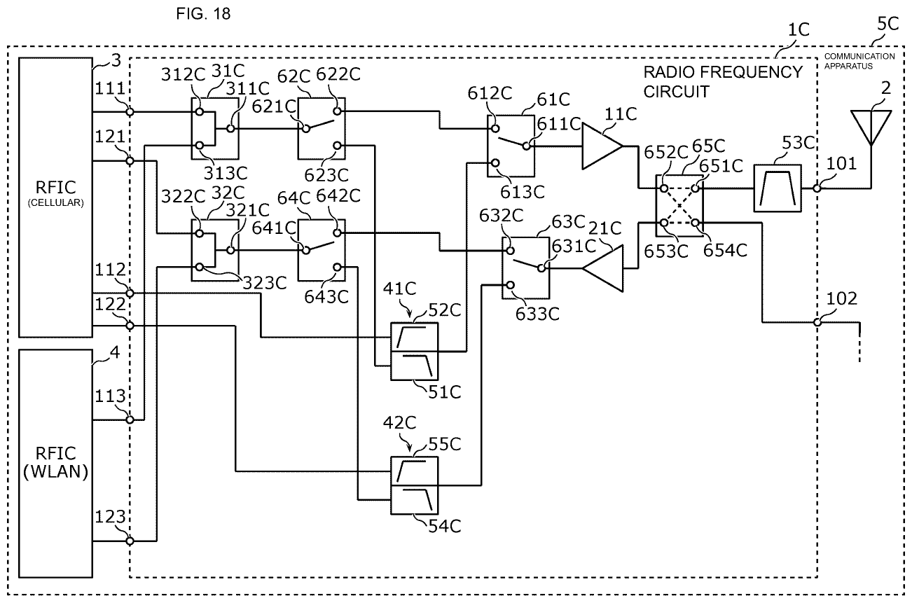

The circuit configuration of the radio frequency circuit 1C according to the fourth exemplary embodiment will be described with reference to FIG. 18. FIG. 18 is a diagram illustrating the circuit configuration of the communication apparatus 5C according to the fourth exemplary embodiment.

The radio frequency circuit 1C includes a power amplifier 11C, a low-noise amplifier 21C, dividers 31C and 32C, multiplexers 41C and 42C, a filter 53C, switches 61C to 65C, the antenna connection terminals 101 and 102, the radio-frequency input terminals 111 to 113, and the radio-frequency output terminals 121 to 123. The components in the radio frequency circuit 1C will be described, focusing on points different from the radio frequency circuit 1.

The power amplifier 11C is an example of the first amplifier and is connected between the switch 61C and the filter 53C. Specifically, an input end of the power amplifier 11C is connected to the switch 61C and an output end of the power amplifier 11C is connected to the filter 53C or the antenna connection terminal 102 via the switch 65C. The power amplifier 11C is capable of amplifying the transmission signals in the WLAN band, the NR-U band, and the 6-GHz licensed band.

The low-noise amplifier 21C is connected between the switch 63C and the filter 53C. Specifically, an input end of the low-noise amplifier 21C is connected to the filter 53C or the antenna connection terminal 102 via the switch 65C and an output end of the low-noise amplifier 21C is connected to the switch 63C. The low-noise amplifier 21C is capable of amplifying the reception signals in the WLAN band, the NR-U band, and the 6-GHz licensed band.

The divider 31C is an example of the first divider and is a power divider including three terminals 311C to 313C. The terminal 311C is an example of the first terminal and is connected to the switch 62C. The terminal 312C is an example of the second terminal and is connected to the radio-frequency input terminal 111. The terminal 313C is an example of the third terminal and is connected to the radio-frequency input terminal 113.

The divider 32C is an example of the second divider and is a power divider including three terminals 321C to 323C. The terminal 321C is an example of the first terminal and is connected to the switch 64C. The terminal 322C is an example of the second terminal and is connected to the radio-frequency output terminal 121. The terminal 323C is an example of the third terminal and is connected to the radio-frequency output terminal 123.

The multiplexers 41C and 42C are examples of the first multiplexer and the second multiplexer, respectively. The multiplexer 41C includes filters 51C and 52C and the multiplexer 42C includes filters 54C and 55C.

The filter 51C is an example of the first filter and has a passband (an example of the first passband) lower than a passband of the filter 52C. One end of the filter 51C is connected to the switch 61C and the other end of the filter 51C is connected to the switch 62C.

In the fourth exemplary embodiment, the low pass filter is used as the filter 51C. At this time, a frequency higher than or equal to the upper limit frequency of the WLAN band in a certain region in which the 6-GHz licensed band is capable of being used is usable as the cutoff frequency of the low pass filter, like the filter 51. The filter 51C is not necessarily the low pass filter and may be a band pass filter.

The filter 52C is an example of the second filter and has a passband (an example of the second passband) higher than the passband of the filter 51C. One end of the filter 52C is connected to the switch 61C and the other end of the filter 52C is connected to the radio-frequency input terminal 112.

In the fourth exemplary embodiment, the high pass filter is used as the filter 52C. At this time, a frequency lower than or equal to the lower limit frequency of the 6-GHz licensed band in a certain region in which the 6-GHz licensed band is capable of being used is usable as the cutoff frequency of the high pass filter, like the filter 52. The filter 52C is not necessarily the high pass filter and may be a band pass filter.

The filter 53C is an example of the third filter and is a band pass filter having a passband (an example of the third passband) including the WLAN band, the NR-U band, and the 6-GHz licensed band, like the filter 53. One end of the filter 53C is connected to the switch 65C and the other end of the filter 53C is connected to the antenna connection terminal 101.

The filter 54C is an example of the fourth filter and has a passband (an example of the fourth passband) lower than a passband of the filter 55C. One end of the filter 54C is connected to the switch 63C and the other end of the filter 54C is connected to the switch 64C.

In the fourth exemplary embodiment, the low pass filter is used as the filter 54C, like the filter 51C. At this time, a frequency higher than or equal to the upper limit frequency of the WLAN band in a certain region in which the 6-GHz licensed band is capable of being used is usable as the cutoff frequency of the low pass filter, like the filter 54. The filter 54C is not necessarily the low pass filter and may be a band pass filter.

The filter 55C is an example of the fifth filter and has a passband (an example of the fifth passband) higher than the passband of the filter 54C. One end of the filter 55C is connected to the switch 63C and the other end of the filter 55C is connected to the radio-frequency output terminal 122.

In the fourth exemplary embodiment, the high pass filter is used as the filter 55C, like the filter 52C. At this time, a frequency lower than or equal to the lower limit frequency of the 6-GHz licensed band in a certain region in which the 6-GHz licensed band is capable of being used is usable as the cutoff frequency of the high pass filter, like the filter 55. The filter 55C is not necessarily the high pass filter and may be a band pass filter.

Each of the filters 51C to 55C may be composed of any of a SAW filter, a BAW filter, an LC filter, and a dielectric filter and is not limited to these filters.

The switch 61C is an example of the first switch and includes three terminals 611C to 613C. The terminal 611C is an example of the first terminal and is connected to the input end of the power amplifier 11C. The terminal 612C is an example of the second terminal and is connected to a terminal 622C of the switch 62C. The terminal 613C is an example of the third terminal and is connected to one end of the filter 51C and one end of the filter 52C.

In this connection configuration, the switch 61C is capable of exclusively connecting the terminal 611C to the terminals 612C and 613C based on, for example, a control signal from the RFIC 3. The switch 61C is composed of, for example, an SPDT switch circuit.

The switch 62C is an example of the second switch and includes three terminals 621C to 623C. The terminal 621C is an example of the first terminal and is connected to the terminal 311C of the divider 31C. The terminal 622C is an example of the second terminal and is connected to the terminal 612C of the switch 61C. The terminal 623C is an example of the third terminal and is connected to the other end of the filter 51C.

In this connection configuration, the switch 62C is capable of exclusively connecting the terminal 621C to the terminals 622C and 623C based on, for example, the control signal from the RFIC 3. The switch 62C is composed of, for example, an SPDT switch circuit.

The switch 63C is an example of the third switch and includes three terminals 631C to 633C. The terminal 631C is an example of the first terminal and is connected to the output end of the low-noise amplifier 21C. The terminal 632C is an example of the second terminal and is connected to a terminal 642C of the switch 64C. The terminal 633C is an example of the third terminal and is connected to one end of the filter 54C and one end of the filter 55C.

In this connection configuration, the switch 63C is capable of exclusively connecting the terminal 631C to the terminals 632C and 633C based on, for example, the control signal from the RFIC 3. The switch 63C is composed of, for example, an SPDT switch circuit.

The switch 64C is an example of the fourth switch and includes three terminals 641C to 643C. The terminal 641C is an example of the first terminal and is connected to the terminal 321C of the divider 32C. The terminal 642C is an example of the second terminal and is connected to the terminal 632C of the switch 63C. The terminal 643C is an example of the third terminal and is connected to the other end of the filter 54C.

In this connection configuration, the switch 64C is capable of exclusively connecting the terminal 641C to the terminals 642C and 643C based on, for example, the control signal from the RFIC 3. The switch 64C is composed of, for example, an SPDT switch circuit.

The switch 65C is an example of the fifth switch and includes four terminals 651C to 654C. The terminal 651C is an example of the first terminal and is connected to one end of the filter 53C. The terminal 652C is an example of the second terminal and is connected to the output end of the power amplifier 11C. The terminal 653C is an example of the third terminal and is connected to the input end of the low-noise amplifier 21C. The terminal 654C is an example of the fourth terminal and is connected to the antenna connection terminal 102.

In this connection configuration, the switch 65C is capable of exclusively connecting the terminal 651C to the terminals 652C and 653C and is capable of exclusively connecting the terminal 654C to the terminals 652C and 653C based on, for example, the control signal from the RFIC 3. The switch 65C is composed of, for example, a DPDT switch circuit.

The radio frequency circuit 1C illustrated in FIG. 18 is only an example and is not limited to this. For example, the radio frequency circuit 1C does not necessarily include the reception path. Specifically, the radio frequency circuit 1C does not necessarily include the low-noise amplifier 21C, the divider 32C, the multiplexer 42C, the switches 63C to 65C, and the radio-frequency output terminals 121 to 123. For example, the radio frequency circuit 1C does not necessarily include the transmission path. Specifically, the radio frequency circuit 1C does not necessarily include the power amplifier 11C, the divider 31C, the multiplexer 41C, the switches 61C, 62C, and 65C, and the radio-frequency input terminals 111 to 113. In this case, the low-noise amplifier 21C is an example of the first amplifier, the divider 32C is an example of the first divider, the multiplexer 42C is an example of the first multiplexer, the filters 54C and 55C are examples of the first filter and the second filter, respectively, the passbands of the filters 54C and 55C are examples of the first passband and the second passband, respectively, the switches 63C and 64C are examples of the first switch and the second switch, respectively, and the radio-frequency output terminals 121 to 123 are examples of the first to third input-output terminals, respectively. For example, the radio frequency circuit 1C does not necessarily include the antenna connection terminal 102. In this case, the switch 65C does not necessarily have the terminal 654C.

### 4.3 Connection States and Flows of Radio Frequency Signal in the Radio Frequency Circuit 1C

Next, specific examples of connection states and the flows of the radio frequency signal in the respective connection states in the radio frequency circuit 1C according to the fourth exemplary embodiment will be described.

### 4.3.1 Connection State and Flow of Radio Frequency Signal for Transmission in First Region

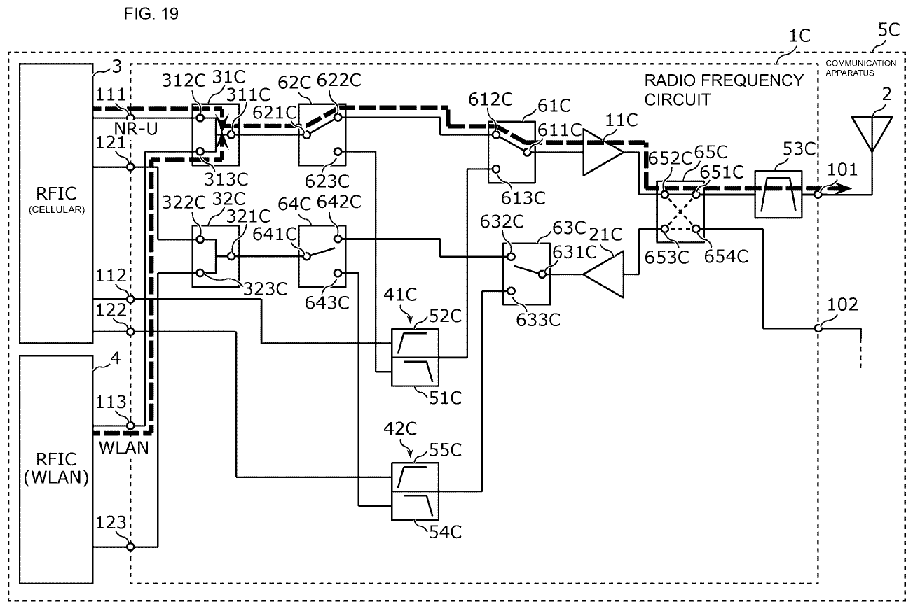

First, the connection state and the flow of the radio frequency signal for transmission in the first region will be described with reference to FIG. 19. FIG. 19 is a diagram illustrating the connection state and the flow of the radio frequency signal for transmission in the first region in the radio frequency circuit 1C according to the fourth exemplary embodiment.

The 6-GHz licensed band is not used and the NR-U band and the WLAN band are used in the first region, as illustrated in FIG. 1. Accordingly, the RFIC 3 controls each switch in the radio frequency circuit 1C to transmit the signals in the NR-U band and the WLAN band using the divider 31C in FIG. 19. Specifically, the switch 61C connects the terminal 611C to the terminal 612C, the switch 62C connects the terminal 621C to the terminal 622C, and the switch 65C connects the terminal 651C to the terminal 652C.

As a result, the transmission signal in the NR-U band is transmitted from the radio-frequency input terminal 111 to the divider 31C. The transmission signal in the WLAN band is transmitted from the radio-frequency input terminal 113 to the divider 31C. The transmission signal in the NR-U band is combined with the transmission signal in the WLAN band in the divider 31C. The transmission signal combined in the divider 31C is transmitted to the antenna connection terminal 101 via the switch 62C, the switch 61C, the power amplifier 11C, the switch 65C, and the filter 53C.

The signals in the NR-U band and the WLAN band received from the RFICs 3 and 4, respectively, are transmitted from the antenna 2.

### 4.3.2 Connection State and Flow of Radio Frequency Signal for Reception in First Region

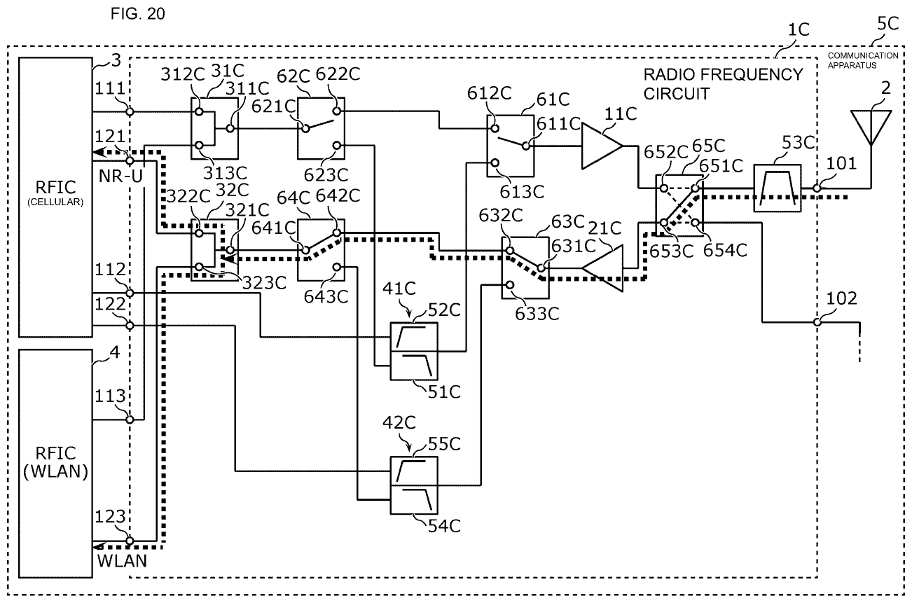

Next, the connection state and the flow of the radio frequency signal for reception in the first region will be described with reference to FIG. 20. FIG. 20 is a diagram illustrating the connection state and the flow of the radio frequency signal for reception in the first region in the radio frequency circuit 1C according to the fourth exemplary embodiment.

The 6-GHz licensed band is not used and the NR-U band and the WLAN band are used in the first region, as illustrated in FIG. 1. Accordingly, the RFIC 3 controls each switch in the radio frequency circuit 1C to receive the signals in the NR-U band and the WLAN band using the divider 32C in FIG. 20. Specifically, the switch 63C connects the terminal 631C to the terminal 632C, the switch 64C connects the terminal 641C to the terminal 642C, and the switch 65C connects the terminal 651C to the terminal 653C.

As a result, the reception signals in the NR-U band and the WLAN band are transmitted from the antenna connection terminal 101 to the divider 32C via the filter 53C, the switch 65C, the low-noise amplifier 21C, the switch 63C, and the switch 64C. The reception signals in the NR-U band and the WLAN band are divided in the divider 32C. One of the divided reception signals is transmitted to the radio-frequency output terminal 121. The other of the divided reception signals is transmitted to the radio-frequency output terminal 123.

The signals in the NR-U band and the WLAN band received through the antenna 2 are supplied to the RFICs 3 and 4, respectively.

### 4.3.3 Connection State and Flow of Radio Frequency Signal for Transmission in Second Region or Third Region

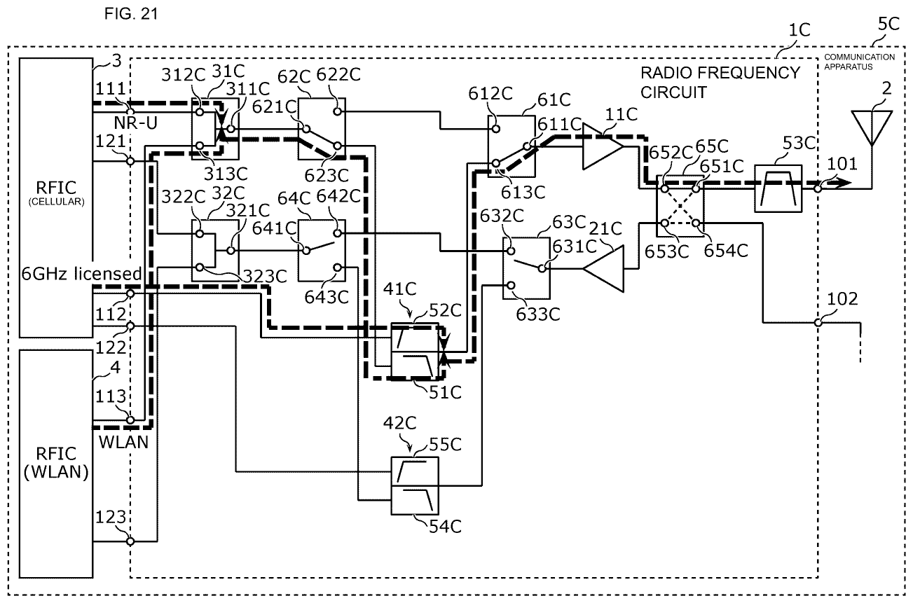

Next, the connection state and the flow of the radio frequency signal for transmission in the second region or the third region will be described with reference to FIG. 21. FIG. 21 is a diagram illustrating the connection state and the flow of the radio frequency signal for transmission in the second region or the third region in the radio frequency circuit 1C according to the fourth exemplary embodiment.

The 6-GHz licensed band is used in the second region and the third region, as illustrated in FIG. 1. Accordingly, the RFIC 3 controls each switch in the radio frequency circuit 1C to transmit the signals in the 6-GHz licensed band, the NR-U band, and the WLAN band using the divider 31C and the multiplexer 41C in FIG. 21. Specifically, the switch 61C connects the terminal 611C to the terminal 613C, the switch 62C connects the terminal 621C to the terminal 623C, and the switch 65C connects the terminal 651C to the terminal 652C.

As a result, the transmission signal in the NR-U band is transmitted from the radio-frequency input terminal 111 to the divider 31C. The transmission signal in the WLAN band is transmitted from the radio-frequency input terminal 113 to the divider 31C. The transmission signal in the NR-U band is combined with the transmission signal in the WLAN band in the divider 31C. The transmission signal combined in the divider 31C is transmitted to the multiplexer 41C via the switch 62C. The transmission signal in the 6-GHz licensed band is transmitted from the radio-frequency input terminal 112 to the multiplexer 41C. The transmission signal combined in the divider 31C is multiplexed with the transmission signal in the 6-GHz licensed band in the multiplexer 41C. The transmission signal multiplexed in the multiplexer 41C is transmitted to the antenna connection terminal 101 via the switch 61C, the power amplifier 11C, the switch 65C, and the filter 53C.

The signals in the NR-U band, the 6-GHz licensed band, and the WLAN band received from the RFICs 3 and 4 are transmitted from the antenna 2.

### 4.3.4 Connection State and Flow of Radio Frequency Signal for Reception in Second Region or Third Region

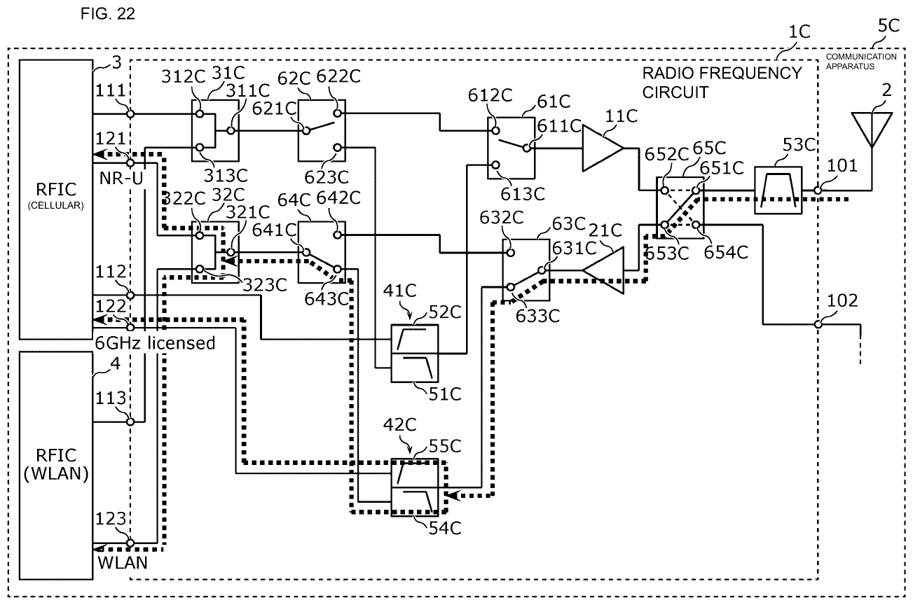

Next, the connection state and the flow of the radio frequency signal for reception in the second region or the third region will be described with reference to FIG. 22. FIG. 22 is a diagram illustrating the connection state and the flow of the radio frequency signal for reception in the second region or the third region in the radio frequency circuit 1C according to the fourth exemplary embodiment.

The 6-GHz licensed band is used in the second region and the third region, as illustrated in FIG. 1. Accordingly, the RFIC 3 controls each switch in the radio frequency circuit 1C to receive the signals in the NR-U band, the 6-GHz licensed band, and the WLAN band using the divider 32C and the multiplexer 42C in FIG. 22. Specifically, the switch 63C connects the terminal 631C to the terminal 633C, the switch 64C connects the terminal 641C to the terminal 643C, and the switch 65C connects the terminal 651C to the terminal 653C.

As a result, the reception signals in the NR-U band, the 6-GHz licensed band, and the WLAN band are transmitted from the antenna connection terminal 101 to the multiplexer 42C via the filter 53C, the switch 65C, the low-noise amplifier 21C, and the switch 63C. The reception signals in the NR-U band, the 6-GHz licensed band, and the WLAN band are demultiplexed into the reception signal in the 6-GHz licensed band and the reception signals in the NR-U band and the WLAN band in the multiplexer 42C. The reception signal in the 6-GHz licensed band demultiplexed in the multiplexer 42C is transmitted to the radio-frequency output terminal 122. The reception signals in the NR-U band and the WLAN band demultiplexed in the multiplexer 42C are transmitted to the divider 32C via the switch 64C. The reception signals in the NR-U band and the WLAN band are divided in the divider 32C. One of the reception signals divided in the divider 32C is transmitted to the radio-frequency output terminal 121. The other of the reception signals divided in the divider 32C is transmitted to the radio-frequency output terminal 123.

The signals in the NR-U band, the 6-GHz licensed band, and the WLAN band received through the antenna 2 are supplied to the RFICs 3 and 4.

### 4.4 Exemplary Advantages

As described above, the radio frequency circuit 1C according to the fourth exemplary embodiment includes the divider 31C or 32C including the first terminal, the second terminal, and the third terminal; the multiplexer 41C or 42C including the filter 51C or 54C having the first passband and the filter 52C or 55C having the second passband higher than the first passband; the switch 61C or 63C including the first terminal, the second terminal, and the third terminal connected on one end of the filter 51C or 54C and one end of the filter 52C or 55C; the switch 62C or 64C including the first terminal connected to the first terminal of the divider 31C or 32C, the second terminal connected to the second terminal of the switch 61C or 63C, and the third terminal connected to the other end of the filter 51C or 54C; the filter 53C having the third passband including the WLAN band of 5 GHZ or more; and the first amplifier (the power amplifier 11C or the low-noise amplifier 21C) connected to one end of the filter 53C. The first terminal of the switch 61C to 63C is connected to the first amplifier (the power amplifier 11C or the low-noise amplifier 21C). With the above configuration, the connection of the first amplifier (the power amplifier 11C or the low-noise amplifier 21C) and the filter 53C is capable of being switched between the divider 31C or 32C and the multiplexer 41C or 42C using the switch 61C or 63C. Accordingly, it is possible to use the multiplexer 41C or 42C, instead of the divider 31C or 32C causing loss of 3 dB, for transmission or reception to improve the quality of transmission signals or the receiving sensibility, compared with that of the radio frequency circuit 901 according to the comparative example.

For example, in the radio frequency circuit 1C according to the fourth exemplary embodiment, the first terminal of the switch 61C or 63C may be connected to the first amplifier (the power amplifier 11C or the low-noise amplifier 21C). The third passband of the filter 53C may further include the NR-U band and the 6-GHz licensed band. The radio frequency circuit 1C may further include the antenna connection terminal 101 connected to the other end of the filter 53C; the first input-output terminal (the radio-frequency input terminal 111 or the radio-frequency output terminal 121) that is for the NR-U band and that is connected to the second terminal of the divider 31C or 32C; the second input-output terminal (the radio-frequency input terminal 112 or the radio-frequency output terminal 122) that is for the 6-GHz licensed band and that is connected to the other end of the filter 52C or 55C; and the third input-output terminal (the radio-frequency input terminal 113 or the radio-frequency output terminal 123) that is for the WLAN band and that is connected to the third terminal of the divider 31C or 32C.

With the above configuration, the multiplexer 41C or 42C is connected between the first amplifier (the power amplifier 11C or the low-noise amplifier 21C) and the first input-output terminal (the radio-frequency input terminal 111 or the radio-frequency output terminal 121), the second input-output terminal (the radio-frequency input terminal 112 or the radio-frequency output terminal 122), and the third input-output terminal (the radio-frequency input terminal 113 or the radio-frequency output terminal 123) via the switch 61C or 63C and the switch 62C or 64C.

Accordingly, the use of the multiplexer 41C or 42C enables the power loss to be reduced in transmission or reception of the signal in the 6-GHz licensed band to improve the quality of transmission signals or the receiving sensibility. In addition, it is possible to share the filter 53C and the first amplifier (the power amplifier 11C or the low-noise amplifier 21C) among the NR-U band, the 6-GHz licensed band, and the WLAN band to contribute to a reduction in the number of components. Furthermore, the filter 51C or 54C is connected to the divider 31C or 32C via the switch 62C or 64C, it possible to realize simultaneous transmission or simultaneous reception of the signals in the NR-U band, the 6-GHz licensed band, and the WLAN band.

For example, in the radio frequency circuit 1C according to the fourth exemplary embodiment, the first amplifier may be the power amplifier 11C, the first input-output terminal may be the radio-frequency input terminal 111 for receiving the transmission signal in the NR-U band from the outside of the radio frequency circuit 1C, the second input-output terminal may be the radio-frequency input terminal 112 for receiving the transmission signal in the 6-GHz licensed band from the outside of the radio frequency circuit 1C, and the third input-output terminal may be the radio-frequency input terminal 113 for receiving the transmission signal in the WLAN band from the outside of the radio frequency circuit 1C.

With the above configuration, the use of the multiplexer 41C enables the power loss to be reduced in transmission of the signals in the 6-GHz licensed band and the WLAN band to improve the quality of transmission signals. In particular, since the output power higher than that of the NR-U band is required in transmission of the signal in the 6-GHz licensed band, the effect of improving the quality of the transmission signals due to the reduction in the power loss is high.

For example, the radio frequency circuit 1C according to the fourth exemplary embodiment may further include the divider 32C including the first terminal, the second terminal, and the third terminal; the multiplexer 42C including the filter 54C having the fourth passband and the filter 55C having the fifth passband higher than the fourth passband; the switch 63C including the first terminal, the second terminal, and the third terminal connected to one end of the filter 54C and one end of the filter 55C; the switch 64C including the first terminal connected to the first terminal of the divider 32C, the second terminal connected to the second terminal of the switch 63C, and the third terminal connected to the other end of the filter 54C; the low-noise amplifier 21C connected between one end of the filter 53C and the first terminal of the switch 63C; the switch 65C including the first terminal connected to one end of the filter 53C, the second terminal connected to the output end of the power amplifier 11C, and the third terminal connected to the input end of the low-noise amplifier 21C; the radio-frequency output terminal 121 that is for supplying the reception signal in the NR-U band to the outside of the radio frequency circuit 1C and that is connected to the second terminal of the divider 32C; the radio-frequency output terminal 122 that is for supplying the reception signal in the 6-GHz licensed band to the outside of the radio frequency circuit 1C and that is connected to the other end of the filter 55C; and the radio-frequency output terminal 123 that is for supplying the reception signal in the WLAN band to the outside of the radio frequency circuit 1C and that is connected to the third terminal of the divider 32C.

With the above configuration, the use of the multiplexer 41C enables the power loss to be reduced in transmission of the signals in the 6-GHz licensed band and the WLAN band and the use of the multiplexer 42C enables the power loss to be reduced in reception of the signals in the 6-GHz licensed band and the WLAN band. Accordingly, it is possible to improve the quality of transmission signals and the receiving sensibility.

For example, the radio frequency circuit 1C according to the fourth exemplary embodiment may further include the antenna connection terminal 102. The switch 65C may further include the fourth terminal connected to the antenna connection terminal 102.

With the above configuration, the antenna connection terminals 101 and 102 are capable of being selected using the switch 65C. Accordingly, the antenna to be used in transmission or reception is capable of being swapped to improve the quality of transmission signals and the receiving sensibility. For example, when a diversity antenna is connected to the antenna connection terminal 102 via a diversity circuit, the signal (for example, the SRS or the like) transmitted through the diversity antenna is capable of being amplified by the power amplifier 11C in the radio frequency circuit 1C. Accordingly, in such a case, the power amplifier in the diversity circuit may be omitted.

For example, in the radio frequency circuit 1C according to the fourth exemplary embodiment, the first amplifier may be the low-noise amplifier 21C, the first input-output terminal may be the radio-frequency output terminal 121 for supplying the reception signal in the NR-U band to the outside of the radio frequency circuit 1C, the second input-output terminal may be the radio-frequency output terminal 122 for supplying the reception signal in the 6-GHz licensed band to the outside of the radio frequency circuit 1C, and the third input-output terminal may be the radio-frequency output terminal 123 for supplying the reception signal in the WLAN band to the outside of the radio frequency circuit 1C.

With the above configuration, the use of the multiplexer 41C enables the power loss to be reduced in reception of the signals in the 6-GHz licensed band and the WLAN band to improve the receiving sensibility.

For example, in the radio frequency circuit 1C according to the fourth exemplary embodiment, the filter 51C and/or 54C may be a low pass filter having the cutoff frequency higher than or equal to the upper limit frequency of the WLAN band in a certain region in which the 6-GHz licensed band is capable of being used. The filter 52C and/or 55C may be a high pass filter having the cutoff frequency lower than or equal to the lower limit frequency of the 6-GHz licensed band in the certain region.

With the above configuration, the signal in the 6-GHz licensed band and the signal in the WLAN band are capable of being efficiently multiplexed and/or demultiplexed with the multiplexer 41C and/or 42C to improve the quality of transmission signals and/or the receiving sensibility.

### Fifth Embodiment

Next, a fifth exemplary embodiment will be described. The fifth exemplary embodiment mainly differs from the second exemplary embodiment described above in that the simultaneous communication of the NR-U band and the 6-GHz licensed band is available. The fifth exemplary embodiment will be described below, focusing on points different from the second exemplary embodiment described above.

### 5.1 Circuit Configuration of Communication Apparatus 5D

The circuit configuration of a communication apparatus 5D according to the fifth exemplary embodiment is the same as that of the communication apparatus 5A according to the second exemplary embodiment described above excluding inclusion of a radio frequency circuit 1D, instead of the radio frequency circuit 1A. Accordingly, description of the circuit configuration of the communication apparatus 5D is omitted herein, excluding the description of the radio frequency circuit 1D.

### 5.2 Circuit Configuration of Radio Frequency Circuit 1D

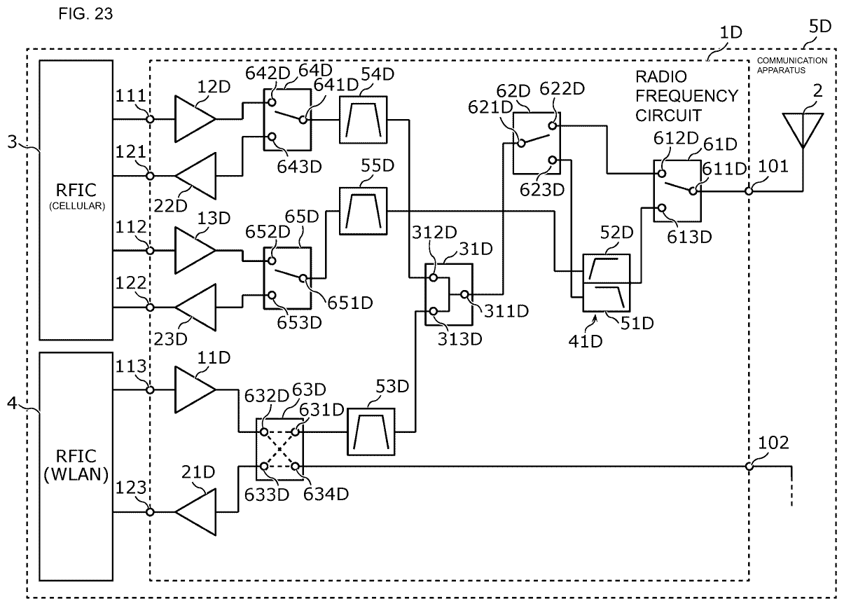

The circuit configuration of the radio frequency circuit 1D according to the fifth exemplary embodiment will be described with reference to FIG. 23. FIG. 23 is a diagram illustrating the circuit configuration of the communication apparatus 5D according to the fifth exemplary embodiment.

The radio frequency circuit 1D includes power amplifiers 11D to 13D, low-noise amplifiers 21D to 23D, a divider 31D, a multiplexer 41D, filters 53D to 55D, switches 61D to 65D, the antenna connection terminals 101 and 102, the radio-frequency input terminals 111 to 113, and the radio-frequency output terminals 121 to 123. The components in the radio frequency circuit 1D will be described, focusing on points different from the radio frequency circuit 1A.

The power amplifier 11D is an example of the first amplifier and the first power amplifier and is connected between the radio-frequency input terminal 113 and the filter 53D. Specifically, an input end of the power amplifier 11D is connected to the radio-frequency input terminal 113 and an output end of the power amplifier 11D is connected to the filter 53D or the antenna connection terminal 102 via the switch 63D. The power amplifier 11D is capable of amplifying the transmission signal in the WLAN band.

The power amplifier 12D is an example of the second amplifier and the second power amplifier and is connected between the radio-frequency input terminal 111 and the filter 54D. Specifically, an input end of the power amplifier 12D is connected to the radio-frequency input terminal 111 and an output end of the power amplifier 12D is connected to the filter 54D via the switch 64D. The power amplifier 12D is capable of amplifying the transmission signal in the NR-U band.

The power amplifier 13D is an example of the third amplifier and the third power amplifier and is connected between the radio-frequency input terminal 112 and the filter 55D. Specifically, an input end of the power amplifier 13D is connected to the radio-frequency input terminal 112 and an output end of the power amplifier 13D is connected to the filter 55D via the switch 65D. The power amplifier 13D is capable of amplifying the transmission signal in the 6-GHz licensed band.

The low-noise amplifier 21D is an example of the first amplifier and the first low-noise amplifier and is connected between the filter 53D and the radio-frequency output terminal 123. Specifically, an input end of the low-noise amplifier 21D is connected to the filter 53D or the antenna connection terminal 102 via the switch 63D and an output end of the low-noise amplifier 21D is connected to the radio-frequency output terminal 123. The low-noise amplifier 21D is capable of amplifying the reception signal in the WLAN band.

The low-noise amplifier 22D is an example of the second amplifier and the second low-noise amplifier and is connected between the filter 54D and the radio-frequency output terminal 121. Specifically, an input end of the low-noise amplifier 22D is connected to the filter 54D via the switch 64D and an output end of the low-noise amplifier 22D is connected to the radio-frequency output terminal 121. The low-noise amplifier 22D is capable of amplifying the reception signal in the NR-U band.

The low-noise amplifier 23D is an example of the third amplifier and the third low-noise amplifier and is connected between the filter 55D and the radio-frequency output terminal 122. Specifically, an input end of the low-noise amplifier 23D is connected to the filter 55D via the switch 65D and an output end of the low-noise amplifier 23D is connected to the radio-frequency output terminal 122. The low-noise amplifier 23D is capable of amplifying the reception signal in the 6-GHz licensed band.

The divider 31D is an example of the first divider and is a power divider including three terminals 311D to 313D. The terminal 311D is an example of the first terminal and is connected to the switch 62D. The terminal 312D is an example of the second terminal and is connected to the filter 54D. The terminal 313D is an example of the third terminal and is connected to the filter 53D.

The multiplexer 41D is an example of the first multiplexer and includes filters 51D and 52D.

The filter 51D is an example of the first filter and has a passband (an example of the first passband) lower than a passband of the filter 52D. One end of the filter 51D is connected to the switch 61D and the other end of the filter 51D is connected to the switch 62D.

In the fifth exemplary embodiment, the low pass filter is used as the filter 51D. At this time, a frequency higher than or equal to the upper limit frequency of the WLAN band in a certain region in which the 6-GHz licensed band is capable of being used is usable as the cutoff frequency of the low pass filter, like the filter 51A. The filter 51D is not necessarily the low pass filter and may be a band pass filter.

The filter 52D is an example of the second filter and has a passband (an example of the second passband) higher than the passband of the filter 51D. One end of the filter 52D is connected to the switch 61D and the other end of the filter 52D is connected to the filter 55D.

In the fifth exemplary embodiment, the high pass filter is used as the filter 52D. At this time, a frequency lower than or equal to the lower limit frequency of the 6-GHz licensed band in a certain region in which the 6-GHz licensed band is capable of being used is usable as the cutoff frequency of the high pass filter, like the filter 52A. The filter 52D is not necessarily the high pass filter and may be a band pass filter.

The filter 53D is an example of the third filter and is a band pass filter having a passband (an example of the third passband) including the WLAN band, like the filter 53A. One end of the filter 53D is connected to the switch 63D and the other end of the filter 53D is connected to the terminal 313D of the divider 31D.

The filter 54D is an example of the fourth filter and is a band pass filter having a passband (an example of the fourth passband) including the NR-U band, like the filter 54A. One end of the filter 54D is connected to the switch 64D and the other end of the filter 54D is connected to terminal 312D of the divider 31D.

The filter 55D is an example of the fifth filter and is a band pass filter having a passband (an example of the fifth passband) including the 6-GHz licensed band, like the filter 55A. One end of the filter 55D is connected to the switch 65D and the other end of the filter 55D is connected to the other end of the filter 52D.

Each of the filters 51D to 55D may be composed of any of a SAW filter, a BAW filter, an LC filter, and a dielectric filter and is not limited to these filters.

The switch 61D is an example of the first switch and includes three terminals 611D to 613D. The terminal 611D is an example of the first terminal and is connected to the antenna connection terminal 101. The terminal 612D is an example of the second terminal and is connected to the terminal 622D of the switch 62D. The terminal 613D is an example of the third terminal and is connected to one end of the filter 51D and one end of the filter 52D.

In this connection configuration, the switch 61D is capable of exclusively connecting the terminal 611D to the terminals 612D and 613D based on, for example, a control signal from the RFIC 3. The switch 61D is composed of, for example, an SPDT switch circuit.

The switch 62D is an example of the second switch and includes three terminals 621D to 623D. The terminal 621D is an example of the first terminal and is connected to the terminal 311D of the divider 31D. The terminal 622D is an example of the second terminal and is connected to the terminal 612D of the switch 61D. The terminal 623D is an example of the third terminal and is connected to the other end of the filter 51D.

In this connection configuration, the switch 62D is capable of exclusively connecting the terminal 621D to the terminals 622D and 623D based on, for example, the control signal from the RFIC 3. The switch 62D is composed of, for example, an SPDT switch circuit.

The switch 63D is an example of the third switch and includes four terminals 631D to 634D. The terminal 631D is an example of the first terminal and is connected to one end of the filter 53D. The terminal 632D is an example of the second terminal and is connected to the output end of the power amplifier 11D. The terminal 633D is an example of the third terminal and is connected to the input end of the low-noise amplifier 21D. The terminal 634D is an example of the fourth terminal and is connected to the antenna connection terminal 102.

In this connection configuration, the switch 63D is capable of exclusively connecting the terminal 631D to the terminals 632D and 633D and is capable of exclusively connecting the terminal 634D to the terminals 632D and 633D based on, for example, the control signal from the RFIC 3. The switch 63D is composed of, for example, a DPDT switch circuit.

The switch 64D is an example of the fourth switch and includes three terminals 641D to 643D. The terminal 641D is an example of the first terminal and is connected to one end of the filter 54D. The terminal 642D is an example of the second terminal and is connected to the output end of the power amplifier 12D. The terminal 643D is an example of the third terminal and is connected to the input end of the low-noise amplifier 22D.

In this connection configuration, the switch 64D is capable of exclusively connecting the terminal 641D to the terminals 642D and 643D based on, for example, the control signal from the RFIC 3. The switch 64D is composed of, for example, an SPDT switch circuit.

The switch 65D is an example of the fifth switch and includes three terminals 651D to 653D. The terminal 651D is an example of the first terminal and is connected to one end of the filter 55D. The terminal 652D is an example of the second terminal and is connected to the output end of the power amplifier 13D. The terminal 653D is an example of the third terminal and is connected to the input end of the low-noise amplifier 23D.

In this connection configuration, the switch 65D is capable of exclusively connecting the terminal 651D to the terminals 652D and 653D based on, for example, the control signal from the RFIC 3. The switch 65D is composed of, for example, an SPDT switch circuit.

The radio frequency circuit 1D illustrated in FIG. 23 is only an example and is not limited to this. For example, the radio frequency circuit 1D does not necessarily include the reception path. Specifically, the radio frequency circuit 1D does not necessarily include the low-noise amplifiers 21D to 23D, the switches 63D to 65D, and the radio-frequency output terminals 121 to 123. For example, the radio frequency circuit 1D does not necessarily include the transmission path. Specifically, the radio frequency circuit 1D does not necessarily include the power amplifiers 11D to 13D, the switches 63D to 65D, and the radio-frequency input terminals 111 to 113. In this case, the low-noise amplifier 21D is an example of the first amplifier, the low-noise amplifier 22D is an example of the second amplifier, the low-noise amplifier 23D is an example of the third amplifier, and the radio-frequency output terminals 121 to 123 are examples of the first to third input-output terminals, respectively.

In addition, for example, the radio frequency circuit 1D does not necessarily include the antenna connection terminal 102. In this case, the switch 63D does not necessarily have the terminal 634D. The switch connected to the antenna connection terminal 102 is not limited to the switch 63D. For example, the switch 61D may have a terminal connected to the antenna connection terminal 102. In this case, the terminal connected to the antenna connection terminal 102 may be exclusively connected to the terminals 612D and 613D.

### 5.3 Connection States and Flows of Radio Frequency Signal in the Radio Frequency Circuit 1D

Next, specific examples of connection states and the flows of the radio frequency signal in the respective connection states in the radio frequency circuit 1D according to the fifth exemplary embodiment will be described.

### 5.3.1 Connection State and Flow of Radio Frequency Signal for Transmission in First Region

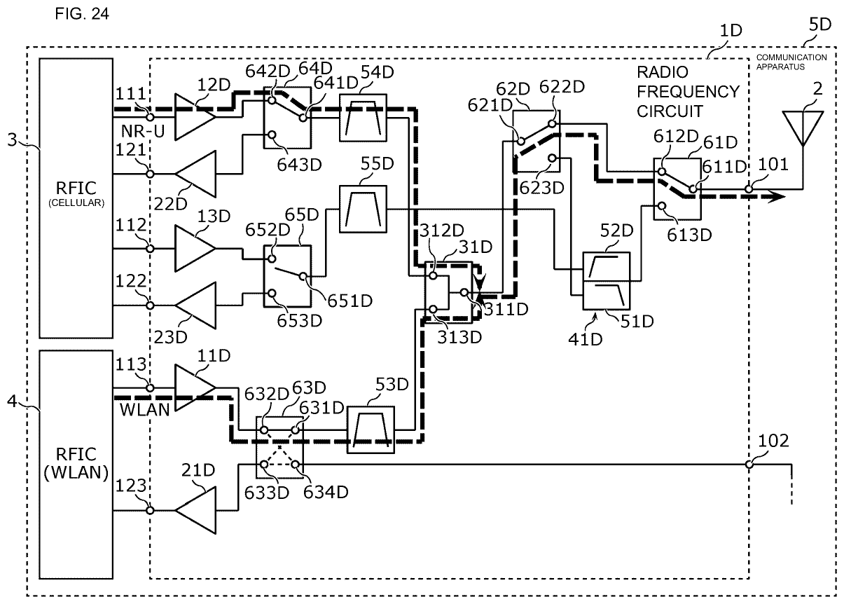

First, the connection state and the flow of the radio frequency signal for transmission in the first region will be described with reference to FIG. 24. FIG. 24 is a diagram illustrating the connection state and the flow of the radio frequency signal for transmission in the first region in the radio frequency circuit 1D according to the fifth exemplary embodiment.

The 6-GHz licensed band is not used and the NR-U band and the WLAN band are used in the first region, as illustrated in FIG. 1. Accordingly, the RFIC 3 controls each switch in the radio frequency circuit 1D to transmit the signals in the NR-U band and the WLAN band using the divider 31D in FIG. 24. Specifically, the switch 61D connects the terminal 611D to the terminal 612D, the switch 62D connects the terminal 621D to the terminal 622D, the switch 63D connects the terminal 631D to the terminal 632D, and the switch 64D connects the terminal 641D to the terminal 642D.

As a result, the transmission signal in the NR-U band is transmitted from the radio-frequency input terminal 111 to the divider 31D via the power amplifier 12D, the switch 64D, and the filter 54D. The transmission signal in the WLAN band is transmitted from the radio-frequency input terminal 113 to the divider 31D via the power amplifier 11D, the switch 63D, and the filter 53D. The transmission signal in the NR-U band is combined with the transmission signal in the WLAN band in the divider 31D. The transmission signal combined in the divider 31D is transmitted to the antenna connection terminal 101 via the switch 62D and the switch 61D.

The signals in the NR-U band and the WLAN band received from the RFICs 3 and 4, respectively, are transmitted from the antenna 2.

### 5.3.2 Connection State and Flow of Radio Frequency Signal for Reception in First Region

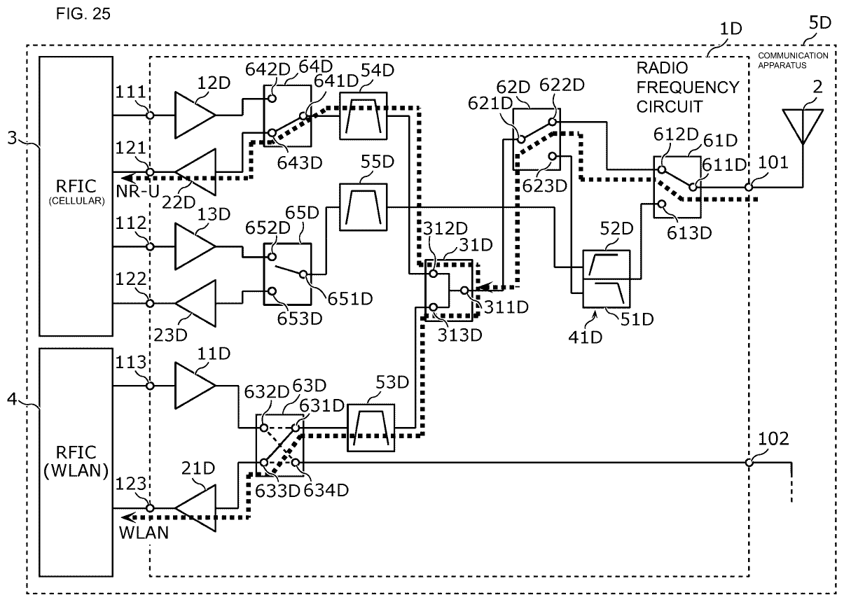

Next, the connection state and the flow of the radio frequency signal for reception in the first region will be described with reference to FIG. 25. FIG. 25 is a diagram illustrating the connection state and the flow of the radio frequency signal for reception in the first region in the radio frequency circuit 1D according to the fifth exemplary embodiment.

The 6-GHz licensed band is not used and the NR-U band and the WLAN band are used in the first region, as illustrated in FIG. 1. Accordingly, the RFIC 3 controls each switch in the radio frequency circuit 1D to receive the signals in the NR-U band and the WLAN band using the divider 31D in FIG. 25. Specifically, the switch 61D connects the terminal 611D to the terminal 612D, the switch 62D connects the terminal 621D to the terminal 622D, the switch 63D connects the terminal 631D to the terminal 633D, and the switch 64D connects the terminal 641D to the terminal 643D.

As a result, the reception signals in the NR-U band and the WLAN band are transmitted from the antenna connection terminal 101 to the divider 31D via the switch 61D and the switch 62D. The reception signals in the NR-U band and the WLAN band are divided in the divider 31D. One of the divided reception signals is transmitted to the radio-frequency output terminal 121 via the filter 54D, the switch 64D, and the low-noise amplifier 22D. The other of the divided reception signals is transmitted to the radio-frequency output terminal 123 via the filter 53D, the switch 63D, and the low-noise amplifier 21D.

The signals in the NR-U band and the WLAN band received through the antenna 2 are supplied to the RFICs 3 and 4, respectively.

### 5.3.3 Connection State and Flow of Radio Frequency Signal for Transmission in Second Region or Third Region

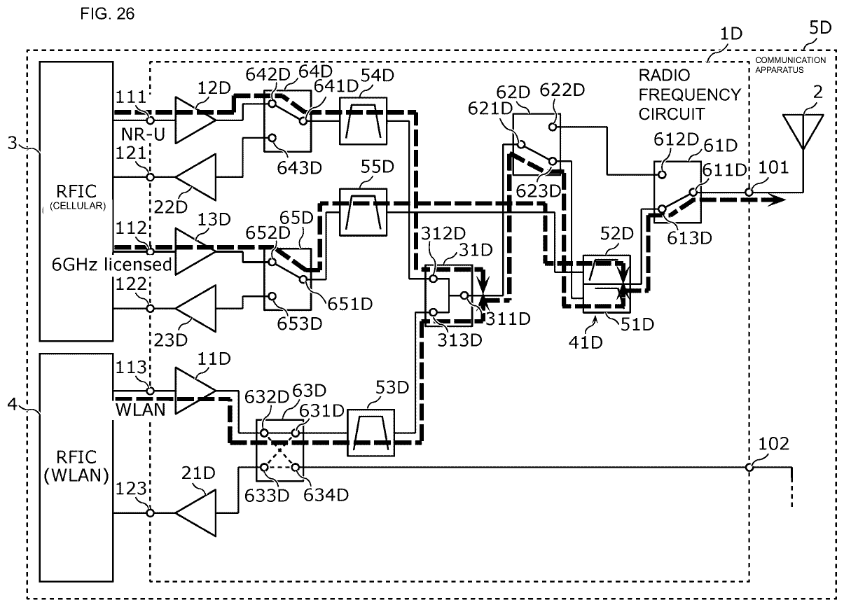

Next, the connection state and the flow of the radio frequency signal for transmission in the second region or the third region will be described with reference to FIG. 26. FIG. 26 is a diagram illustrating the connection state and the flow of the radio frequency signal for transmission in the second region or the third region in the radio frequency circuit 1D according to the fifth exemplary embodiment.

The 6-GHz licensed band is used in the second region and the third region, as illustrated in FIG. 1. Accordingly, the RFIC 3 controls each switch in the radio frequency circuit 1D to transmit the signals in the NR-U band, the 6-GHz licensed band, and the WLAN band using the divider 31D and the multiplexer 41D in FIG. 26. Specifically, the switch 61D connects the terminal 611D to the terminal 613D, the switch 62D connects the terminal 621D to the terminal 623D, the switch 63D connects the terminal 631D to the terminal 632D, the switch 64D connects the terminal 641D to the terminal 642D, and the switch 65D connects the terminal 651D to the terminal 652D.

As a result, the transmission signal in the NR-U band is transmitted from the radio-frequency input terminal 111 to the divider 31D via the power amplifier 12D, the switch 64D, and the filter 54D. The transmission signal in the WLAN band is transmitted from the radio-frequency input terminal 113 to the divider 31D via the power amplifier 11D, the switch 63D, and the filter 53D. The transmission signal in the NR-U band is combined with the transmission signal in the WLAN band in the divider 31D. The combined transmission signal is transmitted to the multiplexer 41D via the switch 62D. The transmission signal in the 6-GHz licensed band is transmitted from the radio-frequency input terminal 112 to the multiplexer 41D via the power amplifier 13D, the switch 65D, and the filter 55D. The transmission signal combined in the divider 31D is multiplexed with the transmission signal in the 6-GHz licensed band in the multiplexer 41D. The transmission signal multiplexed in the multiplexer 41D is transmitted to the antenna connection terminal 101 via the switch 61D.

The signals in the NR-U band, the 6-GHz licensed band, and the WLAN band received from the RFICs 3 and 4 are transmitted from the antenna 2.

### 5.3.4 Connection State and Flow of Radio Frequency Signal for Reception in Second Region or Third Region

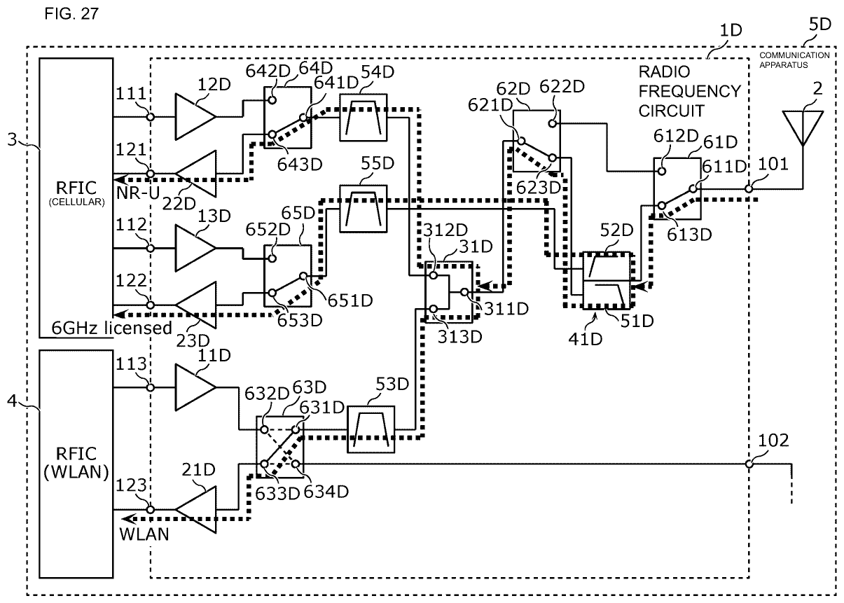

Next, the connection state and the flow of the radio frequency signal for reception in the second region or the third region will be described with reference to FIG. 27. FIG. 27 is a diagram illustrating the connection state and the flow of the radio frequency signal for reception in the second region or the third region in the radio frequency circuit 1D according to the fifth exemplary embodiment.

The 6-GHz licensed band is used in the second region and the third region, as illustrated in FIG. 1. Accordingly, the RFIC 3 controls each switch in the radio frequency circuit 1D to receive the signals in the NR-U band, the 6-GHz licensed band, and the WLAN band using the divider 31D and the multiplexer 41D in FIG. 27. Specifically, the switch 61D connects the terminal 611D to the terminal 613D, the switch 62D connects the terminal 621D to the terminal 623D, the switch 63D connects the terminal 631D to the terminal 633D, the switch 64D connects the terminal 641D to the terminal 643D, and the switch 65D connects the terminal 651D to the terminal 653D.

As a result, the reception signals in the NR-U band, the 6-GHz licensed band, and the WLAN band are transmitted from the antenna connection terminal 101 to the multiplexer 41D via the switch 61D. The reception signals in the NR-U band, the 6-GHz licensed band, and the WLAN band are demultiplexed into the reception signal in the 6-GHz licensed band and the reception signals in the NR-U band and the WLAN band in the multiplexer 41D. The reception signal in the 6-GHz licensed band demultiplexed in the multiplexer 41D is transmitted to the radio-frequency output terminal 122 via the filter 55D, the switch 65D, the low-noise amplifier 23D. The reception signals in the NR-U band and the WLAN band demultiplexed in the multiplexer 41D are transmitted to the divider 31D via the switch 62D. The reception signals in the NR-U band and the WLAN band are divided in the divider 31D. One of the reception signals divided in the divider 31D is transmitted to the radio-frequency output terminal 121 via the filter 54D, the switch 64D, and the low-noise amplifier 22D. The other of the reception signals divided in the divider 31D is transmitted to the radio-frequency output terminal 123 via the filter 53D, the switch 63D, and the low-noise amplifier 21D.

The signals in the NR-U band, the 6-GHz licensed band, and the WLAN band received through the antenna 2 are supplied to the RFICs 3 and 4.

### 5.4 Exemplary Advantages

As described above, the radio frequency circuit 1D according to the fifth exemplary embodiment includes the divider 31D including the first terminal, the second terminal, and the third terminal; the multiplexer 41D including the filter 51D having the first passband and the filter 52D having the second passband higher than the first passband; the switch 61D including the first terminal, the second terminal, and the third terminal connected to one end of the filter 51D and one end of the filter 52D; the switch 62D including the first terminal connected to the first terminal of the divider 31D, the second terminal connected to the second terminal of the switch 61D, and the third terminal connected to the other end of the filter 51D; the filter 53D having the third passband including the WLAN band amplifier 11D or the low-noise amplifier 21D) connected to one end of the filter 53D. The third terminal of the divider 31D is connected to the other end of the filter 53D.

With the above configuration, the connection of the filter 53D is capable of being switched between the divider 31D and the multiplexer 41D using the switch 62D. Accordingly, it is possible to use the multiplexer 41D, instead of the divider 31D causing loss of 3 dB, for transmission or reception to improve the quality of transmission signals or the receiving sensibility, compared with that of the radio frequency circuit 901 according to the comparative example.

For example, in the radio frequency circuit 1D according to the fifth exemplary embodiment, the third terminal of the divider 31D may be connected to the other end of the filter 53D. The radio frequency circuit 1D may further include the antenna connection terminal 101 connected to the first terminal of the switch 61D; the first input-output terminal (the radio-frequency input terminal 111 or the radio-frequency output terminal 121) for the NR-U band; the second input-output terminal (the radio-frequency input terminal 112 or the radio-frequency output terminal 122) for the 6-GHz licensed band; the third input-output terminal (the radio-frequency input terminal 113 or the radio-frequency output terminal 123) that is for the WLAN band and that is connected to the first amplifier (the power amplifier 11D or the low-noise amplifier 21D); the filter 54D having the fourth passband including the NR-U band; the second amplifier (the power amplifier 12D or the low-noise amplifier 22D) connected between the first input-output terminal (the radio-frequency input terminal 111 or the radio-frequency output terminal 121) and one end of the filter 54D; the filter 55D having the fifth passband including the 6-GHz licensed band; and the third amplifier (the power amplifier 13D or the low-noise amplifier 23D) connected between the second input-output terminal (the radio-frequency input terminal 112 or the radio-frequency output terminal 122) and one end of the filter 55D. The second terminal of the divider 31D may be connected to the other end of the filter 54D. The other end of the filter 52D may be connected to the other end of the filter 55D.

With the above configuration, the multiplexer 41D is connected between the antenna connection terminal 101 and the filters 53D to 55D via the switches 61D and 62D. Accordingly, the use of the multiplexer 41D enables the power loss to be reduced in transmission or reception of the signals in the 6-GHz licensed band and the WLAN band to improve the quality of transmission signals or the receiving sensibility. In addition, it is possible to use the divider 31D, the multiplexer 41D, and the switches 61D and 62D in both transmission and reception to contribute to a reduction in the number of components. Furthermore, since the filter 51D is connected to the divider 31D via the switch 62D, it possible to realize the simultaneous transmission or the simultaneous reception of the signals in the NR-U band, the 6-GHz licensed band, and the WLAN band.

For example, in the radio frequency circuit 1D according to the fifth exemplary embodiment, the first amplifier may be the power amplifier 11D, the second amplifier may be the power amplifier 12D, the third amplifier may be the power amplifier 13D, the first input-output terminal may be the radio-frequency input terminal 111 for receiving the transmission signal in the NR-U band from the outside of the radio frequency circuit 1D, the second input-output terminal may be the radio-frequency input terminal 112 for receiving the transmission signal in the 6-GHz licensed band from the outside of the radio frequency circuit 1D, and the third input-output terminal may be the radio-frequency input terminal 113 for receiving the transmission signal in the WLAN band from the outside of the radio frequency circuit 1D.

With the above configuration, the use of the multiplexer 41D enables the power loss to be reduced in transmission of the signals in the 6-GHz licensed band and the WLAN band to improve the quality of transmission signals. In particular, since the output power higher than that of the NR-U band is required in transmission of the signal in the 6-GHz licensed band, the effect of improving the quality of the transmission signals due to the reduction in the power loss is high.

For example, the radio frequency circuit 1D according to the fifth exemplary embodiment may further include the radio-frequency output terminal 121 for supplying the reception signal in the NR-U band to the outside of the radio frequency circuit 1D; the radio-frequency output terminal 122 for supplying the reception signal in the 6-GHz licensed band to the outside of the radio frequency circuit 1D; the radio-frequency output terminal 123 for supplying the reception signal in the WLAN band to the outside of the radio frequency circuit 1D; the low-noise amplifier 21D connected between the radio-frequency output terminal 123 and one end of the filter 53D; the switch 63D including the first terminal connected to one end of the filter 53D, the second terminal connected to the output end of the power amplifier 11D, and the third terminal connected to the input end of the low-noise amplifier 21D; the low-noise amplifier 22D connected between the radio-frequency output terminal 121 and one end of the filter 54D; the switch 64D including the first terminal connected to one end of the filter 54D, the second terminal connected to the output end of the power amplifier 12D, and the third terminal connected to the input end of the low-noise amplifier 22D; the low-noise amplifier 23D connected between the radio-frequency output terminal 122 and one end of the filter 55D; and the switch 65D including the first terminal connected to one end of the filter 55D, the second terminal connected to the output end of the power amplifier 13D, and the third terminal connected to the input end of the low-noise amplifier 23D.

With the above configuration, the use of the multiplexer 41D enables the power loss to be reduced in reception of the signals in the 6-GHz licensed band and the WLAN band, in addition to transmission of the signals in the 6-GHz licensed band and the WLAN band, to improve the receiving sensibility, in addition to the quality of transmission signals.

For example, the radio frequency circuit 1D according to the fifth exemplary embodiment may further include the antenna connection terminal 102. The switch 63D may further include the fourth terminal connected to the antenna connection terminal 102.

With the above configuration, the antenna connection terminals 101 and 102 are capable of being selected using the switch 63D. Accordingly, the antenna to be used in transmission or reception is capable of being swapped to improve the quality of transmission signals and the receiving sensibility. For example, when a diversity antenna is connected to the antenna connection terminal 102 via a diversity circuit, the signal (for example, the SRS or the like) transmitted through the diversity antenna is capable of being amplified by the power amplifier 11D in the radio frequency circuit 1D. Accordingly, in such a case, the power amplifier in the diversity circuit may be omitted.

For example, in the radio frequency circuit 1D according to the fifth exemplary embodiment, the first amplifier may be the low-noise amplifier 21D, the second amplifier may be the low-noise amplifier 22D, the third amplifier may be the low-noise amplifier 23D, the first input-output terminal may be the radio-frequency output terminal 121 for supplying the reception signal in the NR-U band to the outside of the radio frequency circuit 1D, the second input-output terminal may be the radio-frequency output terminal 122 for supplying the reception signal in the 6-GHz licensed band to the outside of the radio frequency circuit 1D, and the third input-output terminal may be the radio-frequency output terminal 123 for supplying the reception signal in the WLAN band to the outside of the radio frequency circuit 1D.

With the above configuration, the use of the multiplexer 41D enables the power loss to be reduced in reception of the signals in the 6-GHz licensed band and the WLAN band to improve the receiving sensibility.

For example, in the radio frequency circuit 1D according to the fifth exemplary embodiment, the filter 51D may be a low pass filter having the cutoff frequency higher than or equal to the upper limit frequency of the WLAN band in a certain region in which the 6-GHz licensed band is capable of being used. The filter 52D may be a high pass filter having the cutoff frequency lower than or equal to the lower limit frequency of the 6-GHz licensed band in the certain region.

With the above configuration, the signal in the 6-GHz licensed band and the signal in the WLAN band are capable of being efficiently multiplexed and/or demultiplexed with the multiplexer 41D to improve the quality of transmission signals and/or the receiving sensibility.

### OTHER EMBODIMENTS

Although the radio frequency circuits according to the present disclosure are described based on the exemplary embodiments, the radio frequency circuits according to the present disclosure are not limited to the above exemplary embodiments. Other exemplary embodiments realized by combining arbitrary components in the above exemplary embodiments, modifications achieved by making various modifications supposed by the person skilled in the art to the above exemplary embodiments without departing from the spirit and scope of the present disclosure, and various devices incorporating the radio frequency circuits described above are also included in the present disclosure.

For example, in the circuit configuration of the radio frequency circuit according to each exemplary embodiment described above, other circuit elements, lines, and so on may be provided between the paths with which the respective circuit elements and signal paths illustrated in the drawings are connected. For example, an impedance matching circuit may be provided between the power amplifier and the filter and/or between the low-noise amplifier and the filter.

Although the radio frequency circuit includes the two antenna connection terminals in each exemplary embodiment described above, the number of the antenna connection terminals is not limited to two. One antenna connection terminal may be provided or the antenna connection terminals of three or more may be provided.

The radio frequency circuit according to each exemplary embodiment described above may further include the transmission path and/or the reception path for a frequency band of less than 5 GHZ.

Features of the radio frequency circuits and the communication apparatuses described above based on the respective exemplary embodiments will be described.

<1> A radio frequency circuit includes
a first divider including a first terminal, a second terminal, and a third terminal;
a first multiplexer including a first filter having a first passband and a second filter having a second passband higher than the first passband;
a first switch including a first terminal, a second terminal connected to the first terminal of the first divider, and a third terminal connected to a first end of the first filter and a first end of the second filter;
a second switch including a first terminal, a second terminal connected to the third terminal of the first divider, and a third terminal connected to a second end of the first filter;
a third filter having a third passband including a wireless local area network (WLAN) band of 5 GHz or more; and
a first amplifier connected to a first end of the third filter,
wherein the first terminal of the first switch is connected to the first amplifier or the first terminal of the second switch is connected to a second end of the third filter.
   <2> The radio frequency circuit described in <1>,
wherein the first terminal of the first switch is connected to the first amplifier, and
wherein the third passband of the third filter further includes a new radio unlicensed (NR-U) band and a 6-GHz licensed band, the radio frequency circuit further comprising:
a first antenna connection terminal connected to the second end of the third filter;
a first input-output terminal for the NR-U band and connected to the second terminal of the first divider;
a second input-output terminal for the 6-GHz licensed band and connected to a second end of the second filter; and
a third input-output terminal for the WLAN band and connected to the first terminal of the second switch.
   <3> The radio frequency circuit described in <2>,
wherein the first amplifier is a power amplifier,
wherein the first input-output terminal is a first input terminal configured to receive a transmission signal in the NR-U band from outside of the radio frequency circuit,
wherein the second input-output terminal is a second input terminal configured to receive a transmission signal in the 6-GHz licensed band from the outside of the radio frequency circuit, and
wherein the third input-output terminal is a third input terminal configured to receive a transmission signal in the WLAN band from the outside of the radio frequency circuit.
   <4> The radio frequency circuit described in <3>, further comprising:
a second divider including a first terminal, a second terminal, and a third terminal;
a second multiplexer including a fourth filter having a fourth passband and a fifth filter having a fifth passband higher than the fourth passband;
a third switch including a first terminal, a second terminal connected to the first terminal of the second divider, and a third terminal connected to a first end of the fourth filter and a first end of the fifth filter;
a fourth switch including a first terminal, a second terminal connected to the third terminal of the second divider, and a third terminal connected to a second end of the fourth filter;
a low-noise amplifier connected between the first end of the third filter and the first terminal of the third switch;
a fifth switch including a first terminal connected to the first end of the third filter, a second terminal connected to an output end of the power amplifier, and a third terminal connected to an input end of the low-noise amplifier;
a first output terminal configured to supply a reception signal in the NR-U band to the outside of the radio frequency circuit and that is connected to the second terminal of the second divider;
a second output terminal configured to supply a reception signal in the 6-GHz licensed band to the outside of the radio frequency circuit and that is connected to a second end of the fifth filter; and
a third output terminal configured to supply a reception signal in the WLAN band to the outside of the radio frequency circuit and that is connected to the first terminal of the fourth switch.
   <5> The radio frequency circuit described in <4>, further comprising:
a second antenna connection terminal,
wherein the fifth switch further includes a fourth terminal connected to the second antenna connection terminal.
   <6> The radio frequency circuit described in <2>,
wherein the first amplifier is a low-noise amplifier,
wherein the first input-output terminal is a first output terminal configured to supply a reception signal in the NR-U band to outside of the radio frequency circuit,
wherein the second input-output terminal is a second output terminal configured to supply a reception signal in the 6-GHz licensed band to the outside of the radio frequency circuit, and
wherein the third input-output terminal is a third output terminal configured to supply a reception signal in the WLAN band to the outside of the radio frequency circuit.
   <7> The radio frequency circuit described in <1>,
wherein the first terminal of the second switch is connected to the second end of the third filter, the radio frequency circuit further comprising:
a first antenna connection terminal connected to the first terminal of the first switch;
a first input-output terminal for an NR-U band;
a second input-output terminal for a 6-GHz licensed band;
a third input-output terminal for the WLAN band and connected to the first amplifier;
a fourth filter having a fourth passband including the NR-U band;
a second amplifier connected between the first input-output terminal and a first end of the fourth filter;
a fifth filter having a fifth passband including the 6-GHz licensed band; and
a third amplifier connected between the second input-output terminal and a first end of the fifth filter,
wherein the second terminal of the first divider is connected to a second end of the fourth filter, and
wherein a second end of the second filter is connected to a second end of the fifth filter.
   <8> The radio frequency circuit described in <7>,
wherein the first amplifier is a first power amplifier,
wherein the second amplifier is a second power amplifier,
wherein the third amplifier is a third power amplifier,
wherein the first input-output terminal is a first input terminal configured to receive a transmission signal in the NR-U band from outside of the radio frequency circuit,
wherein the second input-output terminal is a second input terminal configured to receive a transmission signal in the 6-GHz licensed band from the outside of the radio frequency circuit, and
wherein the third input-output terminal is a third input terminal configured to receive a transmission signal in the WLAN band from the outside of the radio frequency circuit.
   <9> The radio frequency circuit described in <8>, further comprising:
a first output terminal configured to supply a reception signal in the NR-U band to the outside of the radio frequency circuit;
a second output terminal configured to supply a reception signal in the 6-GHz licensed band to the outside of the radio frequency circuit;
a third output terminal configured to supply a reception signal in the WLAN band to the outside of the radio frequency circuit;
a first low-noise amplifier connected between the third output terminal and the first end of the third filter;
a third switch including a first terminal connected to the first end of the third filter, a second terminal connected to an output end of the first power amplifier, and a third terminal connected to an input end of the first low-noise amplifier;
a second low-noise amplifier connected between the first output terminal and the first end of the fourth filter;
a fourth switch including a first terminal connected to the first end of the fourth filter, a second terminal connected to an output end of the second power amplifier, and a third terminal connected to an input end of the second low-noise amplifier;
a third low-noise amplifier connected between the second output terminal and the first end of the fifth filter; and
a fifth switch including a first terminal connected to the first end of the fifth filter, a second terminal connected to an output end of the third power amplifier, and a third terminal connected to an input end of the third low-noise amplifier.
   <10> The radio frequency circuit described in <9>, further comprising:
a second antenna connection terminal,
wherein the third switch further includes a fourth terminal connected the second antenna connection terminal.
   <11> The radio frequency circuit described in <7>,
wherein the first amplifier is a first low-noise amplifier,
wherein the second amplifier is a second low-noise amplifier,
wherein the third amplifier is a third low-noise amplifier,
wherein the first input-output terminal is a first output terminal configured to supply a reception signal in the NR-U band to outside of the radio frequency circuit,
wherein the second input-output terminal is a second output terminal configured to supply a reception signal in the 6-GHz licensed band to the outside of the radio frequency circuit, and
wherein the third input-output terminal is a third output terminal configured to supply a reception signal in the WLAN band to the outside of the radio frequency circuit.
   <12> The radio frequency circuit described in <1>,
wherein the first terminal of the second switch is connected to the second end of the third filter, the radio frequency circuit further comprising:
a first antenna connection terminal connected to the first terminal of the first switch;
a first input-output terminal for an NR-U band and a 6-GHz licensed band;
a second input-output terminal for the WLAN band and connected to the first amplifier;
a fourth filter having a fourth passband including the NR-U band and the 6-GHz licensed band;
a second amplifier connected between the first input-output terminal and a first end of the fourth filter; and
a third switch including a first terminal connected to a second end of the fourth filter, a second terminal connected to the second terminal of the first divider, and a third terminal connected to a second end of the second filter.
   <13> The radio frequency circuit described in <12>,
wherein the first amplifier is a first power amplifier,
wherein the second amplifier is a second power amplifier,
wherein the first input-output terminal is a first input terminal configured to receive transmission signals in the NR-U band and the 6-GHz licensed band from outside of the radio frequency circuit, and
wherein the second input-output terminal is a second input terminal configured to receive a transmission signal in the WLAN band from the outside of the radio frequency circuit.
   <14> The radio frequency circuit described in <13>, further comprising:
a first output terminal configured to supply reception signals in the NR-U band and the 6-GHz licensed band to the outside of the radio frequency circuit;
a second output terminal configured to supply a reception signal in the WLAN band to the outside of the radio frequency circuit;
a first low-noise amplifier connected between the second output terminal and the first end of the third filter;
a fourth switch including a first terminal connected to the first end of the third filter, a second terminal connected to an output end of the first power amplifier, and a third terminal connected to an input end of the first low-noise amplifier;
a second low-noise amplifier connected between the first output terminal and the first end of the fourth filter; and
a fifth switch including a first terminal connected to the first end of the fourth filter, a second terminal connected to an output end of the second power amplifier, and a third terminal connected to an input end of the second low-noise amplifier.
   <15> The radio frequency circuit described in <14>, further comprising:
a second antenna connection terminal,
wherein the fourth switch further includes a fourth terminal connected to the second antenna connection terminal.
   <16> The radio frequency circuit described in <12>,
wherein the first amplifier is a first low-noise amplifier,
wherein the second amplifier is a second low-noise amplifier,
wherein the first input-output terminal is a first output terminal for supplying reception signals in the NR-U band and the 6-GHz licensed band to outside of the radio frequency circuit, and
wherein the second input-output terminal is a second output terminal for supplying a reception signal in the WLAN band to the outside of the radio frequency circuit.
   <17> The radio frequency circuit described in any of <2> to <16>,
wherein the first filter is a low pass filter having a cutoff frequency higher than or equal to an upper limit frequency of the WLAN band in a certain region in which the 6-GHz licensed band is capable of being used, and
wherein the second filter is a high pass filter having a cutoff frequency lower than or equal to a lower limit frequency of the 6-GHz licensed band in the certain region.
   <18> A radio frequency circuit comprising:
a first divider including a first terminal, a second terminal, and a third terminal;
a first multiplexer including a first filter having a first passband and a second filter having a second passband higher than the first passband;
a first switch including a first terminal, a second terminal, and a third terminal connected to a first end of the first filter and a first end of the second filter;
a second switch including a first terminal connected to the first terminal of the first divider, a second terminal connected to the second terminal of the first switch, and a third terminal connected to a second end of the first filter;
a third filter having a third passband including a WLAN band of 5 GHz or more; and
a first amplifier connected to a first end of the third filter,
wherein the first terminal of the first switch is connected to the first amplifier or the third terminal of the first divider is connected to a second end of the third filter.
   <19> The radio frequency circuit described in <18>,
wherein the first terminal of the first switch is connected to the first amplifier, and
wherein the third passband of the third filter further includes an NR-U band and a 6-GHz licensed band, the radio frequency circuit further comprising:
a first antenna connection terminal connected to the second end of the third filter;
a first input-output terminal for the NR-U band and connected to the second terminal of the first divider;
a second input-output terminal for the 6-GHz licensed band and connected to a second end of the second filter; and
a third input-output terminal for the WLAN band and connected to the third terminal of the first divider.
   <20> The radio frequency circuit described in <18>,
wherein the third terminal of the first divider is connected to the second end of the third filter, the radio frequency circuit further comprising:
a first antenna connection terminal connected to the first terminal of the first switch;
a first input-output terminal for an NR-U band;
a second input-output terminal for a 6-GHz licensed band;
a third input-output terminal for the WLAN band and connected to the first amplifier;
a fourth filter having a fourth passband including the NR-U band;
a second amplifier connected between the first input-output terminal and a first end of the fourth filter;
a fifth filter having a fifth passband including the 6-GHz licensed band; and
a third amplifier connected between the second input-output terminal and a first end of the fifth filter,
wherein the second terminal of the first divider is connected to a second end of the fourth filter, and
wherein a second end of the second filter is connected to a second end of the fifth filter.
   <21> The radio frequency circuit described in <19>,
wherein the first amplifier is a power amplifier,
wherein the first input-output terminal is a first input terminal configured to receive a transmission signal in the NR-U band from outside of the radio frequency circuit,
wherein the second input-output terminal is a second input terminal configured to receive a transmission signal in the 6-GHz licensed band from the outside of the radio frequency circuit, and
wherein the third input-output terminal is a third input terminal configured to receive a transmission signal in the WLAN band from the outside of the radio frequency circuit.
   <22> The radio frequency circuit described in <21>, further comprising:
a second divider including a first terminal, a second terminal, and a third terminal;
a second multiplexer including a fourth filter having a fourth passband and a fifth filter having a fifth passband higher than the fourth passband;
a third switch including a first terminal, a second terminal, and a third terminal connected to a first end of the fourth filter and a first end of the fifth filter;
a fourth switch including a first terminal connected to the first terminal of the second divider, a second terminal connected to the second terminal of the third switch, and a third terminal connected to a second end of the fourth filter;
a low-noise amplifier connected between the first end of the third filter and the first terminal of the third switch;
a fifth switch including a first terminal connected to the first end of the third filter, a second terminal connected to an output end of the power amplifier, and a third terminal connected to an input end of the low-noise amplifier;
a first output terminal configured to supply a reception signal in the NR-U band to the outside of the radio frequency circuit and that is connected to the second terminal of the second divider;
a second output terminal configured to supply a reception signal in the 6-GHz licensed band to the outside of the radio frequency circuit and that is connected to a second end of the fifth filter; and
a third output terminal configured to supply a reception signal in the WLAN band to the outside of the radio frequency circuit and that is connected to the third terminal of the second divider.
   <23> The radio frequency circuit described in <22>, further comprising:
a second antenna connection terminal,
wherein the fifth switch further includes a fourth terminal connected to the second antenna connection terminal.
   <24> The radio frequency circuit described in <19>,
wherein the first amplifier is a low-noise amplifier,
wherein the first input-output terminal is a first output terminal configured to supply a reception signal in the NR-U band to outside of the radio frequency circuit,
wherein the second input-output terminal is a second output terminal configured to supply a reception signal in the 6-GHz licensed band to the outside of the radio frequency circuit, and
wherein the third input-output terminal is a third output terminal configured to supply a reception signal in the WLAN band to the outside of the radio frequency circuit.
   <25> The radio frequency circuit described in <20>,
wherein the first amplifier is a first power amplifier,
wherein the second amplifier is a second power amplifier,
wherein the third amplifier is a third power amplifier,
wherein the first input-output terminal is a first input terminal configured to receive a transmission signal in the NR-U band from outside of the radio frequency circuit,
wherein the second input-output terminal is a second input terminal configured to receive a transmission signal in the 6-GHz licensed band from the outside of the radio frequency circuit, and
wherein the third input-output terminal is a third input terminal configured to receive a transmission signal in the WLAN band from the outside of the radio frequency circuit.
   <26> The radio frequency circuit described in <25>, further comprising:
a first output terminal configured to supply a reception signal in the NR-U band to the outside of the radio frequency circuit;
a second output terminal configured to supply a reception signal in the 6-GHz licensed band to the outside of the radio frequency circuit;
a third output terminal configured to supply a reception signal in the WLAN band to the outside of the radio frequency circuit;
a first low-noise amplifier connected between the third output terminal and the first end of the third filter;
a third switch including a first terminal connected to the first end of the third filter, a second terminal connected to an output end of the first power amplifier, and a third terminal connected to an input end of the first low-noise amplifier;
a second low-noise amplifier connected between the first output terminal and the first end of the fourth filter;
a fourth switch including a first terminal connected to the first end of the fourth filter, a second terminal connected to an output end of the second power amplifier, and a third terminal connected to an input end of the second low-noise amplifier;
a third low-noise amplifier connected between the second output terminal and the first end of the fifth filter; and
a fifth switch including a first terminal connected to the first end of the fifth filter, a second terminal connected to an output end of the third power amplifier, and a third terminal connected to an input end of the third low-noise amplifier.
   <27> The radio frequency circuit described in <26>, further comprising:
a second antenna connection terminal,
wherein the third switch further includes a fourth terminal connected the second antenna connection terminal.
   <28> The radio frequency circuit described in <20>,
wherein the first amplifier is a first low-noise amplifier,
wherein the second amplifier is a second low-noise amplifier,
wherein the third amplifier is a third low-noise amplifier,
wherein the first input-output terminal is a first output terminal configured to supply a reception signal in the NR-U band to outside of the radio frequency circuit,
wherein the second input-output terminal is a second output terminal configured to supply a reception signal in the 6-GHz licensed band to the outside of the radio frequency circuit, and
wherein the third input-output terminal is a third output terminal configured to supply a reception signal in the WLAN band to the outside of the radio frequency circuit.
   <29> The radio frequency circuit described in any of <19> to <28>,
wherein the first filter is a low pass filter having a cutoff frequency higher than or equal to an upper limit frequency of the WLAN band in a certain region in which the 6-GHz licensed band is capable of being used, and
wherein the second filter is a high pass filter having a cutoff frequency lower than or equal to a lower limit frequency of the 6-GHz licensed band in the certain region.

The present disclosure is widely usable for a communication device, such as a mobile phone, as the radio frequency circuit disposed in a front-end portion.

What is claimed is:

1. A radio frequency circuit comprising:
a first divider including a first terminal, a second terminal, and a third terminal;
a first multiplexer including a first filter having a first passband and a second filter having a second passband higher than the first passband;
a first switch including a first terminal, a second terminal connected to the first terminal of the first divider, and a third terminal connected to a first end of the first filter and a first end of the second filter;
a second switch including a first terminal, a second terminal connected to the third terminal of the first divider, and a third terminal connected to a second end of the first filter;
a third filter having a third passband including a wireless local area network (WLAN) band of 5 GHz or more; and
a first amplifier connected to a first end of the third filter,
wherein the first terminal of the first switch is connected to the first amplifier or the first terminal of the second switch is connected to a second end of the third filter.

2. The radio frequency circuit according to claim 1,
wherein the first terminal of the first switch is connected to the first amplifier, and
wherein the third passband of the third filter further includes a new radio unlicensed (NR-U) band and a 6-GHz licensed band, the radio frequency circuit further comprising:
a first antenna connection terminal connected to the second end of the third filter;
a first input-output terminal for the NR-U band and connected to the second terminal of the first divider;
a second input-output terminal for the 6-GHz licensed band and connected to a second end of the second filter; and
a third input-output terminal for the WLAN band and connected to the first terminal of the second switch.

3. The radio frequency circuit according to claim 2,
wherein the first amplifier is a power amplifier,
wherein the first input-output terminal is a first input terminal configured to receive a transmission signal in the NR-U band from outside of the radio frequency circuit,
wherein the second input-output terminal is a second input terminal configured to receive a transmission signal in the 6-GHz licensed band from the outside of the radio frequency circuit, and
wherein the third input-output terminal is a third input terminal configured to receive a transmission signal in the WLAN band from the outside of the radio frequency circuit.

4. The radio frequency circuit according to claim 3, further comprising:
a second divider including a first terminal, a second terminal, and a third terminal;
a second multiplexer including a fourth filter having a fourth passband and a fifth filter having a fifth passband higher than the fourth passband;
a third switch including a first terminal, a second terminal connected to the first terminal of the second divider, and a third terminal connected to a first end of the fourth filter and a first end of the fifth filter;
a fourth switch including a first terminal, a second terminal connected to the third terminal of the second divider, and a third terminal connected to a second end of the fourth filter;
a low-noise amplifier connected between the first end of the third filter and the first terminal of the third switch;
a fifth switch including a first terminal connected to the first end of the third filter, a second terminal connected to an output end of the power amplifier, and a third terminal connected to an input end of the low-noise amplifier;
a first output terminal configured to supply a reception signal in the NR-U band to the outside of the radio frequency circuit and that is connected to the second terminal of the second divider;
a second output terminal configured to supply a reception signal in the 6-GHz licensed band to the outside of the radio frequency circuit and that is connected to a second end of the fifth filter; and
a third output terminal configured to supply a reception signal in the WLAN band to the outside of the radio frequency circuit and that is connected to the first terminal of the fourth switch.

5. The radio frequency circuit according to claim 4, further comprising:
a second antenna connection terminal,
wherein the fifth switch further includes a fourth terminal connected to the second antenna connection terminal.

6. The radio frequency circuit according to claim 2,
wherein the first amplifier is a low-noise amplifier,
wherein the first input-output terminal is a first output terminal configured to supply a reception signal in the NR-U band to outside of the radio frequency circuit,
wherein the second input-output terminal is a second output terminal configured to supply a reception signal in the 6-GHz licensed band to the outside of the radio frequency circuit, and
wherein the third input-output terminal is a third output terminal configured to supply a reception signal in the WLAN band to the outside of the radio frequency circuit.

7. The radio frequency circuit according to claim 1,
wherein the first terminal of the second switch is connected to the second end of the third filter, the radio frequency circuit further comprising:
a first antenna connection terminal connected to the first terminal of the first switch;
a first input-output terminal for an NR-U band;
a second input-output terminal for a 6-GHz licensed band;
a third input-output terminal for the WLAN band and connected to the first amplifier;
a fourth filter having a fourth passband including the NR-U band;
a second amplifier connected between the first input-output terminal and a first end of the fourth filter;
a fifth filter having a fifth passband including the 6-GHz licensed band; and
a third amplifier connected between the second input-output terminal and a first end of the fifth filter,
wherein the second terminal of the first divider is connected to a second end of the fourth filter, and
wherein a second end of the second filter is connected to a second end of the fifth filter.

8. The radio frequency circuit according to claim 7,
wherein the first amplifier is a first power amplifier,
wherein the second amplifier is a second power amplifier,
wherein the third amplifier is a third power amplifier,
wherein the first input-output terminal is a first input terminal configured to receive a transmission signal in the NR-U band from outside of the radio frequency circuit,
wherein the second input-output terminal is a second input terminal configured to receive a transmission signal in the 6-GHz licensed band from the outside of the radio frequency circuit, and
wherein the third input-output terminal is a third input terminal configured to receive a transmission signal in the WLAN band from the outside of the radio frequency circuit.

9. The radio frequency circuit according to claim 8, further comprising:
a first output terminal configured to supply a reception signal in the NR-U band to the outside of the radio frequency circuit;
a second output terminal configured to supply a reception signal in the 6-GHz licensed band to the outside of the radio frequency circuit;
a third output terminal configured to supply a reception signal in the WLAN band to the outside of the radio frequency circuit;
a first low-noise amplifier connected between the third output terminal and the first end of the third filter;
a third switch including a first terminal connected to the first end of the third filter, a second terminal connected to an output end of the first power amplifier, and a third terminal connected to an input end of the first low-noise amplifier;
a second low-noise amplifier connected between the first output terminal and the first end of the fourth filter;
a fourth switch including a first terminal connected to the first end of the fourth filter, a second terminal connected to an output end of the second power amplifier, and a third terminal connected to an input end of the second low-noise amplifier;
a third low-noise amplifier connected between the second output terminal and the first end of the fifth filter; and
a fifth switch including a first terminal connected to the first end of the fifth filter, a second terminal connected to an output end of the third power amplifier, and a third terminal connected to an input end of the third low-noise amplifier.

10. The radio frequency circuit according to claim 9, further comprising:
a second antenna connection terminal,
wherein the third switch further includes a fourth terminal connected the second antenna connection terminal.

11. The radio frequency circuit according to claim 7,
wherein the first amplifier is a first low-noise amplifier,
wherein the second amplifier is a second low-noise amplifier,
wherein the third amplifier is a third low-noise amplifier,
wherein the first input-output terminal is a first output terminal configured to supply a reception signal in the NR-U band to outside of the radio frequency circuit,
wherein the second input-output terminal is a second output terminal configured to supply a reception signal in the 6-GHz licensed band to the outside of the radio frequency circuit, and
wherein the third input-output terminal is a third output terminal configured to supply a reception signal in the WLAN band to the outside of the radio frequency circuit.

12. The radio frequency circuit according to claim 1,
wherein the first terminal of the second switch is connected to the second end of the third filter, the radio frequency circuit further comprising:
a first antenna connection terminal connected to the first terminal of the first switch;
a first input-output terminal for an NR-U band and a 6-GHz licensed band;
a second input-output terminal for the WLAN band and connected to the first amplifier;
a fourth filter having a fourth passband including the NR-U band and the 6-GHz licensed band;
a second amplifier connected between the first input-output terminal and a first end of the fourth filter; and
a third switch including a first terminal connected to a second end of the fourth filter, a second terminal connected to the second terminal of the first divider, and a third terminal connected to a second end of the second filter.

13. The radio frequency circuit according to claim 12,
wherein the first amplifier is a first power amplifier,
wherein the second amplifier is a second power amplifier,
wherein the first input-output terminal is a first input terminal configured to receive transmission signals in the NR-U band and the 6-GHz licensed band from outside of the radio frequency circuit, and
wherein the second input-output terminal is a second input terminal configured to receive a transmission signal in the WLAN band from the outside of the radio frequency circuit.

14. The radio frequency circuit according to claim 13, further comprising:
a first output terminal configured to supply reception signals in the NR-U band and the 6-GHz licensed band to the outside of the radio frequency circuit;
a second output terminal configured to supply a reception signal in the WLAN band to the outside of the radio frequency circuit;
a first low-noise amplifier connected between the second output terminal and the first end of the third filter;
a fourth switch including a first terminal connected to the first end of the third filter, a second terminal connected to an output end of the first power amplifier, and a third terminal connected to an input end of the first low-noise amplifier;
a second low-noise amplifier connected between the first output terminal and the first end of the fourth filter; and
a fifth switch including a first terminal connected to the first end of the fourth filter, a second terminal connected to an output end of the second power amplifier, and a third terminal connected to an input end of the second low-noise amplifier.

15. The radio frequency circuit according to claim 14, further comprising:
a second antenna connection terminal,
wherein the fourth switch further includes a fourth terminal connected to the second antenna connection terminal.

16. The radio frequency circuit according to claim 12,
wherein the first amplifier is a first low-noise amplifier,
wherein the second amplifier is a second low-noise amplifier,
wherein the first input-output terminal is a first output terminal configured to supply reception signals in the NR-U band and the 6-GHz licensed band to outside of the radio frequency circuit, and
wherein the second input-output terminal is a second output terminal configured to supply a reception signal in the WLAN band to the outside of the radio frequency circuit.

17. The radio frequency circuit according to claim 2,
wherein the first filter is a low pass filter having a cutoff frequency higher than or equal to an upper limit frequency of the WLAN band in a certain region in which the 6-GHz licensed band is capable of being used, and
wherein the second filter is a high pass filter having a cutoff frequency lower than or equal to a lower limit frequency of the 6-GHz licensed band in the certain region.

18. A radio frequency circuit comprising:
a first divider including a first terminal, a second terminal, and a third terminal;
a first multiplexer including a first filter having a first passband and a second filter having a second passband higher than the first passband;
a first switch including a first terminal, a second terminal, and a third terminal connected to a first end of the first filter and a first end of the second filter;
a second switch including a first terminal connected to the first terminal of the first divider, a second terminal connected to the second terminal of the first switch, and a third terminal connected to a second end of the first filter;
a third filter having a third passband including a wireless local area network (WLAN) band of 5 GHz or more; and
a first amplifier connected to a first end of the third filter,
wherein the first terminal of the first switch is connected to the first amplifier or the third terminal of the first divider is connected to a second end of the third filter.

19. The radio frequency circuit according to claim 18,
wherein the first terminal of the first switch is connected to the first amplifier, and
wherein the third passband of the third filter further includes a new radio unlicensed (NR-U) band and a 6-GHz licensed band, the radio frequency circuit further comprising:
a first antenna connection terminal connected to the second end of the third filter;
a first input-output terminal for the NR-U band and connected to the second terminal of the first divider;
a second input-output terminal for the 6-GHz licensed band and connected to a second end of the second filter; and
a third input-output terminal for the WLAN band and connected to the third terminal of the first divider.

20. The radio frequency circuit according to claim 18,
wherein the third terminal of the first divider is connected to the second end of the third filter, the radio frequency circuit further comprising:
a first antenna connection terminal connected to the first terminal of the first switch;
a first input-output terminal for an NR-U band;
a second input-output terminal for a 6-GHz licensed band;
a third input-output terminal for the WLAN band and connected to the first amplifier;
a fourth filter having a fourth passband including the NR-U band;
a second amplifier connected between the first input-output terminal and a first end of the fourth filter;
a fifth filter having a fifth passband including the 6-GHz licensed band; and
a third amplifier connected between the second input-output terminal and a first end of the fifth filter,
wherein the second terminal of the first divider is connected to a second end of the fourth filter, and
wherein a second end of the second filter is connected to a second end of the fifth filter.
